(19) United States
(12) Patent Application Publication
(10) Pub. No.: US 2026/0214926 A1
(43) Pub. Date: Jul. 23, 2026

(54) Manufacturing Method Of Stack And Manufacturing Method Of Semiconductor Device

(71) Applicant: Semiconductor Energy Laboratory Co., Ltd., Kanagawa-ken (JP)

(72) Inventors: Toshiya ENDO, Atsugi, Kanagawa (JP); Takashi ISHIZAKA, Tochigi, Tochigi (JP); Masaru NAKANO, Isehara, Kanagawa (JP); Yoshikazu HIURA, Isehara, Kanagawa (JP); Akihiro KIKUCHI, Isehara, Kanagawa (JP); Ryota HODO, Atsugi, Kanagawa (JP)

(73) Assignee: Semiconductor Energy Laboratory Co., Ltd., Kanagawa-ken (JP)

(21) Appl. No.: 19/142,815

(22) PCT Filed: Dec. 21, 2023
(86) PCT No.: PCT/IB2023/063063

§ 371 Date: Jun. 24, 2025

(30) Foreign Application Priority Data
Dec. 28, 2022 (JP) 2022-211829
Oct. 20, 2023 (JP) 2023-180822

(51) Int. Cl. H10D 30/01

(52) U.S. Cl. CPC H10D 30/0312

(57) ABSTRACT

A semiconductor device, a display apparatus, or a memory device occupying a small area is provided. A conductor device, a display apparatus, or a memory device with low wiring resistance is provided. A stack includes a first insulating layer including a first opening, a first conductive layer over the first insulating layer, and a second conductive layer over the first conductive layer. The stack is manufactured by forming a first insulating film, a first conductive film, and a second conductive film in this order; forming a coating film over the second conductive film; forming the second conductive layer by performing etching of the second conductive film using, as a mask, a layer obtained by processing the coating film; removing a second coating film; forming the first conductive layer by performing etching of the first conductive film using the second conductive layer as a mask; and forming the first insulating layer including the first opening by performing etching of the first insulating film using the second conductive layer as a mask.

### TECHNICAL FIELD

One embodiment of the present invention relates to a transistor, a semiconductor device, a display apparatus, a memory device, an electronic component, or an electronic appliance. Another embodiment of the present invention relates to a method for manufacturing a semiconductor device, a display apparatus, a memory device, or an electronic appliance. Another embodiment of the present invention relates to a semiconductor wafer or a module.

Note that one embodiment of the present invention is not limited to the above technical field. Examples of the technical field of one embodiment of the present invention include a semiconductor device, a display apparatus, a light-emitting apparatus, a power storage device, a memory device, an electronic appliance, a lighting device, an input device (e.g., a touch sensor), an input/output device (e.g., a touch panel), a driving method thereof, and a manufacturing method thereof.

In this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means any device that can function by utilizing semiconductor characteristics. For example, an integrated circuit, a chip including an integrated circuit, and an electronic component including a chip in a package are examples of the semiconductor device. Moreover, a memory device, a display apparatus, a light-emitting apparatus, a lighting device, and an electronic device themselves are semiconductor devices and each of them includes a semiconductor device in some cases.

### BACKGROUND ART

Semiconductor devices that include transistors are applied to a wide range of electronic appliances. In addition, uses for a display apparatus are diversified in recent years, and for example, the display apparatus is used for a portable information terminal, a television device (also referred to as a television receiver), digital signage, a PID (Public Information Display), and the like. Examples of the display apparatus include a display apparatus including an organic EL (Electro Luminescence) element or a light-emitting diode (LED), a display apparatus including a liquid crystal element, and electronic paper performing display by an electrophoretic method.

In a display apparatus, for example, when the area occupied by transistors is reduced, the pixel size can be reduced and resolution can be increased. Furthermore, when the area occupied by transistors is reduced, the aperture ratio can be increased. Thus, minute transistors have been required. As devices requiring high-resolution display apparatuses, for example, devices for virtual reality (VR), augmented reality (AR), substitutional reality (SR), and mixed reality (MR) have been actively developed. Patent Document 1 discloses a high-resolution display apparatus using an organic EL element.

A technique by which a transistor is formed using a semiconductor thin film formed over a substrate having an insulating surface has been attracting attention. The transistor is used in a wide range of electronic devices such as an integrated circuit and an image display apparatus (also simply referred to as a display apparatus). A silicon-based semiconductor material is widely known as a semiconductor thin film applicable to the transistor, and an oxide semiconductor has been attracting attention as another material.

It is known that a transistor using an oxide semiconductor has an extremely low leakage current in a non-conduction state. For example, Patent Document 2 discloses a low-power-consumption CPU utilizing a feature of a low leakage current. Furthermore, for example, Patent Document 3 discloses a memory device that can retain stored contents for a long time.

### REFERENCES

### Patent Documents

[Patent Document 1] PCT International Publication No. 2016/038508
[Patent Document 2] Japanese Published Patent Application No. 2012-257187
[Patent Document 3] Japanese Published Patent Application No. 2011-151383

### SUMMARY OF THE INVENTION

### Problems to be Solved by the Invention

One object of one embodiment of the present invention is to provide a semiconductor device, a display apparatus, or a memory device occupying a small area. Another object is to provide a conductor device, a display apparatus, or a memory device with low wiring resistance.

Another object of one embodiment of the present invention is to provide a transistor having a minute size. Another object is to provide a transistor having favorable electrical characteristics. Another object is to provide a transistor having high reliability. Another object is to provide a transistor having a long channel length. Another object is to provide a transistor having a long channel length and a transistor having a short channel length. Another object is to provide a method for manufacturing a transistor having high productivity.

Another object of one embodiment of the present invention is to provide a semiconductor device, a display apparatus, a memory device having low power consumption. Another object is to provide a semiconductor device, a display apparatus, or a memory device having high reliability. Another object is to provide a method for manufacturing a semiconductor device, a display apparatus, or a memory device having high productivity. Another object is to provide a display apparatus that can easily achieve higher resolution. Another object is to provide a memory device that can easily achieve higher integration.

Another object of one embodiment of the present invention is to provide a novel transistor, semiconductor device, display apparatus, or memory device. Another object is to provide a manufacturing method thereof.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a method for manufacturing a stack, the stack including a first insulating layer including a first opening, a first conductive layer over the first insulating layer, and a second conductive layer over the first conductive layer. The method includes forming a first insulating film; forming a first conductive film over the first insulating film; forming a second conductive film over the first conductive film; forming a first coating film over the second conductive film; forming a second coating film by removing a part of the first coating film; forming the second conductive layer by performing etching of the second conductive film using the second coating film as a mask; forming the first conductive layer by performing etching of the first conductive film using the second conductive layer as a mask; and forming the first insulating layer including the first opening by performing etching of the first insulating film using the second conductive layer as a mask. The first coating film is a film including silicon, oxygen, and carbon. The first conductive film is an oxide conductor or a nitride conductor. The second conductive film is a metal film including one or more of ruthenium, tantalum, nickel, titanium, molybdenum, tungsten, hafnium, vanadium, niobium, aluminum, chromium, copper, silver, gold, platinum, zinc, manganese, iron, cobalt, magnesium, zirconium, beryllium, indium, iridium, strontium, and lanthanum.

In the above embodiment, preferably, the second coating film is removed at the same time as the etching of the first insulating film.

In the above embodiment, preferably, the second conductive film is a ruthenium film; the etching of the second conductive film is dry etching using an oxygen gas and a chlorine gas as etching gases; and a flow rate ratio of the oxygen gas in the dry etching is higher than or equal to 50% and lower than 100% when the sum of flow rates of the oxygen gas and the chlorine gas is set to 100%.

In the above embodiment, preferably, a pressure in a chamber in the etching of the second conductive film is higher than or equal to 0.5 Pa and lower than or equal to 50 Pa.

In the above embodiment, preferably, the first conductive film is an oxide film including indium.

One embodiment of the present invention is a method for manufacturing a semiconductor device, the semiconductor device including a first conductive layer, a first insulating layer including a first opening overlapping with the first conductive layer, a second conductive layer over the first insulating layer, a third conductive layer over the second conductive layer, a first semiconductor layer, a second insulating layer, and a fourth conductive layer. The method includes forming a first conductive film; forming the first conductive layer by processing the first conductive film; forming a first insulating film over the first conductive layer; forming a second conductive film over the first insulating film; forming a third conductive film over the second conductive film; forming a first coating film over the third conductive film; forming a second coating film by removing a part of the first coating film; forming the third conductive layer by performing etching of the third conductive film using the second coating film as a mask; forming the second conductive layer by performing etching of the first conductive film using the third conductive layer as a mask; forming the first insulating layer including the first opening by performing etching of the first insulating film using the third conductive layer as a mask; forming the first semiconductor layer to cover the first conductive layer, the first insulating layer, and a side surface of the first opening of the first insulating layer; forming the second insulating layer over the first semiconductor layer; and forming the fourth conductive layer over the second insulating layer. The first coating film is a film including silicon, oxygen, and carbon. The second conductive film is an oxide conductor or a nitride conductor. The third conductive film is a metal film including one or more of ruthenium, tantalum, nickel, titanium, molybdenum, tungsten, hafnium, vanadium, niobium, aluminum, chromium, copper, silver, gold, platinum, zinc, manganese, iron, cobalt, magnesium, zirconium, beryllium, indium, iridium, strontium, and lanthanum. The first semiconductor layer is a metal oxide.

In the above embodiment, preferably, the second coating film is removed at the same time as the etching of the first insulating film.

In the above embodiment, preferably, the second conductive film is a ruthenium film; the etching of the second conductive film is dry etching using an oxygen gas and a chlorine gas as etching gases; and a flow rate ratio of the oxygen gas in the dry etching is higher than or equal to 50% and lower than 100% when the sum of flow rates of the oxygen gas and the chlorine gas is set to 100%.

In the above embodiment, preferably, a pressure in a chamber in the etching of the second conductive film is higher than or equal to 0.5 Pa and lower than or equal to 50 Pa.

In the above embodiment, preferably, the first conductive film is an oxide film including indium.

In the above embodiment, preferably, the metal oxide includes one or more of indium and zinc.

In the above embodiment, preferably, the metal oxide includes an element M and one or more of indium and zinc; and the element Mis one or more kinds selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.

### Effect of the Invention

According to one embodiment of the present invention, a semiconductor device, a display apparatus, or a memory device occupying a small area can be provided. Alternatively, a conductor device, a display apparatus, or a memory device with low wiring resistance can be provided.

According to another embodiment of the present invention, a transistor having a minute size can be provided. Alternatively, a transistor having favorable electrical characteristics can be provided. In addition, a transistor having high reliability can be provided. Alternatively, a transistor having a long channel length can be provided. Alternatively, a transistor having a long channel length and a transistor having a short channel length can be provided. Alternatively, a method for manufacturing a transistor having high productivity can be provided.

According to another embodiment of the present invention, a semiconductor device, a display apparatus, a memory device having low power consumption can be provided. Alternatively, a highly reliable semiconductor device, display apparatus, or memory device can be provided. Alternatively, a method for manufacturing a semiconductor device, a display apparatus, or a memory device having high productivity can be provided. Alternatively, a display apparatus that can easily achieve higher resolution can be provided. Alternatively, a memory device that is highly integrated easily can be provided.

According to another embodiment of the present invention, a novel transistor, semiconductor device, display apparatus, or memory device can be provided. Alternatively, a manufacturing method thereof can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A to FIG. 1C are schematic cross-sectional views showing a method for manufacturing a stack.

FIG. 2A to FIG. 2D are schematic cross-sectional views showing a method for manufacturing a stack.

FIG. 3A to FIG. 3C are schematic cross-sectional views showing a method for manufacturing a stack.

FIG. 4A to FIG. 4C are schematic cross-sectional views showing examples of a stack.

FIG. 5A to FIG. 5C are schematic cross-sectional views showing a method for manufacturing a stack.

FIG. 6A and FIG. 6B are schematic cross-sectional views showing a method for manufacturing a stack.

FIG. 7A to FIG. 7C are schematic cross-sectional views showing a method for manufacturing a stack.

FIG. 8A to FIG. 8C are schematic cross-sectional views showing a method for manufacturing a stack.

FIG. 9A is a top view showing an example of a semiconductor device. FIG. 9B is a cross-sectional view showing the example of the semiconductor device.

FIG. 10A is a top view showing an example of a semiconductor device. FIG. 10B is a cross-sectional view showing the example of the semiconductor device.

FIG. 11A is a top view showing an example of a semiconductor device. FIG. 11B is a cross-sectional view showing the example of the semiconductor device.

FIG. 12A is a top view showing an example of a semiconductor device. FIG. 12B is a cross-sectional view showing the example of the semiconductor device.

FIG. 13A is a top view showing an example of a semiconductor device. FIG. 13B is a cross-sectional view showing the example of the semiconductor device.

FIG. 14A to FIG. 14E are cross-sectional views showing an example of a method for manufacturing a semiconductor device.

FIG. 15A to FIG. 15D are cross-sectional views showing an example of a method for manufacturing a semiconductor device.

FIG. 16A to FIG. 16D are cross-sectional views showing an example of a method for manufacturing a semiconductor device.

FIG. 17A to FIG. 17D are cross-sectional views showing an example of a method for manufacturing a semiconductor device.

FIG. 18A and FIG. 18B are top views showing an example of a method for manufacturing a semiconductor device.

FIG. 19A and FIG. 19B are top views showing an example of a method for manufacturing a semiconductor device.

FIG. 20A is a perspective view showing an example of a display apparatus. FIG. 20B is a block diagram showing an example of a display apparatus.

FIG. 21A is a circuit diagram of a latch circuit. FIG. 21B is a circuit diagram of an inverter circuit.

FIG. 22A and FIG. 22B are circuit diagrams of pixel circuits. FIG. 22C is a cross-sectional view showing an example of a pixel circuit.

FIG. 23 is a schematic cross-sectional view showing a structure example of a display apparatus.

FIG. 24A to FIG. 24C are structure examples of a memory device.

FIG. 25A and FIG. 25B are structure examples of a memory device.

FIG. 26A to FIG. 26C are structure examples of a memory device.

FIG. 27A and FIG. 27B are structure examples of a memory device.

FIG. 28A and FIG. 28B are structure examples of a memory device.

FIG. 29A and FIG. 29B are structure examples of a memory device.

FIG. 30 is a structure example of a memory device.

FIG. 31 is a structure example of a memory device.

FIG. 32A and FIG. 32B are structure examples of a memory device.

FIG. 33A to FIG. 33D are structure examples of a memory device.

FIG. 34 is a structure example of a memory device.

FIG. 35A to FIG. 35D are structure examples of electronic appliances.

FIG. 36A to FIG. 36F are structure examples of electronic appliances.

FIG. 37A to FIG. 37G are structure examples of electronic appliances.

FIG. 38A and FIG. 38B are structure examples of electronic components.

FIG. 39A to FIG. 39C are structure examples of a large computer.

FIG. 40A is a structure example of a device for space. FIG. 40B is a structure example of a storage system.

FIG. 41A and FIG. 41B are evaluation results of etching characteristics.

FIG. 42A and FIG. 42B are evaluation results of etching characteristics.

FIG. 43A to FIG. 43D are results of SEM observations.

FIG. 44A to FIG. 44D are results of SEM observations.

### MODE FOR CARRYING OUT THE INVENTION

Embodiments will be described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

In the drawings, the size, the layer thickness, or the region is sometimes exaggerated for clarity. Thus, the size, the layer thickness, or the region is not limited to the shown scale. Note that the drawings schematically show ideal examples, and embodiments of the present invention are not limited to shapes or values shown in the drawings. For example, in the actual manufacturing process, a layer, a resist mask, or the like might be unintentionally reduced in size by treatment such as etching, which might not be reflected in the drawings for easy understanding. Furthermore, in the drawings, the same reference numerals are used in common for the same portions or portions having similar functions in different drawings, and repeated description thereof is omitted in some cases. The same hatching pattern is used for portions having similar functions, and the portions are not especially denoted by reference numerals in some cases.

Furthermore, especially in a plan view (also referred to as a “top view”), a perspective view, or the like, the description of some components is omitted for easy understanding of the invention in some cases. The description of some hidden lines is also omitted in some cases.

The ordinal numbers such as “first” and “second” in this specification and the like are used for convenience and do not denote the order of steps or the stacking order of layers. Thus, for example, the term “first” can be replaced with the term “second”, “third”, or the like as appropriate. In addition, the ordinal numbers in this specification and the like do not sometimes correspond to the ordinal numbers that are used to specify one embodiment of the present invention.

Moreover, in this specification and the like, terms for describing arrangement, such as “over” and “under”, are used for convenience for describing the positional relationship between components with reference to drawings. The positional relationship between components is changed as appropriate in accordance with the direction in which the components are described. Thus, without limitation to terms described in this specification, the description can be changed appropriately depending on the situation.

In this specification and the like, for example, the expression “X and Y are connected” means the case where X and Y are electrically connected. Here, the expression “X and Y are electrically connected” means connection that enables electrical signal transmission between X and Y in the case where an object (that refers to an element such as a switch, a transistor element, or a diode, a circuit including the element and a wiring, or the like) is present between X and Y. Note that the case where X and Y are electrically connected includes the case where X and Y are directly connected. Here, the expression “X and Y are directly connected” means connection that enables electrical signal transmission between X and Y through a wiring (or an electrode) or the like, not through the above object. In other words, direct connection refers to connection that can be regarded as the same circuit diagram when represented by an equivalent circuit.

In this specification and the like, a transistor is an element having at least three terminals including a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

Furthermore, functions of a source and a drain are sometimes interchanged with each other when a transistor of different polarity is used or when the direction of a current is changed in a circuit operation, for example. Thus, the terms “source” and “drain” can sometimes be interchanged with each other in this specification and the like. Note that a source and a drain of a transistor can also sometimes be referred to as a source terminal and a drain terminal or a source electrode and a drain electrode, for example, as appropriate depending on circumstances.

Note that impurities in a semiconductor refer to, for example, elements other than the main components of the semiconductor. For example, an element with a concentration lower than 0.1 atomic % can be regarded as an impurity. When an impurity is included, for example, the density of defect states in a semiconductor increases and the crystallinity decreases in some cases. In the case where the semiconductor is an oxide semiconductor, examples of impurities which change the characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. Note that water also serves as an impurity in some cases. In addition, oxygen vacancies (also referred to as V_{O}) are formed in an oxide semiconductor in some cases by entry of impurities, for example.

Note that in this specification and the like, an oxynitride is a material that includes more oxygen than nitrogen in its composition. Examples of the oxynitride include silicon oxynitride, aluminum oxynitride, and hafnium oxynitride. Moreover, a nitride oxide is a material that includes more nitrogen than oxygen in its composition. Examples of the nitride oxide include silicon nitride oxide, aluminum nitride oxide, and hafnium nitride oxide.

Note that the term “film” and the term “layer” can be used interchangeably depending on the case or the circumstances. For example, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

Note that in this specification and the like, the expression “level with” indicates a structure having the same level from a reference surface (e.g., a flat surface such as a substrate surface) in a cross-sectional view. For example, in a manufacturing process of a memory device, planarization treatment (typically, CMP treatment) is performed, whereby the surface of a single layer or the surfaces of a plurality of layers is/are exposed in some cases. In that case, the surfaces on which the CMP treatment is performed are at the same level from a reference surface. Note that a plurality of layers may be at different levels depending on a treatment apparatus, a treatment method, or a material of the treated surfaces, used for the CMP treatment. This case is also regarded as being “level with” in this specification and the like. For example, the expression “level with” includes the case where two layers (here, given as a first layer and a second layer) having different levels with respect to the reference surface are included, and the difference between the top-surface level of the first layer and the top-surface level of the second layer is less than or equal to 20 nm.

Note that in this specification and the like, the expression “end portions are aligned” means that outlines of stacked layers at least partly overlap with each other in a plan view. For example, the case of processing the upper layer and the lower layer with use of the same mask pattern or mask patterns that are partly the same is included. Note that, in some cases, the outlines do not exactly overlap with each other and the outline of the upper layer is positioned inward from the outline of the lower layer or the outline of the upper layer is positioned outward from the outline of the lower layer; such a case is also represented by the expression “end portions are aligned”.

In general, it is difficult to clearly differentiate being “perfectly aligned” from being “substantially aligned”. Thus, in this specification and the like, the expression being “aligned” includes both being “perfectly aligned” and being “substantially aligned”.

Note that in this specification and the like, “normally-on characteristics” means a state where a channel exists without application of a voltage to a gate and a current flows through the transistor. Furthermore, “normally-off characteristics” mean a state where a current does not flow through a transistor when no potential or a ground potential is applied to a gate.

In this specification and the like, a leakage current sometimes expresses the same meaning as an off-state current. Furthermore, in this specification and the like, the off-state current sometimes refers to a current that flows between a source and a drain of a transistor in an off state, for example.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes described without such identification signs in this specification and the like when the components do not need to be distinguished from each other.

A transistor is a kind of semiconductor element and can achieve a function of amplifying a current or a voltage, a switching operation for controlling electrical continuity or discontinuity, and the like. An IGFET (Insulated Gate Field Effect Transistor) and a thin film transistor (TFT) are in the category of a transistor in this specification and the like.

A “gate” and a “back gate” can be interchanged with each other. Thus, the terms “gate” and “back gate” can be used interchangeably in this specification and the like. Note that a gate and a back gate of a transistor can also be referred to as a gate electrode and a back gate electrode, for example, as appropriate depending on circumstances.

In this specification and the like, the expression “electrically connected” includes the case where components are connected to each other through an “object having any electric action”. There is no particular limitation on an “object having any electric function” as long as electric signals can be transmitted and received between components that are connected through the object. Examples of the “object having any electric function” include a switching element such as a transistor, a resistor, a coil, and other elements with a variety of functions as well as an electrode or a wiring.

Unless otherwise specified, an off-state current in this specification and the like refers to a leakage current between a source and a drain generated when a transistor is in an off state (also referred to as a non-conducting state or a cutoff state). Unless otherwise specified, an off state in an n-channel transistor refers to a state where a voltage V_{gs} between its gate and source is lower than a threshold voltage Vₜₕ (in a p-channel transistor, higher than Vₜₕ).

In this specification and the like, the expression “having substantially the same top surface shapes” means that at least outlines of stacked layers partly overlap with each other. For example, the case of processing the upper layer and the lower layer with use of the same mask pattern or mask patterns that are partly the same is included. However, in some cases, the outlines do not completely overlap with each other and the upper layer is positioned inward from the lower layer or the upper layer is positioned outward from the lower layer; such a case is also represented by the expression “having substantially the same top surface shapes”. The state of “having the same top surface shape” or “having substantially the same top surface shapes” can be rephrased as the state where “end portions are aligned with each other” or “end portions are substantially aligned with each other”.

In this specification and the like, a tapered shape refers to such a shape that at least part of the side surface of a component is inclined with respect to a substrate surface or a formation surface. For example, the tapered shape preferably includes a region where the angle formed by the inclined side surface and the substrate surface or the formation surface (such an angle is also referred to as a taper angle) is less than 90°. Note that the side surface, the substrate surface, and the formation surface of the component are not necessarily completely flat and may have a substantially planar shape with a small curvature or a substantially planar shape with slight unevenness.

In this specification and the like, a device formed using a metal mask or an FMM (fine metal mask, high resolution metal mask) may be referred to as a device having an MM (metal mask) structure. In this specification and the like, a device formed without using a metal mask or an FMM may be referred to as a device having an MML (metal maskless) structure. Note that a device having the MML structure can be manufactured without using a metal mask, and thus can break through the resolution limit due to alignment accuracy of the metal mask. Furthermore, the device having the MML structure can eliminate the need for the manufacturing facilities for metal masks and the washing process for metal masks. In addition, the device having the MML structure can be manufactured at low cost, and thus is suitable for mass production.

In this specification and the like, a structure in which at least light-emitting layers of light-emitting devices (also referred to as light-emitting elements) having different emission wavelengths are separately formed may be referred to as an SBS (Side By Side) structure. The SBS structure can optimize materials and structures of light-emitting devices and thus can extend freedom of choice of materials and structures, whereby the luminance and the reliability can be easily improved.

In this specification and the like, a light-emitting device includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer serving as a photoelectric conversion layer between a pair of electrodes. In this specification and the like, one of the pair of electrodes may be referred to as a pixel electrode and the other may be referred to as a common electrode. Note that the above-described carrier-injection layer, carrier-transport layer, and carrier-blocking layer cannot be clearly distinguished from each other in some cases. One layer may have two or three functions of the carrier-injection layer, the carrier-transport layer, and the carrier-blocking layer in some cases.

In this specification and the like, a sacrificial layer (which may be referred to as a mask layer) is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

### Embodiment 1

In this embodiment, a method for processing a stack including an oxide semiconductor layer and a conductor layer according to one embodiment of the present invention will be described. The stack of one embodiment of the present invention can be used for a transistor, a semiconductor device, and the like.

### <Structure Example of Stack>

The stack of one embodiment of the present invention includes an insulator and a first conductor over the insulator, and the first conductor is a metal oxide, for example. By the method for processing the stack of one embodiment of the present invention, an opening can be provided in the insulator included in the stack. In the method for processing the stack of one embodiment of the present invention, a mask using a second conductor is formed over the first conductor, and then the second conductor is etched using the mask. The second conductor is a metal, for example, and ruthenium or the like can be suitably used as the metal.

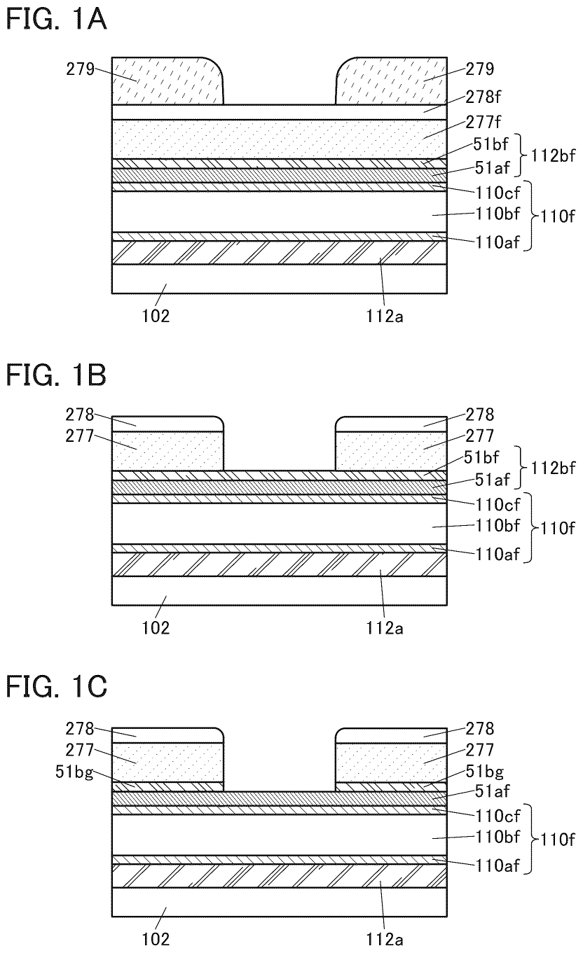

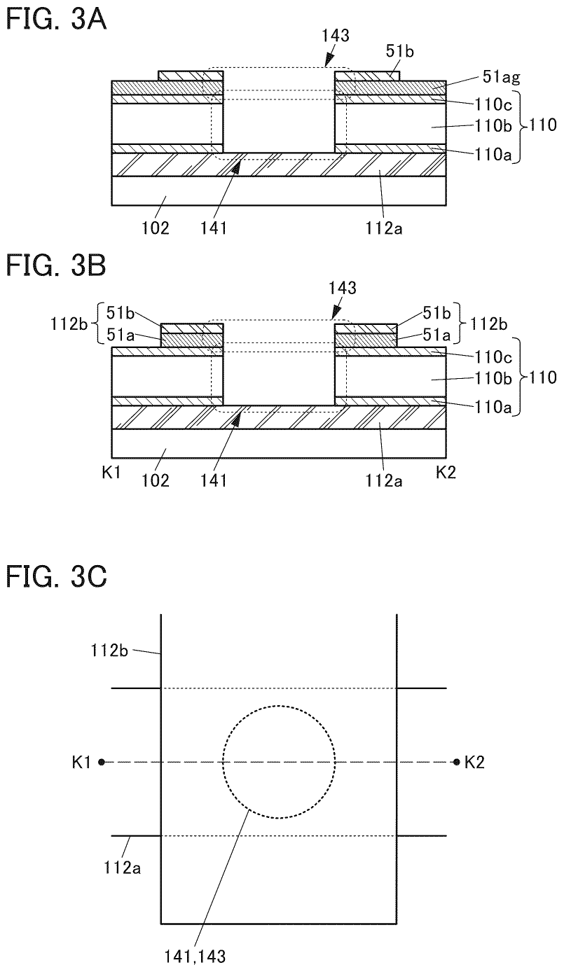

FIG. 1A to FIG. 3A show a method for manufacturing the stack of one embodiment of the present invention, and FIG. 3B and FIG. 3C show an example of a stack formed by the manufacturing method.

FIG. 3C is a top view showing an example of the stack of one embodiment of the present invention. FIG. 3B is a cross-sectional view of a cross section along the dashed-dotted line K1-K2 in FIG. 3C. A structure shown in FIG. 3B and FIG. 3C includes a conductive layer 112a, an insulating layer 110 including an opening 141 over the conductive layer 112a, and a conductive layer 112b over the insulating layer 110. The conductive layer 112b has an opening 143 that overlaps with the conductive layer 112a.

In one embodiment of the present invention, the conductive layer 112b preferably has a stacked-layer structure of a conductive layer 51a and a metal layer 51b over the conductive layer 51a. When the conductive layer 112b includes the metal layer 51b, the resistance in the case where the conductive layer 112b is used as a wiring or the like can be reduced. Moreover, when the conductive layer 112b has a stacked-layer structure of the conductive layer 51a and the metal layer 51b, dry etching treatment using a metal layer (a metal layer 51bg described later) as a hard mask is performed, so that the conductive layer 51a with a favorable shape can be formed.

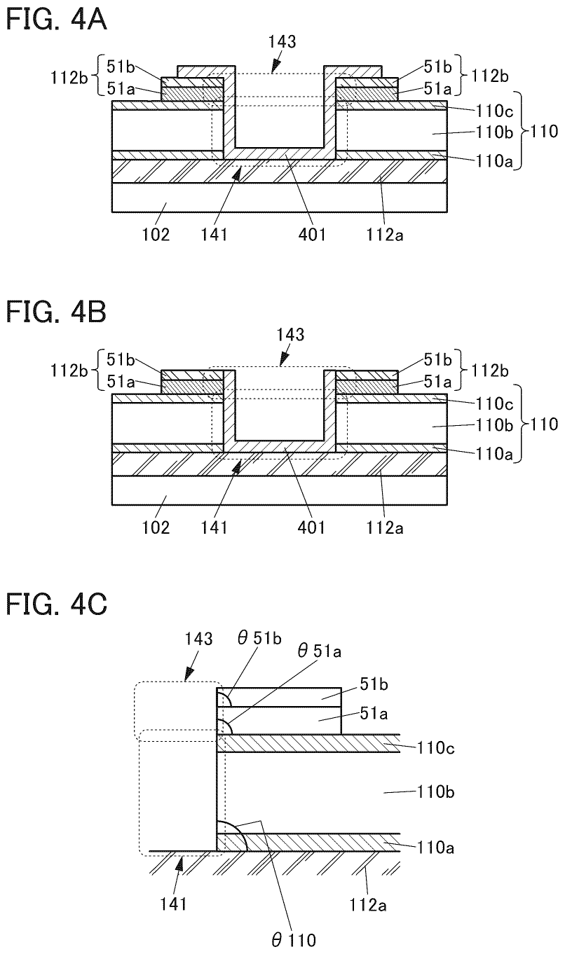

In the stack of one embodiment of the present invention, an angle of the side surface of the conductive layer 112b on the opening 143 side is preferably vertical or substantially vertical. When the side surface on the opening 143 side is vertical, the area occupied by the stack in the top view can be smaller than that in the case where the side surface of the opening 143 has a tapered shape. Accordingly, the area of the transistor using the stack of one embodiment of the present invention can be reduced, so that the semiconductor device can be miniaturized and highly integrated. When the side surface on the opening 143 side is vertical, the area of the top surface of the conductive layer 112a in the opening 143 is increased. Thus, in structures shown later in FIG. 4A, FIG. 4B, and the like, the contact area between a semiconductor layer 401 and the conductive layer 112a can be increased, so that the resistance can be reduced.

In this specification and the like, “parallel” indicates a state where two straight lines are placed at an angle greater than or equal to −10° and less than or equal to 10°, for example. Moreover, “perpendicular” indicates a state where two straight lines are placed at an angle greater than or equal to 80° and less than or equal to 100°, for example.

FIG. 4C is an enlarged view of part of a cross section shown in FIG. 3B. Note that in FIG. 4C, the conductive layer 51a and the metal layer 51b are shown without hatching patterns for easy viewing of an angle θ51a and an angle θ51b. The angle θ51a formed between the side surface of the conductive layer 51a on the opening 143 side and the formation surface of the conductive layer 51a (here, the top surface of an insulating layer 110c) can be, for example, greater than or equal to 30°, greater than or equal to 35°, greater than or equal to 40°, greater than or equal to 45°, greater than or equal to 50°, greater than or equal to 55°, greater than or equal to 60°, greater than or equal to 65°, greater than or equal to 70°, or greater than or equal to 75° and less than or equal to 90°, less than or equal to 85°, or less than or equal to 80°.

The angle θ51a is preferably 90° or an angle in the vicinity of 90°. For example, the angle θ51a is preferably greater than or equal to 75° and less than or equal to 90°.

The angle θ51a is sometimes less than 75°, less than 70°, less than 65°, or less than 60°.

The angle θ51b formed between the side surface of the metal layer 51b on the opening 143 side and the formation surface of the metal layer 51b (here, the top surface of the conductive layer 51a) can be greater than or equal to 30°, greater than or equal to 35°, greater than or equal to 40°, greater than or equal to 45°, greater than or equal to 50°, greater than or equal to 55°, greater than or equal to 60°, greater than or equal to 65°, greater than or equal to 70°, or greater than or equal to 75° and less than or equal to 90°, less than or equal to 85°, or less than or equal to 80°.

The angle θ51b is preferably 90° or an angle in the vicinity of 90°. For example, the angle θ51b is preferably greater than or equal to 75° and less than or equal to 90°.

The angle θ51b is sometimes less than 75°, less than 70°, less than 65°, or less than 60°.

Note that the angle θ51a may be an angle between the side surface of the conductive layer 51a on the opening 143 side and the top surface of the conductive layer 112a. The angle θ51b may be an angle between the side surface of the metal layer 51b on the opening 143 side and the top surface of the conductive layer 112a.

In the stack of one embodiment of the present invention, not only the side surface of the conductive layer 112b on the opening 143 side but also the side surface of the insulating layer 110 on the opening 141 side is preferably vertical. When the side surface of the opening 143 and the side surface on the opening 141 side are each vertical, the area occupied by the stack in the top view can be smaller than that in the case where the side surface of the opening 143 and the side surface of the opening 141 each have a tapered shape. Accordingly, the area of the transistor using the stack of one embodiment of the present invention can be reduced, so that the semiconductor device can be miniaturized and highly integrated. An angle θ110 between the side surface of an insulating layer 110b on the opening 141 side and the formation surface of the insulating layer 110b (here, the top surface of an insulating layer 110a) can be greater than or equal to 30°, greater than or equal to 35°, greater than or equal to 40°, greater than or equal to 45°, greater than or equal to 50°, greater than or equal to 55°, greater than or equal to 60°, greater than or equal to 65°, greater than or equal to 70°, or greater than or equal to 75° and less than or equal to 90°, less than or equal to 85°, or less than or equal to 80°.

The angle θ110 is preferably 90° or an angle in the vicinity of 90°. For example, the angle θ51a is preferably greater than or equal to 75° and less than or equal to 90°.

The angle θ110 is sometimes less than 75°, less than 70°, less than 65°, or less than 60°.

Note that when the side surfaces of the opening 143, the opening 141, and the like are vertical, a sidewall insulating layer along the side surfaces can be provided. Specifically, the sidewall insulating layer can be provided by anisotropic etching or the like such that the insulating layer remains only in a region along a sidewall.

In the case where a structure body shown in FIG. 3B or the like is used for a transistor, a semiconductor layer of the transistor can be provided so as to be in contact with the top surface or the like of the metal layer 51b included in the structure body, for example.

FIG. 4A shows an example in which the semiconductor layer 401 is provided in the opening 141 and the opening 143 and over the conductive layer 112b which are included in the structure body shown in FIG. 3B. In FIG. 4A, the semiconductor layer 401 is in contact with, for example, the top surface of the conductive layer 112a, the side surface of the insulating layer 110 on the opening 141 side, the side surface of the conductive layer 51a on the opening 143 side, the side surface of the metal layer 51b on the opening 143 side, and the top surface of the metal layer 51b.

The semiconductor layer 401 is not necessarily provided on the top surface of the metal layer 51b. FIG. 4B shows an example in which a semiconductor layer 108 is not provided over the conductive layer 112b and is provided in the opening 141 and the opening 143. In FIG. 4B, the semiconductor layer 401 is in contact with, for example, the top surface of the conductive layer 112a, the side surface of the insulating layer 110 on the opening 141 side, the side surface of the conductive layer 51a on the opening 143 side, and the side surface of the metal layer 51b on the opening 143 side.

The conductive layer 112b is preferably used for a source electrode, a drain electrode, or the like of the transistor, and the conductive layer 112b preferably has low contact resistance with the semiconductor layer 401. Note that after the conductive layer 112b is further processed and divided into a plurality of conductive layers, each of the conductive layers may be used for a source electrode, a drain electrode, or the like of the transistor.

The contact resistance between the metal layer 51b and the semiconductor layer is preferably low. For example, ohmic contact between the surface of the metal layer 51b and the semiconductor layer is preferably made. In the case where a metal oxide is used for the semiconductor layer 401, the use of a metal that is easily oxidized for the metal layer 51b forms an insulating oxide between the metal layer 51b and the semiconductor layer, which might inhibit electrical continuity between the metal layer 51b and the semiconductor layer. Thus, the metal layer 51b is preferably formed using a conductive material that is less likely to be oxidized or a conductive material that maintains low electrical resistance even after being oxidized. In the case where a metal oxide is used for the semiconductor layer 401 of the transistor, ruthenium can be suitably used for a metal film 51bf.

In each of the structures shown in FIG. 4A and FIG. 4B, the semiconductor layer 401 is preferably in contact with the side surface of the conductive layer 51a; when a conductive material that is less likely to be oxidized or a conductive material that maintains low electrical resistance even after being oxidized is used for the conductive layer 51a, the contact resistance between the semiconductor layer 401 and the conductive layer 51a can be suitably reduced.

### <Processing Method Example of Stack>

Specific examples of processing of the stack including the conductive layer 112a, the insulating layer 110 of the conductive layer 112a, and the conductive layer 112b over the insulating layer 110 are described below with reference to FIG. 1A to FIG. 3C. The insulating layer 110 has the opening 141 in a region overlapping with the conductive layer 112a. The conductive layer 112b has the opening 143 in the region overlapping with the conductive layer 112a.

In the steps of FIG. 1B to FIG. 3C, processing by a dry etching method is preferably performed. A dry etching method enables anisotropic etching and thus is suitable for forming a stack having a minute structure including an opening having a vertical side surface with a high aspect ratio.

As an etching gas for the dry etching treatment, for example, a gas including a halogen can be used.

As the gas including a halogen, for example, an etching gas including one or more of fluorine, chlorine, and bromine can be used. A fluorocarbon gas, a hydrofluorocarbon gas, a SF₆ gas, a Cl₂ gas, a BCl₃ gas, a SiCl₄ gas, a BBr₃ gas, or the like can be used alone or two or more of the gases can be mixed and used. As the fluorocarbon gas, a gas represented by CₓF_{y} (y≤2x+2) can be used. Examples of the fluorocarbon gas satisfying y=2x+2 include saturated carbon fluoride compounds such as CF₄, C₂F₆, C₃F₈, C₄F₁₀, and C₅F₁₂. Examples of the fluorocarbon gas satisfying y<2x+2 include unsaturated carbon fluoride compounds such as C₂F₄, C₂F₂, C₃F₇, C₃F₄, C₄F₈, C₄F₆, C₄F₄, C₄F₂, C₅F₁₀, C₅F₈, C₅F₆, and C₅F₄. Examples of the hydrofluorocarbon gas include a CHF₃ gas and a CH₂F₂ gas.

In the case where the gas including a halogen is used as the etching gas, an oxygen (O₂) gas, a carbonic acid gas, a nitrogen (N₂) gas, a helium gas, an argon gas, a hydrogen gas, a hydrocarbon gas, or the like can be added as appropriate.

A gas that includes a hydrocarbon gas or a hydrogen gas and does not include a halogen gas can be used as the etching gas.

As the hydrocarbon gas, one or more of methane (CH₄), ethane (C₂H₆), propane (C₃H₈), butane (C₄H₁₀), ethylene (C₂H₄), propylene (C₃H₆), acetylene (C₂H₂), and propyne (C₃H₄) can be used.

Note that in the case where the hydrocarbon gas is used as the etching gas, a nitrogen gas, a helium gas, an argon gas, a hydrogen gas, or the like can be added as appropriate.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example. The etching apparatus can be set as appropriate depending on an object to be etched.

Note that with the use of a multi-chamber etching apparatus, at least some of the steps of FIG. 1B to FIG. 3C can be successively performed without exposure to the air.

First, the conductive layer 112a, an insulating film 110f, and a conductive film 112bf are formed in this order over a substrate 102 (FIG. 1A). Here, the insulating film 110f is an insulating film to be the insulating layer 110 in a later step. The conductive film 112bf is a conductive film to be the conductive layer 112b in a later step.

The insulating film 110f includes an insulating film 110af, an insulating film 110bf over the insulating film 110af, and a 110cf over the insulating film 110bf. The insulating film 110af is a film to be the insulating layer 110a in a later step, the insulating film 110bf is a film to be the insulating layer 110b in a later step, and the insulating film 110cf is a film to be the insulating layer 110c in a later step.

The conductive film 112bf includes a conductive film 51af and the metal film 51bf over the conductive film 51af. The conductive film 51af is a film to be the conductive layer 51a in a later step, and the metal film 51bf is a film to be the metal layer 51b in a later step.

The metal film 51bf can be formed by a sputtering method, a CVD method, an MBE method, a PLD method, or an ALD method, for example. In particular, the use of a sputtering method enables the film formation to be performed with high mass productivity. The metal layer 51b formed using the metal film 51bf is a film serving as a hard mask for forming the conductive layer 51a and the insulating layer 110 in a later step. After being used as a hard mask, the metal layer 51b can be left to be used as a conductive layer serving as an electrode, a wiring, or the like.

For the metal film 51bf, one or more of ruthenium, tantalum, nickel, titanium, molybdenum, tungsten, hafnium, vanadium, niobium, aluminum, chromium, copper, silver, gold, platinum, zinc, manganese, iron, cobalt, magnesium, zirconium, beryllium, indium, iridium, strontium, and lanthanum, an alloy including one or more of these metals as its components, or the like can be used.

Furthermore, ruthenium, titanium, and an alloy thereof can each be suitably used as a conductive material that is less likely to be oxidized or a material that maintains low electrical resistance even after being oxidized.

For the metal film 51bf, ruthenium can be suitably used. Ruthenium has high etching selectivity with respect to the conductive film 51af described later and can thus be suitably used as a hard mask. Moreover, ruthenium is a material having favorable contact resistance with a metal oxide and can be suitably used for the metal film 51bf. Furthermore, since the oxide of ruthenium also has conductivity, ruthenium has favorable conductivity and thus can be suitably used even in the case where the surface is oxidized in the manufacturing process, for example.

For example, a film of ruthenium formed by a sputtering method can be used as the metal film 51bf. After the formation of the conductive film 51af, the metal film 51bf may be successively formed without exposure to the air.

The conductive film 51af can be formed by a sputtering method, a CVD method, an MBE method, a PLD method, an ALD method, or the like. In particular, the use of a sputtering method enables the film formation to be performed with high mass productivity.

For the conductive film 51af, a conductive metal oxide (an oxide conductor) can be used.

As the oxide conductor (OC, also referred to as a conductive material including oxygen), a conductive oxide including indium can be used. Examples of the conductive oxide including indium include indium oxide, In—Sn oxide (ITO), In—Zn oxide, In—W oxide, In—W—Zn oxide, In—Ti oxide, In—Ti—Sn oxide, In—Sn—Si oxide (also referred to as indium tin oxide to which silicon is added, ITO including silicon, or ITSO), and In—Ga—Zn oxide. As the oxide conductor, zinc oxide and zinc oxide to which gallium is added can be used. As the oxide conductor, ruthenium oxide, an oxide including strontium and ruthenium, and an oxide including lanthanum and nickel can also be used, for example. A conductive oxide including indium is particularly preferable because of its high conductivity. In this specification and the like, a conductive film formed using the oxide conductor may be referred to as an oxide conductive film.

The oxide conductor is a material having favorable contact resistance with the oxide semiconductor. Thus, the oxide conductor can be suitably used for the conductive film 51af.

Furthermore, for the conductive film 51af, a nitride conductor (also referred to as a conductive metal nitride or a conductive material including nitrogen) can be used. In some cases, tantalum nitride, a nitride including tantalum, a nitride including tantalum and aluminum, titanium nitride, a nitride including titanium, a nitride including titanium and aluminum, ruthenium nitride, a nitride including ruthenium, molybdenum nitride, a nitride including molybdenum, tungsten nitride, a nitride including tungsten, or the like can be used as the nitride conductor depending on its conductivity.

When formed using an oxide conductor or a nitride conductor, the conductive film 51af sometimes functions as a protective film for the insulating layer 110 when a mask used for processing, e.g., a mask formed using SOG (Spin On Glass) or the like is removed after the formation of a metal layer with the use of the metal film 51bf.

Next, a coating film 277f is formed over the metal film 51bf, and a coating film 278f is formed over the coating film 277f (FIG. 1A). The coating film 277f and the coating film 278f may have a function of improving adhesion between a later-described resist mask and the metal film 51bf. The coating film 277f may have a function of improving adhesion between the coating film 278f and the metal film 51bf. The coating film 277f and the coating film 278f are formed by a spin coating method or the like, for example. For the coating film 277f and the coating film 278f, a non-photosensitive organic resin is used.

Here, the coating film 278f functions as a mask in etching treatment for processing the coating film 277f. Thus, the etching rate of the coating film 278f is preferably lower than the etching rate of the coating film 277f under the etching conditions of the coating film 277f. For example, the coating film 277f is a film including carbon, and the coating film 278f is a film including silicon and carbon. Specifically, for example, a film including silicon, oxygen, and carbon can be used as the coating film 278f. For example, a film including a polymer including silicon and oxygen can be used. In this embodiment, an SOC (Spin On Carbon) film is formed as the coating film 277f, and an SOG film is formed as the coating film 278f. As the SOG film, for example, a film including polysiloxane can be formed by a spin coating method.

Note that the coating film 277f and the coating film 278f each include an organic solvent such as alcohol, ethel, or the like at the time of application, but an organic substance contained may be reduced or removed in later steps or at the completion of a semiconductor device. For example, when the SOG film is used as the coating film 278f and treatment such as heat treatment is performed after the application, an inorganic insulating film can sometimes be formed depending on the components of the SOG film, the conditions of the treatment, and the like. Note that the coating films are provided as necessary; the coating film may be a single layer, or a structure without the coating films may be employed in the case where the later-described resist mask alone functions sufficiently.

Next, a resist mask 279 is formed over the coating film 278f by a lithography method (FIG. 1A). A photosensitive organic resin, which is also called a photoresist, is used for the resist mask 279. For example, a positive photoresist or a negative photoresist can be used. The photoresist to be the resist mask 279 can be formed by a spin coating method or the like, for example, to have a uniform thickness.

Note that in a lithography method, first, a resist is exposed to light through a mask. Next, a region exposed to light is removed or left using a developing solution, so that a resist mask is formed. Then, etching treatment through the resist mask is conducted, whereby a conductor, a semiconductor, an insulator, or the like can be processed into a desired shape. The resist mask can be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that the use of a mask may be unnecessary in the case of using an electron beam or an ion beam.

Note that heat treatment may be performed after the application of the coating film 277f, the coating film 278f, and a film to be the resist mask 279. For example, the heat treatment is performed at 60° C. or higher.

First, the coating film 278f is processed using the resist mask 279, whereby a coating film 278 including an opening is formed. In the case where the SOG film is used as the coating film 278f, for example, a fluorocarbon gas, a hydrofluorocarbon gas, or the like can be used; specifically, CF₄, CHF₃, or the like can be used as an etching gas, for example. An oxygen gas, a nitrogen gas, an argon gas, a helium gas, or the like can also be used.

Next, the coating film 277f is processed using the coating film 278 as a mask, whereby a coating film 277 including an opening is formed (FIG. 1B). For example, in the case where an SOC film is used as the coating film 277f, an H₂ gas and an N₂ gas can be used as etching gases. Oxygen and nitrogen, carbon dioxide and carbon monoxide, or the like may be used as the etching gases. Here, since the SOG film is used as the coating film 278, the coating film 278 can be prevented from disappearing in the etching step of the coating film 277f.

The resist mask 279 is preferably removed simultaneously during the processing of the coating film 277f. The use of an organic film including carbon, such as the SOC film, as the coating film 277f facilitates removal of the resist mask 279. In the case where the resist mask 279 remains after the formation of the coating film 277, the resist mask 279 is preferably removed.

Next, the metal film 51bf is processed to form the metal layer 51bg including an opening (FIG. 1C). A dry etching method enables anisotropic etching capable of processing the side surface to have an angle vertical or nearly vertical, and thus a dry etching method is preferably used as an etching method for the metal film 51bf.

The metal film 51bf can be processed using the coating film 278 and the coating film 277 as masks. In particular, in the case of using, for the metal film 51bf, a conductive material that is less likely to be oxidized or a material that maintains low electrical resistance even after being oxidized, such as ruthenium, the coating film 278 is preferably used as a mask.

As described later, ruthenium enables processing with an etching gas including O₂. In the case where SOC is used as the coating film 277, the etching rate with an etching gas including an O₂ gas is difficult to lower in some cases. When SOG is used as the coating film 278, the etching rate with the etching gas including an O₂ gas can be sufficiently low. Thus, the metal film 51bf is preferably processed using the coating film 278 as a mask.

For the etching conditions of the metal film 51bf, a condition having high selectivity with respect to the mask is used. In particular, a condition with high selectivity with respect to the coating film 278 is preferably used. Here, high selectivity refers to a condition used for the etching where the etching rate of the metal film 51bf is higher than that of the coating film 278. Specifically, for example, the etching rate of the metal film 51bf is preferably higher than or equal to 1.5 times, further preferably higher than or equal to 2.5 times, still further preferably higher than or equal to 3.5 times the etching rate of the coating film 278.

The metal film 51bf is preferably processed by a dry etching method. In the case where SOG is used as the coating film 278f and a ruthenium film is used as the metal film 51bf, the selectivity in the dry etching treatment can be increased with the use of an oxygen (O₂) gas as an etching gas. The selectivity in the dry etching treatment can be further increased with the use of an oxygen (O₂) gas and a chlorine (Cl₂) gas as etching gases.

In the dry etching treatment on the metal film 51bf, etching is preferably performed using an O₂ gas or an O₂ and a Cl₂ gas in a chamber under a pressure higher than or equal to 0.5 Pa and lower than or equal to 50 Pa. As the process temperature of the dry etching, the temperature of a lower electrode is preferably higher than or equal to −20° C. and lower than or equal to 200° C. Note that the lower electrode is an electrode positioned on the side where a substrate subjected to the dry etching treatment is provided.

An inductively coupled plasma etching apparatus can be used for the dry etching treatment on the metal film 51bf, for example.

In the case where an O₂ and a Cl₂ gas are used as the etching gases, the flow rate ratio of the O₂ gas is preferably higher than or equal to 50 [%] and lower than 100 [%], further preferably higher than or equal to 70% and lower than or equal to 95% when the sum of flow rates of the 02 gas and the Cl₂ gas is set to 100 [%].

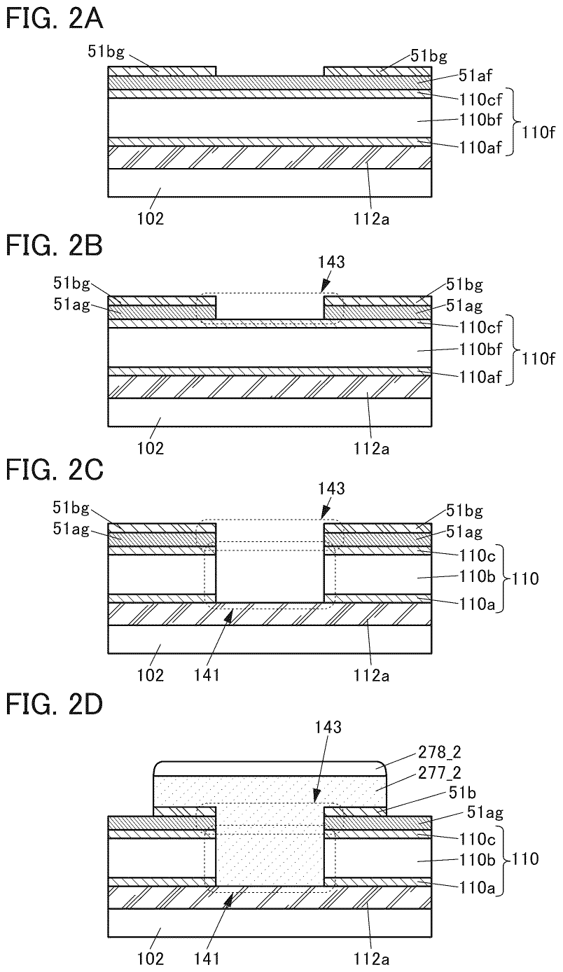

Next, the coating film 278 is removed. For the removal of the coating film 278, for example, the etching conditions used for processing the coating film 278f can be used as appropriate. Subsequently, the coating film 277 is removed (FIG. 2A). For the removal of the coating film 277, for example, the etching conditions used for processing the coating film 277f can be used as appropriate.

Next, the conductive film 51af is processed by a dry etching method using the metal layer 51bg as a hard mask to form a conductive layer 51ag including an opening (FIG. 2B). When a dry etching method is used as an etching method for the conductive film 51af, the side surface can be processed to have an angle vertical or nearly vertical.

Note that the etching rate of the oxide conductor in a dry etching method may be low. In the case where the etching rate is low, the amount of a generated reaction product is increased with an increase in the etching time, for example. In particular, in the case where a film including a large amount of organic substance, such as a resist or SOC (Spin On Carbon), is used as an etching mask, a reaction product is likely to be attached to a side wall of the mask. A reaction product that remains after the removal of the mask (referred to as a rabbit ear in some cases) might provoke a decrease in coverage with a film formed in a later step, for example, which might cause a decrease in reliability of the semiconductor device.

Dry etching treatment on the conductive film 51af using the metal layer 51bg as a hard mask is preferable, in which case generation of a reaction product can be inhibited. A wet etching method is sometimes used to remove the reaction product. In the wet etching treatment, not only the reaction product but also the conductive film 51af is etched in some cases. Since the wet etching method is isotropic etching, it is difficult to process the side surface of a conductive film to be vertical. In the case where the side surface of the conductive film 51af cannot be processed to be vertical, the side surface of the metal layer 51b and the side surface of the conductive layer 51a are not aligned with each other, and a step is generated between the side surface of the conductive layer 51a and the side surface of the metal layer 51b, for example. Such a step might reduce the coverage with the semiconductor layer 401 and the coverage with the layers formed later.

When the conductive film 51af is etched using the metal layer 51bg as a hard mask, dry etching treatment can be performed while generation of a reaction product is inhibited, so that the side surface of the conductive layer 51ag can be processed to have a vertical shape.

Here, for example, in the case where ITSO is used for the conductive film 51af, a hydrocarbon gas such as a CH₄ gas or a fluorocarbon gas such as a CHF₃ gas can be used as an etching gas in the dry etching treatment, for example. Here, for example, CH₄ is used.

It is preferable to use an oxide conductive film as the conductive film 51af and to use ruthenium as the metal layer 51bg, in which case the selectivity under the etching conditions of the conductive film 51af can be particularly increased. The increase in the selectivity can inhibit the disappearance and deformation of the metal layer 51bg, for example. Here, for example, the etching rate of the conductive film 51af is preferably higher than or equal to 5 times, further preferably higher than or equal to 10 times the etching rate of the metal layer 51bg. Here, the thickness of the metal layer 51b is, for example, greater than or equal to 1 nm and less than or equal to 100 nm, and is preferably greater than or equal to 8 nm and less than or equal to 35 nm. The thickness of the conductive layer 51a is, for example, greater than or equal to 1 nm and less than or equal to 70 nm, and is preferably greater than or equal to 3 nm and less than or equal to 25 nm.

In the dry etching treatment on the conductive film 51af, etching is preferably performed using an CH₄ gas in a chamber under a pressure higher than or equal to 0.5 Pa and lower than or equal to 10 Pa. As the process temperature of the dry etching, the temperature of the lower electrode is preferably higher than or equal to −10° C. and lower than or equal to 200° C.

For the dry etching treatment on the conductive film 51af, a capacitively coupled plasma etching apparatus including parallel plate electrodes can be used.

In the case where a CH₄ gas is used as the etching gas and an argon gas is further added to the etching gas, the flow rate ratio of the argon gas can be higher than or equal to 20 [%] and lower than or equal to 95 [%], for example, when the sum of flow rates of the CH₄ gas and the argon gas is set to 100 [%].

Next, the insulating film 110f is processed using the metal layer 51bg as a mask to form the insulating layer 110 including the opening 141 (FIG. 2C). By performing dry etching treatment on the insulating film 110f using the metal film 51bf as a hard mask, generation of a reaction product can be inhibited and the side surface of the insulating layer 110 on the opening 141 side can be processed to be vertical.

The insulating film 110f preferably includes one or more inorganic insulating films. Examples of a material usable for the inorganic insulating film include an oxide, a nitride, an oxynitride, and a nitride oxide. Note that in this specification and the like, an oxynitride refers to a material that includes more oxygen than nitrogen in its composition. A nitride oxide refers to a material that includes more nitrogen than oxygen in its composition.

Examples of the oxide include an oxide of silicon, aluminum, magnesium, gallium, germanium, yttrium, zirconium, lanthanum, neodymium, hafnium, tantalum, or cerium, gallium zinc oxide, and hafnium aluminate. Examples of the nitride include a nitride of silicon or aluminum. Examples of the oxynitride include an oxynitride of silicon, aluminum, gallium, yttrium, or hafnium. Examples of the nitride oxide include a nitride oxide of silicon or aluminum.

In the case where silicon oxide, silicon oxynitride, silicon nitride oxide, or silicon nitride is used for the insulating layer 110, a gas including a fluorocarbon gas, a hydrofluorocarbon gas, or the like can be used as an etching gas in the dry etching treatment, for example. Specifically, a mixed gas of C₄F₈, C₄F₆, and O₂ can be used, for example.

Next, as a mask for etching part of the metal layer 51bg, a coating film 277_2 is formed over the metal layer 51bg, in the opening 141, and in the opening 143, and a coating film 278_2 over the coating film 277_2 is formed (FIG. 2D). For a material and a formation method usable for the coating film 277_2, the coating film 277 can be referred to. For a material and a formation method usable for the coating film 278_2, the coating film 278 can be referred to.

Next, part of the metal layer 51bg is removed using the coating film 278_2 and the coating film 277_2 as masks to form the metal layer 51b. Subsequently, the coating film 278_2 is removed.

Here, when an oxide conductor or a nitride conductor is used for the conductive film 51af, the etching rate of the conductive film 51af can be sufficiently lower than the etching rate of the coating film 278_2 in the removal of the coating film 278_2. Accordingly, the surface of the insulating layer 110 can be inhibited from being exposed at the time of the removal of the coating film 278_2. In the case where SOG is used as the coating film 278_2, the etching selectivity with respect to the insulating layer 110 becomes low in some cases. Thus, the surface of the insulating layer 110 is preferably inhibited from being exposed.

Next, the coating film 277_2 is removed (FIG. 3A).

Subsequently, part of the conductive layer 51ag is etched using the metal layer 51b as a mask to form the conductive layer 51a, whereby the conductive layer 112b in which the conductive layer 51a and the metal layer 51b are stacked is obtained (FIG. 3B). The etching conditions of the metal film 51bf and the conductive film 51af can be used as the etching conditions of the conductive layer 51ag and part of the metal layer 51bg, for example.

As described above, a stack including the conductive layer 112a, the insulating layer 110 including the opening 141 over the conductive layer 112a, and the conductive layer 112b over the insulating layer 110 can be formed as shown in FIG. 3B. Manufacturing a transistor using such a stack having a minute structure can achieve miniaturization and high integration of a semiconductor device.

When the conductive layer 51ag and the insulating layer 110 are formed using the metal layer 51bg as a mask, the side surfaces of the opening 143 and the opening 141 can each be vertical or inclined substantially vertically. Accordingly, the sizes of the opening 143 and the opening 141 can be smaller than in the case where the side surfaces of the opening 143 and the opening 141 each have a tapered shape. Thus, the area of the transistor using the stack shown in FIG. 3B and the like can be reduced, so that the semiconductor device can be miniaturized and highly integrated.

When the conductive layer 51ag and the insulating layer 110 are formed using the metal layer 51bg as a mask, generation of a reaction product in etching for the conductive layer 51ag and the insulating layer 110 can be inhibited. Thus, the reliability of the transistor can be increased, and the performance of the semiconductor device can be improved. Furthermore, the manufacturing process of the transistor can be stabilized, and the productivity of the semiconductor device can be improved.

### <Processing Method Example 2 of Stack>

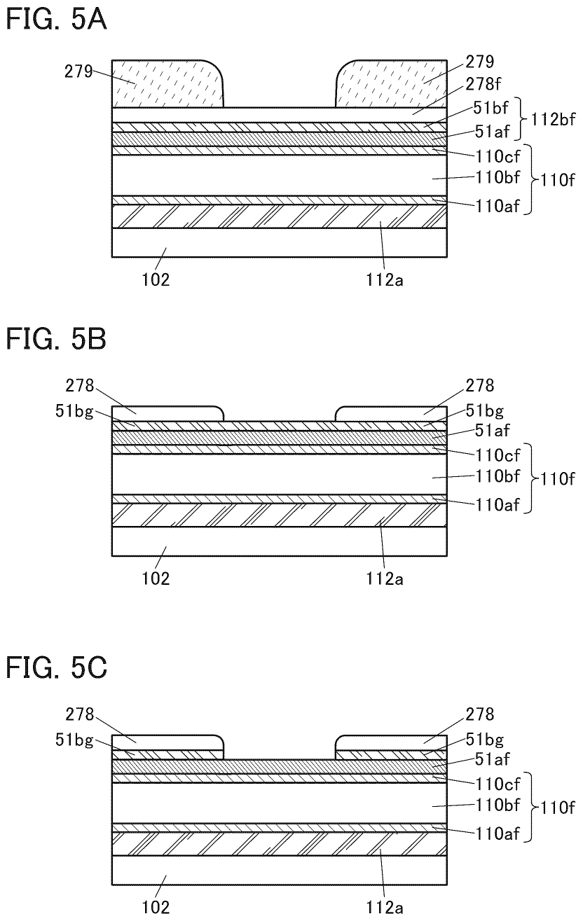

Although FIG. 1A to FIG. 1C show an example in which the coating film 277f is formed over the metal film 51bf and the coating film 278f is provided over the coating film 277f, a structure in which the coating film 278f is provided over the metal film 51bf and the coating film 277f is not used may be employed as shown in FIG. 5A to FIG. 5C.

As described with reference to FIG. 1C and the like, in the etching conditions of the processing of the metal film 51bf, selectivity with respect to the coating film 278 is preferably high. Meanwhile, in the etching conditions, selectivity with respect to the coating film 277 is not sufficiently high in some cases. In such a case, an end portion of the coating film 277 sometimes recedes more than an end portion of the coating film 278. To prevent this, for example, a structure including no coating film 277 is employed, in which case the shape of the metal layer 51b can sometimes be further improved.

First, layers up to the metal film 51bf are formed by a method similar to that in the above-described processing method example 1. Next, the coating film 278f is formed over the metal film 51bf. Subsequently, the resist mask 279 is formed over the coating film 278 by a lithography method (FIG. 5A).

Next, the coating film 278f is processed using the resist mask 279 to form the coating film 278 including an opening (FIG. 5B).

Subsequently, the metal film 51bf is processed using the coating film 278 as a mask to form the metal layer 51bg including an opening (FIG. 5C).

Next, the coating film 278 is removed, so that the structure shown in FIG. 2A can be manufactured. Subsequently, the step shown in FIG. 2A and the subsequent steps are performed, whereby the stack of one embodiment of the present invention can be formed.

### <Processing Method Example 3 of Stack>

The coating film 278 may be removed after the conductive layer 51ag.

First, the metal layer 51bg including an opening is formed by the method described with reference to FIG. 5A to FIG. 5C.

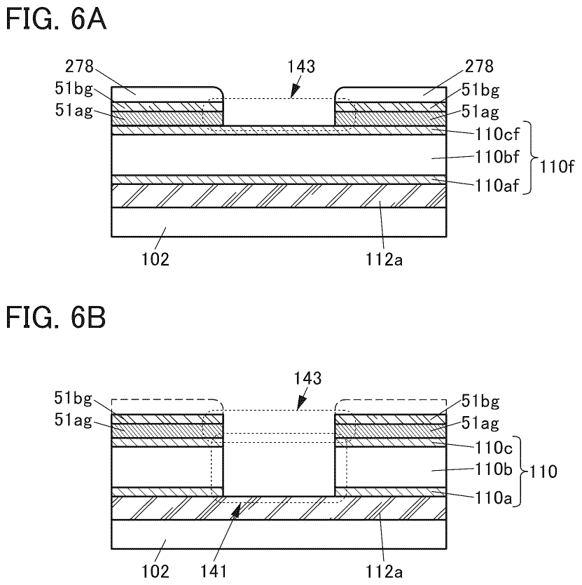

After that, without removing the coating film 278, the conductive film 51af is processed by dry etching using the coating film 278 and the metal layer 51bg as masks, so that the conductive layer 51ag is formed (FIG. 6A).

Next, dry etching is performed on the insulating film 110f. Here, removal of the coating film 278 is preferably performed at the same time as the processing of the insulating film 110f. For example, when the insulating film 110f is formed using silicon oxide, silicon oxynitride, or the like and a polymer including silicon and oxygen is used for the coating film 278f, the removal of the coating film 278 can be performed at the same time.

After that, the step shown in FIG. 2D and the subsequent steps are performed, whereby the stack of one embodiment of the present invention can be formed.

When the coating film 278 is left in the dry etching of the conductive film 51af and at the start of the dry etching of the insulating film 110f, the surface of the metal layer 51bg can be protected in the dry etching steps. Thus, for example, a reduction in the thickness of the metal layer 51bg, film floating, a change in the quality of the surface, and the like in the dry etching can be inhibited.

### <Structure Example 2 of Stack>

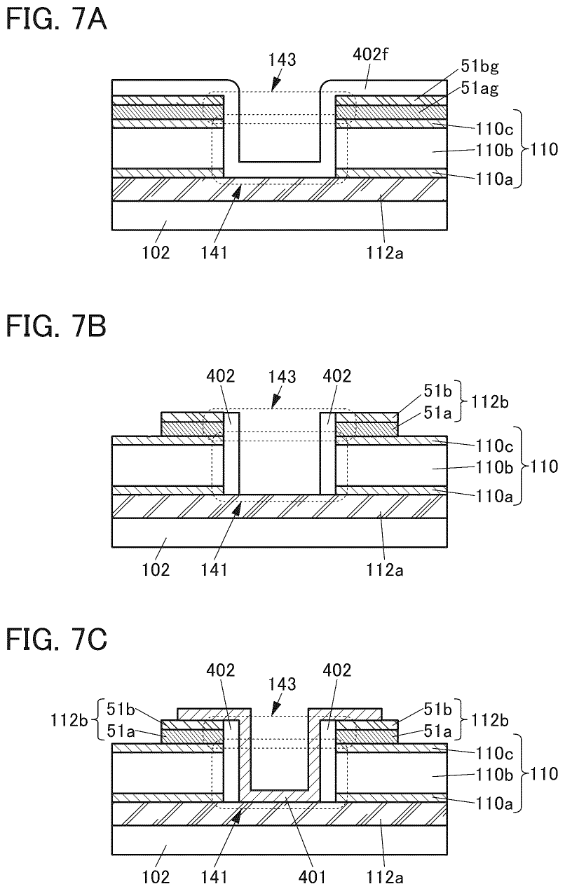

As shown in FIG. 7B, an insulating layer 402 can be provided along the side surface of the opening 143 in the conductive layer 112b and the side surface of the opening 141 in the insulating layer 110.

A method for manufacturing the insulating layer 402 is described with reference to FIG. 7A.

First, after the manufacturing steps shown in FIG. 1A to FIG. 2C are performed, an insulating film 402f is formed to cover the top surface of the metal layer 51bg, the side surface of the opening 143, and the side surface of the opening 141 (FIG. 7A). Next, the insulating layer 402 is formed along the side surface of the opening 143 and the side surface of the opening 141 by anisotropic etching. When the side surface of the opening 143 and the side surface of the opening 141 are vertical, the insulating film 402f can be left in a region along the side surface of the opening 143 and the side surface of the opening 141 and can be removed in another region, by anisotropic etching.

After that, the conductive layer 51ag and the metal layer 51bg are processed to form the conductive layer 51a and the metal layer 51b, whereby the structure shown in FIG. 7B can be manufactured.

FIG. 7C shows an example in which the semiconductor layer 401 is provided in the opening 141 and the opening 143 and over the conductive layer 112b which are included in the structure body shown in FIG. 7B.

In the structure shown in FIG. 7C, the insulating layer 402 can be provided between the semiconductor layer 401 and the side surface of the opening 143 in the conductive layer 112b and between the semiconductor layer 401 and the side surface of the opening 141 in the insulating layer 110. When an insulating layer having a barrier property against impurities such as hydrogen is used as the insulating layer 402, diffusion of impurities included in the insulating layer 110 into the semiconductor layer 401 can be inhibited.

### <Structure Example 3 of Stack>

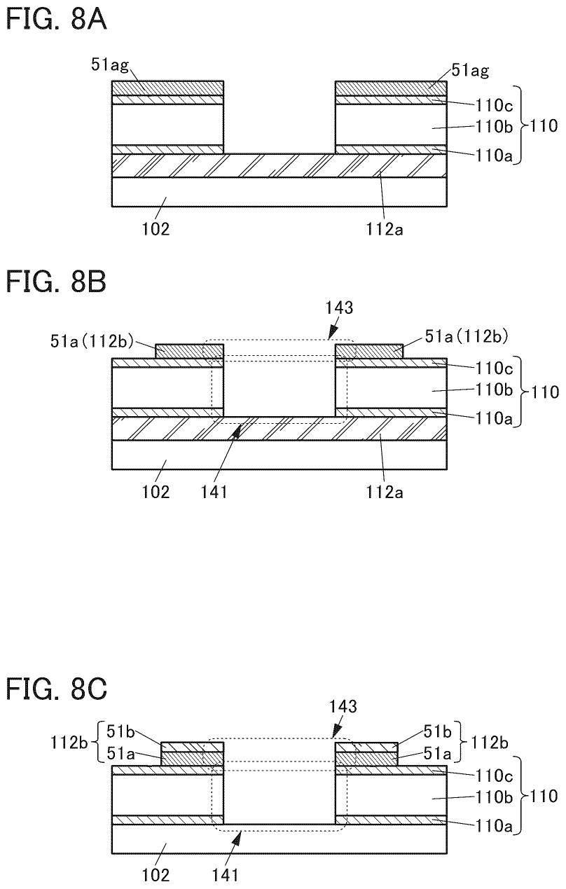

As shown in FIG. 8B, the conductive layer 112b may have a single-layer structure of the conductive layer 51a. In that case, the metal layer 51bg is removed after the structure in FIG. 2C is formed (FIG. 8A). Then, part of the conductive layer 51ag is removed using a resist mask or the like, so that the structure shown in FIG. 8B can be manufactured. Alternatively, the metal layer 51b can be removed after the structure in FIG. 3B is formed, so that the structure shown in FIG. 8B can be manufactured.

In the case where a ruthenium film is used as the metal film 51bf, O₂, or O₂ and Cl₂ can be used as an etching gas to remove the metal layer 51bg or the metal layer 51b, for example. For the etching conditions used for the removal of the metal layer 51bg or the removal of the metal layer 51b, it is preferable to use a condition with high selectivity with respect to the conductive layer 51ag or the conductive layer 51a.

When the metal layer 51bg or the like is used for the processing for the conductive layer 51a and then the metal layer 51bg is removed, the semiconductor layer provided on the top surface of the conductive layer 112b and the conductive layer 51a can be in contact with each other; when a material with low contact resistance with the semiconductor layer is used for the conductive layer 51a, the contact resistance between the conductive layer 51a and the semiconductor layer can be reduced. In addition, the conductive layer 51a having a favorable shape can be obtained.

Meanwhile, when the conductive layer 112b has the stacked-layer structure of the conductive layer 51a and the metal layer 51b as shown in FIG. 3B and the like, the resistance of the case where the conductive layer 112b is used as a wiring can be reduced. Furthermore, the contact resistance with the semiconductor layer provided on the top surface of the conductive layer 112b can be reduced. In addition, the conductive layer 51a having a favorable shape can be obtained.

### <Structure Example 4 of Stack>

Note that although FIG. 3B and FIG. 8B each show an example in which the opening 141 of the insulating layer 110 and the opening 143 of the conductive layer 112b overlap with the conductive layer 112a, the conductive layer 112a is not necessarily provided in a position overlapping with the opening 141 of the insulating layer 110 and the opening 143 of the conductive layer 112b as shown in FIG. 8C. In FIG. 8C, for example, an insulating film is formed on the surface of the substrate 102, and the opening 141 reaches the surface of the insulating film. In that case, the etching condition of the insulating layer 110a can be a condition with high selectivity with respect to the insulating film on the surface of the substrate 102, for example.

This embodiment can be combined with the other embodiments as appropriate. In this specification, in the case where a plurality of structure examples are shown in one embodiment, the structure examples can be combined as appropriate.

### Embodiment 2

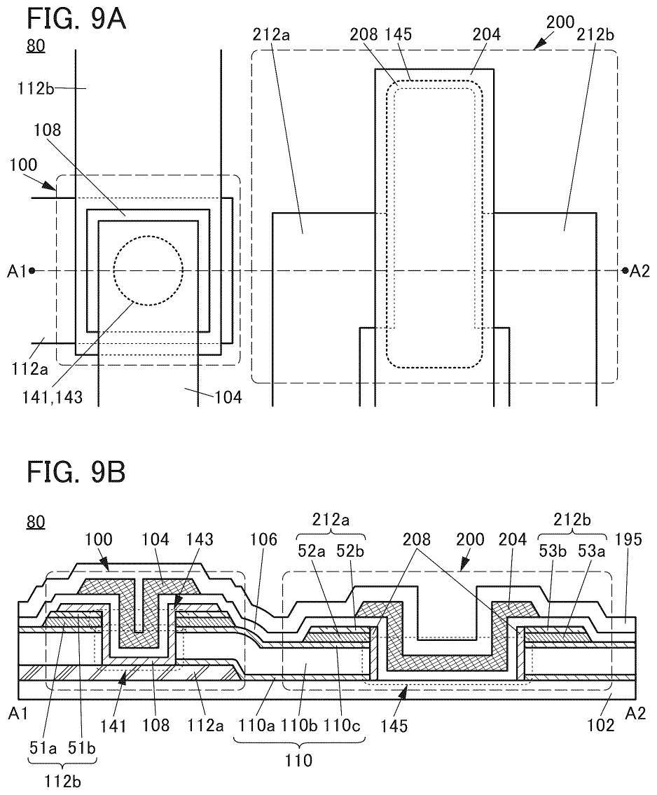

In this embodiment, a semiconductor device using the stack described in the above embodiment, a manufacturing method thereof, and the like will be described with reference to FIG. 9 to FIG. 19.

The semiconductor device of one embodiment of the present invention can be used for a display apparatus, for example. In the case where the semiconductor device of one embodiment of the present invention is used for a pixel circuit of a display apparatus, for example, the area occupied by the pixel circuit can be reduced and the display apparatus can have high resolution. In the case where the semiconductor device of one embodiment of the present invention is used for a driver circuit (e.g., one or both of a gate line driver circuit and a source line driver circuit) of a display apparatus, for example, the area occupied by the driver circuit can be reduced and the display apparatus can have a narrow bezel.

### <Structure Example 1 of Semiconductor Device>

FIG. 9A is a top view (also referred to as a plan view) of a semiconductor device 80. FIG. 9B is a cross-sectional view of a cut plane along the dashed-dotted line A1-A2 in FIG. 9A. Note that in FIG. 9A, some components (e.g., an insulating layer) of the semiconductor device 80 are not shown. Some components are not shown in top views of semiconductor devices in the following diagrams, as in FIG. 9A.

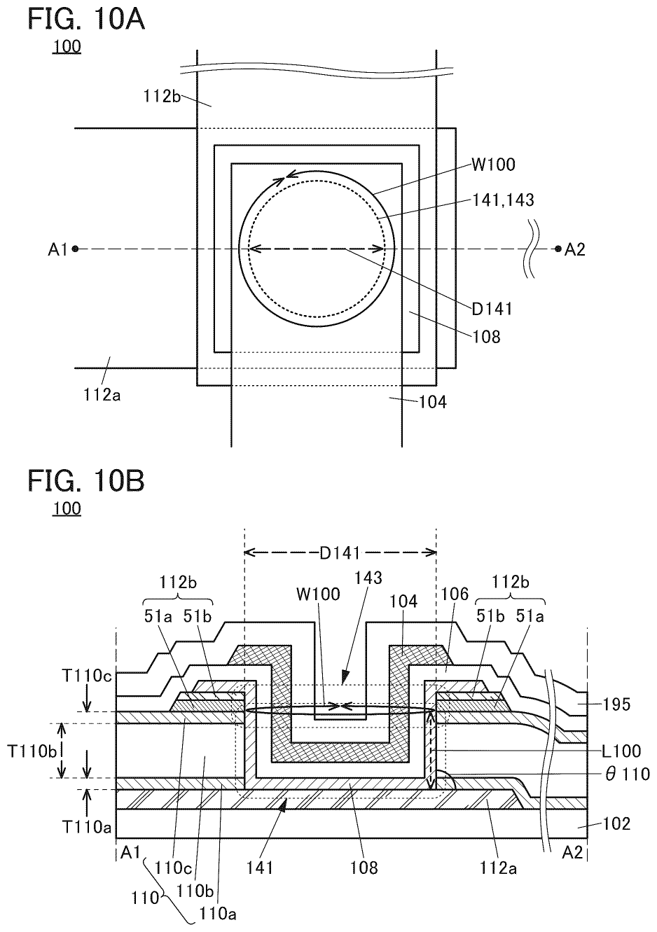

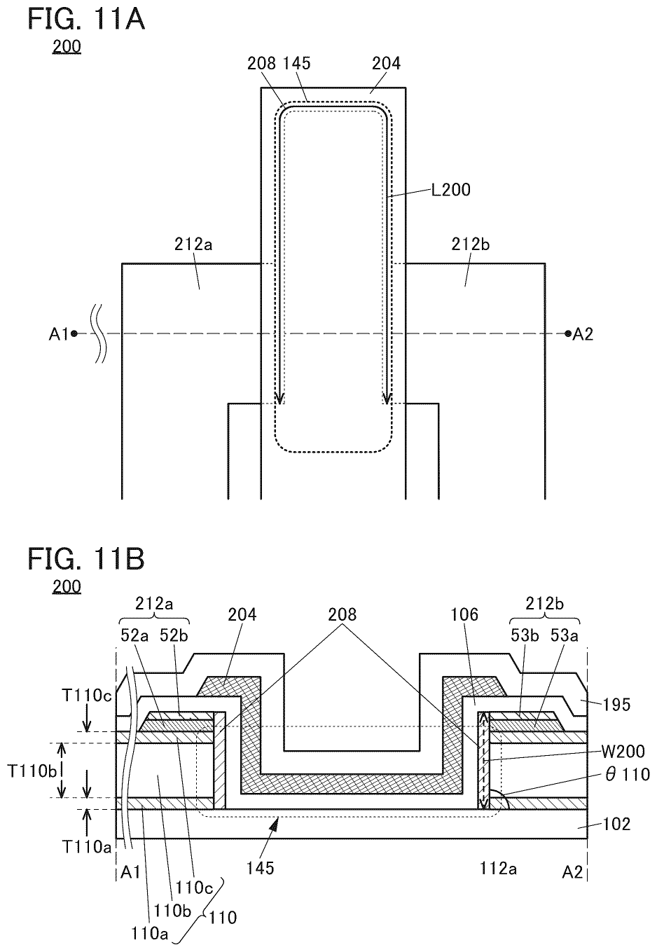

The semiconductor device 80 includes a transistor 100, a transistor 200, and the insulating layer 110. The transistor 100 and the transistor 200 are provided over the substrate 102. The transistor 100 has a structure different from that of the transistor 200. Some of the formation steps of the transistor 100 can be the same as some of the formation steps of the transistor 200. FIG. 10A and FIG. 10B are enlarged views of the transistor 100 shown in FIG. 9A and FIG. 9B, and FIG. 11A and FIG. 11B are enlarged views of the transistor 200 shown in FIG. 9A and FIG. 9B.

Note that in the case where the semiconductor device 80 is used for a display apparatus, preferably, the transistor 100 is used as a selection transistor of a pixel and the transistor 200 is used as a driving transistor. More specifically, since it is preferable that the driving transistor have high saturation characteristics, the transistor 200 with a long channel length can be suitably used. As described above, the semiconductor device of one embodiment of the present invention has an excellent effect that transistors with different channel lengths over the same substrate can be freely designed by the thickness of an insulating layer and by pattern forming.

In this specification and the like, the state where the change in a current is small in the saturation region of the Id-Vd characteristics of a transistor is sometimes described using the expression “high saturation characteristics”.

The structure of the transistor 100 will be described.

The transistor 100 includes a conductive layer 104, an insulating layer 106, the semiconductor layer 108, the conductive layer 112a, and the conductive layer 112b. The conductive layer 112b preferably has a stacked-layer structure of the conductive layer 51a and the metal layer 51b over the conductive layer 51a. For materials, structures, and the like usable for the conductive layer 51a and the metal layer 51b, the description of the conductive layer 51a and the metal layer 51b in the above embodiment can be referred to.

In the transistor 100, the conductive layer 104 serves as a gate electrode (also referred to as a first gate electrode), and part of the insulating layer 106 serves as a gate insulating layer (also referred to as a first gate insulating layer). The conductive layer 112a serves as one of a source electrode and a drain electrode, and the conductive layer 112b serves as the other. The layers forming the transistor 100 may each have a single-layer structure or a stacked-layer structure.

The conductive layer 112a is provided over the substrate 102, and the insulating layer 110 is provided over the conductive layer 112a. The insulating layer 110 is provided to cover the top surface and the side surface of the conductive layer 112a. The insulating layer 110 has the opening 141 reaching the conductive layer 112a in a region overlapping with the conductive layer 112a. It can be said that the conductive layer 112a is exposed in the opening 141.

The conductive layer 112b is provided over the insulating layer 110. The conductive layer 112b includes a region overlapping with the conductive layer 112a with the insulating layer 110 therebetween. The conductive layer 112b has an opening 143 in the region overlapping with the conductive layer 112a. The opening 143 is provided in a region overlapping with the opening 141.

The semiconductor layer 108 is provided to cover the opening 141 and the opening 143.

The semiconductor layer 108 includes a region in contact with the top surface and the side surface of the conductive layer 112b, the side surface of the insulating layer 110, and the top surface of the conductive layer 112a. In the case where the conductive layer 112b has a stacked-layer structure of the conductive layer 51a and the metal layer 51b over the conductive layer 51a, the semiconductor layer 108 includes a region in contact with the top surface of the metal layer 51b. In FIG. 9B, FIG. 10B, and the like, the semiconductor layer 108 includes a region in contact with the side surface of the metal layer 51b and the side surface of the conductive layer 51a. The semiconductor layer 108 is electrically connected to the conductive layer 112a through the opening 141 and the opening 143. The semiconductor layer 108 has a shape along the shapes of the top surface and the side surface of the conductive layer 112b, the side surface of the insulating layer 110, and the top surface of the conductive layer 112a. The semiconductor layer 108 includes a region overlapping with the conductive layer 112a with the insulating layer 110 therebetween. It can also be said that the insulating layer 110 includes a region sandwiched between the conductive layer 112a and the semiconductor layer 108.

In the semiconductor layer 108, the region in contact with the conductive layer 112a serves as one of a source region and a drain region, and the region in contact with the conductive layer 112b serves as the other. In the semiconductor layer 108, the channel formation region is provided between the source region and the drain region. Note that in FIG. 9B, FIG. 10B, and the like, the semiconductor layer 108 includes a region in contact with the top surface of the metal layer 51b, the side surface of the metal layer 51b, and the side surface of the conductive layer 51a. The region of the semiconductor layer 108 that is in contact with the top surface of the metal layer 51b, the side surface of the metal layer 51b, and the side surface of the conductive layer 51a preferably serves as the other of the source region and the drain region of the transistor 100, for example.

The insulating layer 106 is provided to cover the opening 141 and the opening 143. The insulating layer 106 is provided over the semiconductor layer 108, the conductive layer 112b, and the insulating layer 110. The insulating layer 106 includes a region in contact with the top surface and the side surface of the semiconductor layer 108, the top surface and the side surface of the conductive layer 112b, and the top surface of the insulating layer 110. The insulating layer 106 has a shape along the shapes of the top surface and the side surface of the semiconductor layer 108, the top surface and the side surface of the conductive layer 112b, and the top surface of the insulating layer 110. Note that in FIG. 9B, FIG. 10B, and the like, the insulating layer 106 includes a region in contact with the top surface of the metal layer 51b, the side surface of the metal layer 51b, and the side surface of the conductive layer 51a.

The conductive layer 104 is provided over the insulating layer 106 and includes a region in contact with the top surface of the insulating layer 106. The conductive layer 104 includes a region overlapping with the semiconductor layer 108 with the insulating layer 106 therebetween. The conductive layer 104 has a shape along the shape of the top surface of the insulating layer 106. For the conductive layer 104, the same material as a conductive layer 204 can be used. The conductive layer 104 can be formed in the same step as the conductive layer 204. For example, a film to be the conductive layer 104 and the conductive layer 204 is formed and the film is processed, whereby the conductive layer 104 and the conductive layer 204 can be formed.

The transistor 100 is what is called a top-gate transistor including the gate electrode above the semiconductor layer 108. Furthermore, since the bottom surface of the semiconductor layer 108 is in contact with the conductive layer 112a and the conductive layer 112b that serve as the source electrode and the drain electrode, the transistor 100 can be referred to as a TGBC (Top Gate Bottom Contact) transistor. In the transistor 100, the source electrode and the drain electrode are positioned at different levels with respect to the surface of the substrate 102 over which the transistor 100 is formed, and a drain current flows in a direction perpendicular or substantially perpendicular to the surface of the substrate 102. In the transistor 100, the drain current can also be regarded as flowing in the vertical direction or the substantially vertical direction. Accordingly, the transistor of one embodiment of the present invention can be referred to as a vertical-channel transistor or a VFET (Vertical Field-Effect Transistor). The transistor 200 has a structure in which a current flows in both the vertical direction and the horizontal direction; thus, the transistor 200 can be referred to as a VLFET (Vertical Lateral Field Effect Transistor).

The channel length of the transistor 100 can be controlled by the thickness of the insulating layer 110 (specifically, the insulating layer 110b) provided between the conductive layer 112a and the conductive layer 112b. Accordingly, a transistor with a channel length smaller than the resolution limit of a light exposure apparatus used for manufacturing the transistor can be manufactured with high accuracy. Furthermore, variation in characteristics among the transistors 100 are also reduced. Accordingly, the operation of the semiconductor device including the transistor 100 can be stabilized and the reliability thereof can be improved. When the variation in characteristics are reduced, the circuit design flexibility is increased and the operation voltage of the semiconductor device can be reduced. Thus, power consumption of the semiconductor device can be reduced.

In the transistor 100, since the source electrode, the layer including the channel formation region, and the drain electrode can be provided to overlap with each other, the area occupied by the transistor can be significantly reduced as compared with a so-called planar transistor in which a layer including a channel formation region is provided in a planar shape.

The conductive layer 112a, the conductive layer 112b, and the conductive layer 104 can serve as wirings, and the transistor 100 can be provided in a region where these wirings overlap with each other. That is, the areas occupied by the transistor 100 and the wirings can be reduced in a circuit including the transistor 100 and the wirings. Accordingly, the area occupied by the circuit can be reduced, which makes it possible to provide a small semiconductor device.

The structure of the transistor 200 will be described.

The transistor 200 includes the conductive layer 204, a conductive layer 212a, a conductive layer 212b, the insulating layer 106, and a semiconductor layer 208. In the transistor 200, the conductive layer 204 serves as a gate electrode, and part of the insulating layer 106 serves as a gate insulating layer. The conductive layer 212a serves as one of the source electrode and the drain electrode, and the conductive layer 212b serves as the other. The layers forming the transistor 200 may each have a single-layer structure or a stacked-layer structure.

The insulating layer 110 includes an opening 145. The conductive layer 212a and the conductive layer 212b are provided over the insulating layer 110. Part of end portions of the conductive layer 212a and the conductive layer 212b is preferably aligned with an end portion of the insulating layer 110 on the opening 145 side. The conductive layer 212a and the conductive layer 212b can be formed using the same material as the conductive layer 112b. The conductive layer 212a and the conductive layer 212b can be formed in the same step as the conductive layer 112b.

The conductive layer 212a preferably has a stacked-layer structure of a conductive layer 52a and a metal layer 52b over the conductive layer 52a. For materials and the like usable for the conductive layer 52a and the metal layer 52b, the conductive layer 51a and the metal layer 51b can be referred to. The conductive layer 212b preferably has a stacked-layer structure of a conductive layer 53a and a metal layer 53b over the conductive layer 53a. For materials and the like usable for the conductive layer 53a and the metal layer 53b, the conductive layer 51a and the metal layer 51b can be referred to.

The semiconductor layer 208 is provided in contact with the side surface of the conductive layer 212a, the side surface of the conductive layer 212b, and the side surface of the insulating layer 110. In the structure shown in FIG. 9A and FIG. 9B, the semiconductor layer 208 is not provided in the bottom portion of the opening 145. The semiconductor layer 208 can be formed using the same material as the semiconductor layer 108. The semiconductor layer 208 can be formed in the same step as the semiconductor layer 108. For example, a film to be the semiconductor layer 108 and the semiconductor layer 208 is formed and then processed, whereby the semiconductor layer 108 and the semiconductor layer 208 can be formed.

In the semiconductor layer 208, the region in contact with the conductive layer 212a serves as one of a source region and a drain region, and the region in contact with the conductive layer 212b serves as the other. In the semiconductor layer 208, the channel formation region is provided between the source region and the drain region.

The insulating layer 106 is provided to cover the opening 145. The insulating layer 106 is provided over the semiconductor layer 208, the conductive layer 212a, the conductive layer 212b, and the insulating layer 110. The insulating layer 106 includes a region in contact with the top surface and the side surface of the semiconductor layer 208, the top surface and the side surface of the conductive layer 212a, the top surface and the side surface of the conductive layer 212b, the side surface of the insulating layer 110, and the top surface of the substrate 102. The insulating layer 106 has a shape along the shapes of the top surface and the side surface of the semiconductor layer 208, the top surface and the side surface of the conductive layer 212a, the top surface and the side surface of the conductive layer 212b, the side surface of the insulating layer 110, and the top surface of the substrate 102. Note that in FIG. 9B, FIG. 11B, and the like, the insulating layer 106 includes a region in contact with the top surface of the metal layer 52b, the side surface of the metal layer 52b, the side surface of the conductive layer 52a, the top surface of the metal layer 53b, the side surface of the metal layer 53b, and the side surface of the conductive layer 53a.

The conductive layer 204 is provided over the insulating layer 106 and includes a region in contact with the top surface of the insulating layer 106. The conductive layer 204 includes a region overlapping with the semiconductor layer 208 with the insulating layer 106 therebetween. The conductive layer 204 has a shape along the shape of the top surface of the insulating layer 106.

In manufacturing the semiconductor device of one embodiment of the present invention, the transistor 100 with a short channel length and the transistor 200 with a long channel length can be formed over the same substrate by the formation steps some of which are shared. For example, when the transistor 100 is used as the transistor required to have a high on-state current and the transistor 200 is used as the transistor required to have favorable saturation characteristics, the semiconductor device can achieve high performance.

The conductive layer 112a and the conductive layer 112b that serve as the source electrode and the drain electrode of the transistor 100 are provided on different planes. Specifically, the conductive layer 112a is provided over the substrate 102, the conductive layer 112b is provided over the insulating layer 110, and the insulating layer 110 is sandwiched between the conductive layer 112a and the conductive layer 112b. Meanwhile, the conductive layer 212a and the conductive layer 212b that serve as the source electrode and the drain electrode of the transistor 200 are provided on the same plane. Specifically, the conductive layer 212a and the conductive layer 212b are provided over the insulating layer 110. It can be said that one of the source electrode and the drain electrode of the transistor 100 is provided on a plane different from a plane where the source electrode and the drain electrode of the transistor 200 are provided, and the other is provided on the same plane as the source electrode and the drain electrode of the transistor 200.

An insulating layer 195 is provided to cover the transistor 100 and the transistor 200. The insulating layer 195 serves as a protective layer of the transistor 100 and the transistor 200.

A semiconductor material that can be used for each of the semiconductor layer 108 and the semiconductor layer 208 is not particularly limited. For example, a single-element semiconductor or a compound semiconductor can be used. Examples of the single-element semiconductor include silicon and germanium. Examples of the compound semiconductor include gallium arsenide and silicon germanium. Other examples of the compound semiconductor include an organic semiconductor, a nitride semiconductor, and an oxide semiconductor (OS). These semiconductor materials may include an impurity as a dopant.

There is no particular limitation on the crystallinity of a semiconductor material used for each of the semiconductor layer 108 and the semiconductor layer 208, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

For each of the semiconductor layer 108 and the semiconductor layer 208, silicon can be used. Examples of silicon include single crystal silicon, polycrystalline silicon, microcrystalline silicon, and amorphous silicon. An example of polycrystalline silicon is low-temperature polysilicon (LTPS). The transistor including amorphous silicon in the channel formation region can be formed over a large glass substrate, and can be manufactured at low cost. A transistor including polycrystalline silicon in the channel formation region has high field-effect mobility and enables high-speed operation. A transistor including microcrystalline silicon in the channel formation region has higher field-effect mobility and enables higher-speed operation than the transistor including amorphous silicon.

Each of the semiconductor layer 108 and the semiconductor layer 208 preferably includes a metal oxide exhibiting semiconductor characteristics (also referred to as an oxide semiconductor).

The band gaps of the metal oxides used for the semiconductor layer 108 and the semiconductor layer 208 are each preferably greater than or equal to 2.0 eV, further preferably greater than or equal to 2.5 eV.

A transistor including an oxide semiconductor (hereinafter referred to as an OS transistor) has much higher field-effect mobility than a transistor including amorphous silicon. In addition, the OS transistor has an extremely low off-state current, and a charge accumulated in a capacitor that is connected in series to the transistor can be retained for a long period. Furthermore, a semiconductor device can have lower power consumption by including the OS transistor.

The insulating layer 110 preferably includes one or more inorganic insulating films. Examples of a material usable for the inorganic insulating film include an oxide, a nitride, an oxynitride, and a nitride oxide. Examples of the oxide include silicon oxide, aluminum oxide, magnesium oxide, gallium oxide, germanium oxide, yttrium oxide, zirconium oxide, lanthanum oxide, neodymium oxide, hafnium oxide, tantalum oxide, cerium oxide, gallium zinc oxide, and hafnium aluminate. Examples of the nitride include silicon nitride and aluminum nitride. Examples of the oxynitride include silicon oxynitride, aluminum oxynitride, gallium oxynitride, yttrium oxynitride, and hafnium oxynitride. Examples of the nitride oxide include silicon nitride oxide and aluminum nitride oxide.

Note that in this specification and the like, an oxynitride refers to a material that includes more oxygen than nitrogen in its composition. A nitride oxide refers to a material that includes more nitrogen than oxygen in its composition.

In the transistor 100, a region of the semiconductor layer 108 in contact with the insulating layer 110 can serve as the channel formation region. In the transistor 200, a region of the semiconductor layer 208 in contact with the insulating layer 110 can serve as the channel formation region. In the case where a metal oxide is used for each of the semiconductor layer 108 and the semiconductor layer 208, at least part of a region of the insulating layer 110 that is in contact with the semiconductor layer 108 and at least part of a region of the insulating layer 110 that is in contact with the semiconductor layer 208 preferably include oxygen in order to improve the properties of the interface between the semiconductor layer 108 and the insulating layer 110 and the interface between the semiconductor layer 208 and the insulating layer 110. Specifically, the region of the insulating layer 110 that is in contact with the channel formation region of the semiconductor layer 108 and the region of the insulating layer 110 that is in contact with the channel formation region of the semiconductor layer 208 preferably include oxygen. One or more of an oxide and an oxynitride is suitably used for the region of the insulating layer 110 that is in contact with the channel formation region of the semiconductor layer 108 and the region of the insulating layer 110 that is in contact with the channel formation region of the semiconductor layer 208.

The insulating layer 110 preferably has a stacked-layer structure. FIG. 9B and the like show an example in which the insulating layer 110 includes the insulating layer 110a, the insulating layer 110b over the insulating layer 110a, and the insulating layer 110c over the insulating layer 110b.

The insulating layer 110b preferably includes oxygen, and is preferably formed using any one or more of the oxides and oxynitrides described above. Specifically, one or both of silicon oxide and silicon oxynitride can be suitably used for the insulating layer 110b. Accordingly, at least a region of the semiconductor layer 208 that is in contact with the insulating layer 110b and a region of the semiconductor layer 108 that is in contact with the insulating layer 110b can each serve as a channel formation region.

It is further preferable that a film from which oxygen is released by heating be used as the insulating layer 110b. When the insulating layer 110b releases oxygen by being heated during the manufacturing process of the transistor 100, the oxygen can be supplied to the semiconductor layer 108. Supply of oxygen from the insulating layer 110b to the semiconductor layer 108, particularly to the channel formation region, can repair oxygen vacancies (V_{O}) and reduce oxygen vacancies (V_{O}). Consequently, a transistor with favorable electrical characteristics and high reliability can be obtained.

For example, the insulating layer 110b can be supplied with oxygen when heat treatment in an atmosphere including oxygen or plasma treatment in an atmosphere including oxygen is performed. Alternatively, an oxide film may be formed over the top surface of the insulating layer 110b by a sputtering method in an atmosphere including oxygen to supply oxygen. After that, the oxide film may be removed. Note that Embodiment 3 described later shows an example in which oxygen is supplied to the insulating layer 110b by forming a metal oxide layer 137.

The insulating layer 110b is preferably formed by a film formation method such as a sputtering method or a plasma-enhanced chemical vapor deposition (PECVD) method. In particular, when the insulating layer 110b is formed by a sputtering method, which is a method that does not use a hydrogen gas as a film formation gas, the insulating layer 110b can be a film having an extremely low hydrogen content. Thus, supply of hydrogen to the channel formation region is inhibited and the electrical characteristics of the transistor 100 can be stabilized.

Preferably, a substance is easily diffused into the insulating layer 110b. In other words, the diffusion coefficient of a substance in the insulating layer 110b is preferably high. Preferably, oxygen in particular is easily diffused in the insulating layer 110b. That is, the diffusion coefficient of oxygen in the insulating layer 110b is preferably high. Oxygen included in the insulating layer 110b is diffused into the insulating layer 110b, and is supplied to the semiconductor layer 108 through the interface between the insulating layer 110b and the semiconductor layer 108 and supplied to the semiconductor layer 208 through the interface between the insulating layer 110b and the semiconductor layer 208.

The use of a material having high electrical conductivity for the semiconductor layer 108 and the semiconductor layer 208 enables the transistor to have a high on-state current. However, the use of a material having high electrical conductivity facilitates the formation of oxygen vacancies (V_{O}); the increased oxygen vacancies (V_{O}) in the channel formation region shift the threshold voltage of the transistor, which might increase the drain current flowing at a gate voltage of 0 V (hereinafter, also referred to as a cut-off current). For example, a negative shift of the threshold voltage might increase the cut-off current in the case of an n-channel transistor. By providing the insulating layer 110b, oxygen is supplied to at least the region of the semiconductor layer 108 that is in contact with the insulating layer 110b and the region of the semiconductor layer 208 that is in contact with the insulating layer 110b, that is, the channel formation regions of the transistor 100 and transistor 200, so that oxygen vacancies (V_{O}) in the channel formation regions can be reduced. This prevents the threshold voltage shift and allows the transistor to have both a low cut-off current and a high on-state current. Consequently, the semiconductor device can have both low power consumption and high performance.

In the semiconductor layer 108, the region in contact with the conductive layer 112a serves as one of the source region and the drain region of the transistor 100, and the region in contact with the conductive layer 112b serves as the other. The source region and the drain region each have lower electrical resistance than the channel formation region. In other words, the source region and the drain region are each a region having a higher carrier concentration or a higher oxygen vacancy density than the channel formation region.

The insulating layer 110a is provided between the insulating layer 110b and the conductive layer 112a. The insulating layer 110c is provided between the insulating layer 110b and the conductive layer 112b. It is preferable that the insulating layer 110a and the insulating layer 110c themselves release a small amount of impurity (e.g., hydrogen and water) and not easily transmit impurities. Thus, the impurities included in the insulating layer 110a and the insulating layer 110c can be inhibited from being diffused into the channel formation region. Consequently, a transistor with favorable electrical characteristics and high reliability can be obtained.

For each of the insulating layer 110a and the insulating layer 110c, a film that does not easily transmit oxygen is preferably used. Accordingly, oxygen included in the insulating layer 110b can be inhibited from being diffused into the conductive layer 112a through the insulating layer 110a. Similarly, oxygen included in the insulating layer 110b can be inhibited from being diffused into the conductive layer 112b through the insulating layer 110c. This can inhibit the conductive layer 112a and the conductive layer 112b from having increased electrical resistance. At the same time, oxygen included in the insulating layer 110b can be inhibited from being diffused to the insulating layer 110a side and the insulating layer 110c side, which increases the amount of oxygen supplied to the channel formation region from the insulating layer 110b and can reduce oxygen vacancies (V_{O}) and V_{O}H in the channel formation region.

When a film that does not easily allow diffusion of oxygen is used for each of the insulating layer 110a and the insulating layer 110c, oxygen can be effectively supplied from the insulating layer 110b to the channel formation region. Note that one or both of the insulating layer 110a and the insulating layer 110c are not necessarily provided.

It is preferable that the insulating layer 110a and the insulating layer 110c each include nitrogen and be each formed using any one or more of the nitride and nitride oxide described above. For example, silicon nitride or silicon nitride oxide can be suitably used for each of the insulating layer 110a and the insulating layer 110c. Alternatively, any one or more of oxide and oxynitride may be used for one or both of the insulating layer 110a and the insulating layer 110c. For example, aluminum oxide can be suitably used for each of the insulating layer 110a and the insulating layer 110c. Note that the insulating layer 110a and the insulating layer 110c may be formed using the same material or different materials.

Note that in this specification and the like, different materials mean materials in which some or all of constituent elements are different or materials having the same constituent elements and different compositions.

For example, a thickness T110a of the insulating layer 110a can be greater than or equal to 3 nm, greater than or equal to 5 nm, greater than or equal to 10 nm, greater than or equal to 20 nm, greater than or equal to 50 nm, or greater than or equal to 70 nm and less than 1 μm or less than or equal to 500 nm, less than or equal to 400 nm, less than or equal to 300 nm, less than or equal to 200 nm, less than or equal to 150 nm, or less than or equal to 120 nm. The thickness T110a can be the shortest distance between the formation surface of the insulating layer 110a (the top surface of the conductive layer 112a here) and the bottom surface of the insulating layer 110b in a cross-sectional view, as shown in FIG. 10B.

If the thickness T110a of the insulating layer 110a is large, more impurities might be released from the insulating layer 110a, resulting in an increase in impurities being diffused into the channel formation region. Meanwhile, if the thickness T110a is small, oxygen included in the insulating layer 110b might be diffused to the conductive layer 112a side through the insulating layer 110a, resulting in a reduction in the amount of oxygen supplied to the channel formation region. When the thickness T110a is set within the above-described range, the oxygen vacancies (V_{O}) and V_{O}H in the channel formation region can be reduced. Furthermore, the conductive layer 112a can be inhibited from being oxidized by oxygen included in the insulating layer 110b and from having increased electrical resistance.

For example, a thickness T110c of the insulating layer 110c can be greater than or equal to 3 nm, greater than or equal to 5 nm, greater than or equal to 10 nm, greater than or equal to 15 nm, or greater than or equal to 20 nm and less than or equal to 1 μm or less than or equal to 500 nm, less than or equal to 300 nm, less than or equal to 200 nm, less than or equal to 150 nm, or less than or equal to 120 nm, or less than or equal to 100 nm. The thickness T110c can be the shortest distance between the formation surface of the insulating layer 110c (the top surface of the conductive layer 110b here) and the bottom surface of the insulating layer 112b in a cross-sectional view, as shown in FIG. 10B. Note that in the case where the conductive layer 112b has the stacked-layer structure of the conductive layer 51a and the metal layer 51b shown in FIG. 9B, FIG. 10B, and the like, the thickness T110c can be the shortest distance between the formation surface of the insulating layer 110c (here, the top surface of the insulating layer 110b) and the bottom surface of the conductive layer 51a in a cross-sectional view.

If the thickness T110c of the insulating layer 110c is large, more impurities might be released from the insulating layer 110c, resulting in an increase in the amount of impurities being diffused into the channel formation region. Meanwhile, if the thickness T110c is small, oxygen included in the insulating layer 110b might be diffused to the conductive layer 112b side through the insulating layer 110c, resulting in a reduction in the amount of oxygen supplied to the channel formation region. When the thickness T110c is set within the above-described range, the oxygen vacancies (V_{O}) and V_{O}H in the channel formation region can be reduced. Furthermore, the conductive layer 112b can be inhibited from being oxidized by oxygen included in the insulating layer 110b and from having increased electrical resistance.

In the semiconductor layer 108, at least one of the region in contact with the insulating layer 110a and the region in contact with the insulating layer 110c may be a region having lower electrical resistance than the channel formation region (hereinafter, also referred to as a low-resistance region). In other words, the region is a region having a higher carrier concentration or a higher oxygen vacancy density than the channel formation region. When a material that releases an impurity (e.g., water or hydrogen) is used for the insulating layer 110a, the region of the semiconductor layer 108 that is in contact with the insulating layer 110a can be a low-resistance region. In the semiconductor layer 108, the low-resistance region can be formed between the channel formation region and the region in contact with the conductive layer 112a (one of the source region and the drain region). Similarly, when a material that releases an impurity is used for the insulating layer 110c, the region of the semiconductor layer 108 that is in contact with the insulating layer 110c can be a low-resistance region. In the semiconductor layer 108, the low-resistance region can be formed between the channel formation region and the region in contact with the conductive layer 112b (the other of the source region and the drain region). The low-resistance region can serve as a buffer region for relieving a drain electric field. These low-resistance regions may serve as the source region and the drain region.

The low-resistance region between the drain region and the channel formation region inhibits generation of a high electric field in the vicinity of the drain region, so that generation of hot carriers is inhibited to prevent the deterioration of the transistor. For example, in the case where the conductive layer 112a serves as the drain electrode, the conductive layer 112b serves as the source electrode, and the region of the semiconductor layer 108 that is in contact with the insulating layer 110a serves as the low-resistance region, a high electric field is not easily generated in the vicinity of the drain region, so that generation of hot carriers is inhibited to prevent the deterioration of the transistor. In the case where the conductive layer 112a serves as the source electrode, the conductive layer 112b serves as the drain electrode, and the region of the semiconductor layer 108 that is in contact with the insulating layer 110c serves as the low-resistance region, a high electric field is not easily generated in the vicinity of the drain region, so that generation of hot carriers is inhibited to prevent the deterioration of the transistor.

As described above, when an excessive amount of impurities is released from the insulating layer 110a and the insulating layer 110c, impurities might be diffused into the channel formation region. Even when a material that releases impurities is used for the insulating layer 110a and the insulating layer 110c, the amount of released impurities is preferably small.

Note that the insulating layer 110 preferably includes at least the insulating layer 110b. For example, a structure in which one or both of the insulating layer 110a and the insulating layer 110c are not provided may be employed. The insulating layer 110 may have a single-layer structure or a stacked-layer structure of two or four or more layers.

There is no limitation on the top surface shapes of the opening 145, the opening 141, and the opening 143, and the shapes can be polygons such as a circle, an ellipse, a triangle, a tetragon (including a rectangle, a rhombus, and a square), and a pentagon; and polygons with rounded corners, for example. Note that the polygon may be a concave polygon (a polygon at least one of the interior angles of which is greater than 180°) or a convex polygon (a polygon all the interior angles of which are less than or equal to 180°). The top surface shapes of the opening 141 and the opening 143 are preferably circles as shown in FIG. 9A and the like. When the top surface shapes of the openings are each a circular shape, processing accuracy at the time of formation of the openings can be high, whereby the openings can be formed to have minute sizes. Note that in this specification and the like, a circular shape is not necessarily a perfect circular shape.

In this specification and the like, the top surface shape of the opening 145 refers to the shape of an end portion of the top surface of the insulating layer 110 on the opening 145 side. The top surface shape of the opening 141 refers to the shape of an end portion of the top surface of the insulating layer 110 on the opening 141 side. The top surface shape of the opening 143 refers to the shape of an end portion of the bottom surface of the conductive layer 112b on the opening 143 side. Although FIG. 9B and FIG. 10B show an example in which the conductive layer 112b has the stacked-layer structure of the conductive layer 51a and the metal layer 51b and an end portion of the conductive layer 51a and an end portion of the metal layer 51b are aligned with each other on the opening 143 side, the end portions are not aligned with each other in some cases. For example, the end portion of the conductive layer 51a is positioned inward from the end portion of the metal layer 51b in some cases. Alternatively, for example, the end portion of the conductive layer 51a is positioned outward from the end portion of the metal layer 51b in some cases.

As shown in FIG. 9A and the like, the top surface shape of the opening 141 and the top surface shape of the opening 143 can be the same or substantially the same. In that case, it is preferable that the end portion of the bottom surface of the conductive layer 112b on the opening 143 side be aligned with or substantially aligned with the end portion of the top surface of the insulating layer 110 on the opening 141 side as shown in FIG. 9B and the like. The bottom surface of the conductive layer 112b refers to the surface thereof on the insulating layer 110 side. The top surface of the insulating layer 110 refers to the surface thereof on the conductive layer 112b side.

Note that the top surface shape of the opening 141 and the top surface shape of the opening 143 are not necessarily the same. In the case where the opening 141 and the opening 143 have circular top surface shapes, the opening 141 and the opening 143 may be concentrically arranged, but not necessarily concentrically arranged.

The channel length and channel width of the transistor 100 are described with reference to FIG. 10A and FIG. 10B.

In FIG. 10B, a channel length L100 of the transistor 100 is indicated by a dashed double-headed arrow. The channel length L100 of the transistor 100 corresponds to the length of the side surface of the insulating layer 110b on the opening 141 side in a cross-sectional view. In other words, the channel length L100 depends on a thickness T110b of the insulating layer 110b and the angle θ110 formed between the side surface of the insulating layer 110b on the opening 141 side and the formation surface of the insulating layer 110b (which is the top surface of the insulating layer 110a here). Thus, the channel length L100 can be a value smaller than that of the resolution limit of a light-exposure apparatus, which enables a transistor having a minute size. Specifically, a transistor with an extremely short channel length that could not be achieved with a conventional light-exposure apparatus for mass production of flat panel displays (the minimum line width: approximately 2 μm or approximately 1.5 μm, for example) can be achieved. Moreover, a transistor with a channel length less than 10 nm can also be achieved without using an extremely expensive light-exposure apparatus used in the latest LSI technology.

The channel length L100 can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L100 can be greater than or equal to 100 nm and less than or equal to 1 μm.

When the channel length L100 is small, the transistor 100 can have a high on-state current. With use of the transistor 100, a circuit capable of high-speed operation can be manufactured. Furthermore, the area occupied by the circuit can be reduced. Thus, a small semiconductor device can be obtained. The application of the semiconductor device of one embodiment of the present invention to a large display apparatus or a high-definition display apparatus can reduce signal delay in wirings and reduce display unevenness even if the number of wirings is increased, for example. In addition, since the area occupied by the circuit can be reduced, the bezel of the display apparatus can be narrowed.

By adjusting the thickness T110b of the insulating layer 110b and the angle θ110, the channel length L100 can be controlled. Note that in FIG. 10B, the thickness T110b of the insulating layer 110b is indicated by the dashed-dotted double-headed arrow.

The thickness T110b of the insulating layer 110b can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm.

The side surface of the insulating layer 110 on the opening 141 side preferably has a vertical shape or a tapered shape.

Note that the above embodiment can be referred to for the angle θ110.

By reducing the angle θ110, the coverage with a layer (e.g., the semiconductor layer 108) formed over the insulating layer 110 can be improved. The smaller the angle θ110 is, the larger the channel length L100 can be, and the larger the angle θ110 is, the smaller the channel length L100 can be.

Although FIG. 10B and the like show the structure in which the side surface of the insulating layer 110 on the opening 141 side is linear in the cross-sectional view, one embodiment of the present invention is not limited thereto. In the cross-sectional view, the side surface of the insulating layer 110 on the opening 141 side may be curved, or the side surface may include both a linear region and a curved region.

It is preferable that the conductive layer 112b not be provided inside the opening 141. Specifically, it is preferable that the conductive layer 112b not include a region in contact with the side surface of the insulating layer 110 on the opening 141 side. If the conductive layer 112b is also provided inside the opening 141, the channel length L100 of the transistor 100 is shorter than the length of the side surface of the insulating layer 110b and the channel length L100 is difficult to control in some cases. Accordingly, it is preferable that the top surface shape of the opening 143 be the same as the top surface shape of the opening 141, or the opening 143 cover the opening 141 completely in the top view.

In FIG. 10A and FIG. 10B, a width D141 of the opening 141 is indicated by a dashed double-dotted double-headed arrow. FIG. 10A shows an example where the top surface shape of the opening 141 is a circle. In this case, the width D141 corresponds to the diameter of the circle, and a channel width W100 of the transistor 100 is the length of the circumference of the circle. That is, the channel width W100 is π×D141. As described above, in the case where the top surface shape of the opening 141 is a circle, the channel width W100 of the transistor can be small as compared with the case where the top surface shape is any other shape.

The width D141 of the opening 141 sometimes varies in the depth direction. As the width D141 of the opening 141, for example, the average value of the following three diameters can be used: the diameter at the highest level of the insulating layer 110b (or the insulating layer 110) in a cross-sectional view, the diameter at the lowest level thereof, and the diameter at the midpoint between these levels. For another example, any of the diameter at the highest level of the insulating layer 110b (or the insulating layer 110) in the cross-sectional view, the diameter at the lowest level thereof, and the diameter at the midpoint between these levels can be used as the diameter of the opening 141.

In the case where the opening 141 is formed by a photolithography method, the width D141 of the opening 141 is larger than or equal to the resolution limit of a light-exposure apparatus. The width D141 can be, for example, greater than or equal to 200 nm, greater than or equal to 300 nm, greater than or equal to 400 nm, or greater than or equal to 500 nm and less than 5 μm, less than or equal to 4.5 μm, less than or equal to 4 μm, less than or equal to 3.5 μm, less than or equal to 3 μm, less than or equal to 2.5 μm, less than or equal to 2 μm, less than or equal to 1.5 μm, or less than or equal to 1 μm.

In the case where the channel length L100 of the transistor 100 is short, the insulating layer 110a and the insulating layer 110c are each preferably formed using a material that releases as little hydrogen as possible. When formed using a material that releases even a small amount of hydrogen, the insulating layer 110a and the insulating layer 110c preferably have small thicknesses. For example, when the channel length L100 is less than or equal to 100 nm, the thickness T110a of the insulating layer 110a and the thickness T110c of the insulating layer 110c are each preferably greater than or equal to 1 nm, greater than or equal to 3 nm, or greater than or equal to 5 nm and less than or equal to 50 nm, less than or equal to 40 nm, less than or equal to 30 nm, less than or equal to 20 nm, less than or equal to 15 nm, or less than or equal to 10 nm. Accordingly, the amount of impurities being diffused into the channel formation region can be reduced, and the transistor can have favorable electrical characteristics and high reliability even with the short channel length L100.

Although the structure where the region of the semiconductor layer 108 that is in contact with the insulating layer 110b serves as the channel formation region is described as an example, one embodiment of the present invention is not limited thereto. The region of the semiconductor layer 108 that is in contact with the insulating layer 110a may also serve as the channel formation region. Similarly, the region that is in contact with the insulating layer 110c may also serve as the channel formation region.

Although FIG. 9B and the like show an example where the semiconductor layer 108, the insulating layer 106, and the conductive layer 104 cover the opening 141 and the opening 143 in the transistor 100, one embodiment of the present invention is not limited thereto. A step may be formed between the insulating layer 110 and the conductive layer 112a, and the semiconductor layer 108, the insulating layer 106, and the conductive layer 104 may be provided along the step.

Next, the detailed structure of the transistor 200 will be described with reference to FIG. 11A and FIG. 11B. FIG. 11A and FIG. 11B are enlarged views of the transistor 200 shown in FIG. 9A and FIG. 9B.

The channel length and the channel width of the transistor 200 will be described with reference to FIG. 11A and FIG. 11B.

In FIG. 11A, a channel length L200 of the transistor 200 is indicated by a solid double-headed arrow. The channel length L200 corresponds to the distance between the conductive layer 212a and the conductive layer 212b along the perimeter direction of the opening 145. In FIG. 11B, a channel width W200 of the transistor 200 is indicated by a dashed double-headed arrow. The channel width W200 is the width of a semiconductor layer 21 along the depth direction of the opening 145.

As described above, the channel length L100 of the transistor 100 can have a value smaller than that of the resolution limit of the light-exposure apparatus, and the channel length L200 of the transistor 200 can have a value larger than or equal to that of the resolution limit of the light-exposure apparatus. For example, when the transistor 100 is used as the transistor required to have a high on-state current and the transistor 200 is used as the transistor required to have favorable saturation, a high-performance semiconductor device utilizing the advantages of the transistors can be provided. Furthermore, some formation steps can be common between the transistor 100 and the transistor 200. Specifically, the semiconductor layer 108 and the semiconductor layer 208 can be formed in the same step. One part of the insulating layer 106 serves as the gate insulating layer of the transistor 100 and another part of the insulating layer 106 serves as the gate insulating layer of the transistor 200. The conductive layer 104 and the conductive layer 204 can be formed in the same step. The conductive layer 112b, the conductive layer 212a, and the conductive layer 212b can be formed in the same step. This allows higher productivity and lower manufacturing cost of the semiconductor device.

[Conductive Layer 112a, Conductive Layer 112b, Conductive Layer 104, Conductive Layer 204, Conductive Layer 212a, and Conductive Layer 212b]

The conductive layer 112a, the conductive layer 112b, the conductive layer 104, the conductive layer 204, the conductive layer 212a, and the conductive layer 212b may each have a single-layer structure or a stacked-layer structure of two or more layers. Examples of materials usable for the conductive layer 112a, the conductive layer 112b, the conductive layer 104, the conductive layer 204, the conductive layer 212a, and the conductive layer 212b include one or more of ruthenium, tantalum, nickel, titanium, molybdenum, tungsten, hafnium, vanadium, niobium, aluminum, chromium, copper, silver, gold, platinum, zinc, manganese, iron, cobalt, magnesium, zirconium, beryllium, indium, iridium, strontium, and lanthanum; and an alloy including one or more of these metals as its components.

A Cu—X alloy film (X is Mn, Ni, Cr, Fe, Co, Mo, Ta, or Ti) may be used as the conductive layer 112a, the conductive layer 112b, the conductive layer 104, the conductive layer 204, the conductive layer 212a, and the conductive layer 212b. The use of a Cu—X alloy film can reduce the manufacturing cost because a wet etching method can be used in the processing.

For each of the conductive layer 112a, the conductive layer 112b, the conductive layer 104, the conductive layer 204, the conductive layer 212a, and the conductive layer 212b, a conductive metal oxide (an oxide conductor) can be used. As the oxide conductor, any of the materials described in the above embodiment can be used.

When an oxygen vacancy is formed in a metal oxide having semiconductor characteristics and hydrogen is added to the oxygen vacancy, a donor level is formed in the vicinity of the conduction band. As a result, the conductivity of the metal oxide is increased, and thus, the metal oxide becomes a conductor. The metal oxide having become a conductor can be referred to as an oxide conductor.

The conductive layer 112a, the conductive layer 112b, the conductive layer 104, the conductive layer 204, the conductive layer 212a, and the conductive layer 212b may each have a stacked-layer structure of a conductive film including the above-described oxide conductor (metal oxide) and a conductive film including a metal or an alloy. The use of the conductive film including a metal or an alloy can reduce the wiring resistance.

Note that the conductive layer 112a, the conductive layer 112b, the conductive layer 104, the conductive layer 204, the conductive layer 212a, and the conductive layer 212b may be formed using the same material or different materials.

The conductive layer 112a, the conductive layer 112b, the conductive layer 212a, and the conductive layer 212b each include a region in contact with the semiconductor layer 108. The conductive layer 112a and the conductive layer 112b each include a region that is in contact with the semiconductor layer 208. In the case where a metal oxide is used for the semiconductor layer 108, when the conductive layer 112a and the conductive layer 112b are formed using a metal that is easily oxidized (e.g., aluminum), an insulating oxide (e.g., aluminum oxide) might be formed between the conductive layer 112a and the semiconductor layer 108 and between the conductive layer 112b and the semiconductor layer 108 to prevent electrical continuity between these layers. Similarly, in the case where a metal oxide is used for the semiconductor layer 208, when the conductive layer 212a and the conductive layer 212b are formed using a metal that is easily oxidized, an insulating oxide might be formed between the conductive layer 212a and the semiconductor layer 208 and between the conductive layer 212b and the semiconductor layer 208 to prevent electrical continuity between these layers. Thus, the conductive layer 112a, the conductive layer 112b, the conductive layer 212a, and the conductive layer 212b are preferably formed using a conductive material that is less likely to be oxidized or a conductive material that maintains low electrical resistance even after being oxidized.

As a conductive material that is less likely to be oxidized or a material that maintains low electrical resistance even after being oxidized, for example, ruthenium, titanium, and an alloy thereof are preferably used.

An oxide conductor is preferably used for the conductive layer 112a, the conductive layer 112b, the conductive layer 212a, and the conductive layer 212b, in which case formation of an insulating oxide between the conductive layer and the semiconductor layer can be inhibited.

The conductive layer 112a, the conductive layer 112b, the conductive layer 212a, and the conductive layer 212b are preferably formed using a nitride conductor, in which case formation of an insulating oxide between the conductive layer and the semiconductor layer can be inhibited. As the nitride conductor, any of the materials described in the above embodiment can be used.

As a conductive material that is less likely to be oxidized or a material that maintains low electrical resistance even after being oxidized, it is particularly preferable to use ruthenium, ruthenium oxide, ruthenium nitride, an oxide including strontium and ruthenium, titanium, tantalum nitride, titanium nitride, a nitride including titanium and aluminum, a nitride including tantalum and aluminum, or an oxide including lanthanum and nickel.

As described in the above embodiment, the conductive layer 112b preferably has the stacked-layer structure of the conductive layer 51a and the metal layer 51b.

The conductive layer 112a, the conductive layer 104, the conductive layer 212a, the conductive layer 212b, and the conductive layer 204 may each have a stacked-layer structure. In that case, for at least a region in contact with the semiconductor layer 108, a conductive material that is less likely to be oxidized, a conductive material that maintains low electrical resistance even after being oxidized, an oxide conductive material, or a nitride conductive material is preferably used. Furthermore, when a material with low electrical resistivity is used to be stacked with an oxide conductive material, the electrical resistance of the conductive layer can be reduced. For example, in the case where ITSO is used in a region with a large contact area with the semiconductor layer 108, copper or tungsten can be suitably used to be stacked with ITSO. Specifically, for example, ITSO can be used for the upper layer of the conductive layer 112a, the upper layer of the conductive layer 212a, and the upper layer of the conductive layer 212b, and copper or tungsten can be used for the lower layer of each of the conductive layers.

### [Semiconductor Layer 108 and Semiconductor Layer 208]

Metal oxides usable for the semiconductor layer 108 and the semiconductor layer 208 are specifically described. Examples of the metal oxide include an indium oxide, a gallium oxide, and a zinc oxide. The metal oxide preferably includes at least indium or zinc. The metal oxide preferably includes two or three selected from indium, an element M, and zinc. The element M is a metal element or a metalloid element that has a high binding energy with oxygen, such as a metal element or a metalloid element whose binding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more kinds of the above elements, further preferably one or more kinds selected from aluminum, gallium, tin, and yttrium, and still further preferably one or more of gallium and tin. In this specification and the like, a metal element and a metalloid element may be collectively referred to as a “metal element”, and a “metal element” described in this specification and the like may refer to a metalloid element.

For each of the semiconductor layer 108 and the semiconductor layer 208, indium oxide (In oxide), indium zinc oxide (In—Zn oxide), indium tin oxide (also referred to as In—Sn oxide or ITO), indium titanium oxide (In—Ti oxide), indium gallium oxide (In—Ga oxide), indium tungsten oxide (also referred to as In—W oxide or IWO), indium gallium aluminum oxide (In—Ga—Al oxide), indium gallium tin oxide (In—Ga—Sn oxide), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or an indium gallium aluminum zinc oxide (also referred to as In—Ga—Al—Zn oxide, IGAZO, IGZAO, or IAGZO) can be used, for example. Alternatively, indium tin oxide including silicon (also referred to as ITSO), gallium tin oxide (Ga—Sn oxide), aluminum tin oxide (Al—Sn oxide), or the like can be used. Note that a material that does not include Zn, typified by an indium oxide or the like, has high compatibility with a Si process, and thus is suitable. Meanwhile, a material including Zn can increase the crystallinity, and thus is suitable.

By increasing the proportion of the number of indium atoms in the total number of atoms of all the metal elements included in the metal oxide, the field-effect mobility of the transistor can be increased. In addition, the transistor can have a high on-state current.

Instead of indium or in addition to indium, the metal oxide may include one or more kinds of metal elements with larger period numbers. The larger the overlap between orbits of metal elements is, the more likely it is that the metal oxide will have high carrier conductivity. Thus, a transistor including a metal element with a larger period number can have high field-effect mobility in some cases. Examples of the metal elements with larger period numbers include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may include one or more kinds selected from nonmetallic elements. By including a non-metallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements included in the metal oxide, the metal oxide has high crystallinity, so that diffusion of impurities in the metal oxide can be inhibited. Consequently, a change in electrical characteristics of the transistor is suppressed, and the reliability of the transistor can be increased.

By increasing the proportion of the number of the element M atoms in the total number of atoms of all the metal elements included in the metal oxide, oxygen vacancies (V_{O}) can be inhibited from being formed in the metal oxide. Thus, generation of carriers due to oxygen vacancies (V_{O}) is inhibited, which makes the off-state current of the transistor low. Furthermore, a change in electrical characteristics of the transistor is suppressed, and the reliability of the transistor can be increased.

The compositions of the metal oxides used for the semiconductor layer 108 and the semiconductor layer 208 affect the electrical characteristics and reliability of the transistors. Thus, by varying the composition of the metal oxide in accordance with the electrical characteristics and reliability required for the transistor, the semiconductor device can have both good electrical characteristics and high reliability.

When the metal oxide is In-M-Zn oxide, the proportion of the number of In atoms is preferably higher than or equal to that of the number of M atoms in the In-M-Zn oxide. Examples of the atomic ratio of the metal elements in such In-M-Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:1, In:M:Zn=10:1:3, In:M:Zn=10:1:4, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, and a composition in the neighborhood of any of these atomic ratios. Note that the vicinity of the atomic ratio includes ±30% of an intended atomic ratio. By increasing the proportion of the number of indium atoms in the metal oxide, the on-state current, field-effect mobility, or the like of the transistor can be increased.

The proportion of the number of In atoms may be less than that of the number of M atoms in the In-M-Zn oxide. Examples of the atomic ratio of the metal elements in such In-M-Zn oxide include In:M:Zn=1:3:2, In:M:Zn=1:3:3, In:M:Zn=1:3:4, and a composition in the neighborhood of any of these atomic ratios. By increasing the proportion of the number of M atoms in the metal oxide, generation of oxygen vacancies (V_{O}) can be inhibited.

In the case where a plurality of metal elements are included as the element M, the sum of the proportions of the numbers of atoms of the metal elements can be the proportion of the number of element M atoms.

In this specification and the like, the proportion of the number of indium atoms in the total number of atoms of all the metal elements included is sometimes referred to as the content percentage of indium. The same applies to other metal elements.

The use of a material with a high indium content percentage for the semiconductor layer 108 and the semiconductor layer 208 can increase the on-state current, field-effect mobility, or the like of the transistors. Furthermore, with the element M, generation of oxygen vacancies (V_{O}) can be inhibited. The content percentage of the element M (the proportion of the number of atoms of the element M in the total number of atoms of all the metal elements contained) is preferably higher than or equal to 0.1% and lower than or equal to 3%, further preferably higher than or equal to 0.1% and lower than or equal to 2%. Accordingly, a transistor with favorable electrical characteristics can be provided. For example, a metal oxide with In:M:Zn of 40:1:10 or the neighborhood thereof is preferably used. The element M is preferably one or more kinds of the above elements, further preferably one or more kinds selected from aluminum, gallium, tin, and yttrium. Specifically, a metal oxide with In:Sn:Zn of 40:1:10 or the neighborhood thereof can be suitably used. Alternatively, a metal oxide with In:Al:Zn of 40:1:10 or the neighborhood thereof can be suitably used.

Here, in the case where a metal oxide having a polycrystalline structure is used for the semiconductor layer 108 and the semiconductor layer 208, the grain boundary becomes a recombination center and captures carriers and thus might reduce the on-state current of the transistor. In the case where a metal oxide with a composition that tends to form a polycrystalline structure is used, the metal oxide preferably includes an element that hinders crystallization. For example, indium tin oxide including silicon (ITSO) is less likely to have a polycrystalline structure than indium tin oxide (ITO), and thus can be suitably used for the semiconductor layer 108 and the semiconductor layer 208. In the case where ITSO is used, the content percentage of silicon (the proportion of the number of silicon atoms in the total number of atoms of all the metal elements contained) is preferably higher than or equal to 1% and lower than or equal to 20%, further preferably higher than or equal to 3% and lower than or equal to 20%, further preferably higher than or equal to 3% and lower than or equal to 15%, still further preferably higher than or equal to 5% and lower than or equal to 15%. Specifically, a metal oxide with In:Sn:Si of 45:5:4, In:Sn:Si of 95:5:8, or the neighborhood thereof can be suitably used.

For analysis of the compositions of the semiconductor layer 108 and the semiconductor layer 208, for example, energy dispersive X-ray spectrometry (EDX), X-ray photoelectron spectrometry (XPS), inductively coupled plasma-mass spectrometry (ICP-MS), or inductively coupled plasma-atomic emission spectrometry (ICP-AES) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element Mis low, for example, the content percentage of the element M obtained by analysis may be lower than the actual content percentage.

A sputtering method or an atomic layer deposition (ALD) method can be suitably used to form the metal oxide. In the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

The semiconductor layer 108 and the semiconductor layer 208 may each have a stacked-layer structure including two or more metal oxide layers. The two or more metal oxide layers included in each of the semiconductor layer 108 and the semiconductor layer 208 may have the same composition or substantially the same compositions. When the compositions of the stacked metal oxide layers are the same, they can be formed using the same sputtering target, for example, and the manufacturing cost can thus be reduced.

The two or more metal oxide layers included in each of the semiconductor layer 108 and the semiconductor layer 208 may have different compositions. For example, a stacked-layer structure of a first metal oxide layer having a composition of In:M:Zn=1:3:4 [atomic ratio] or in the neighborhood thereof and a second metal oxide layer having a composition of In:M:Zn=1:1:1 [atomic ratio] or in the neighborhood thereof and being provided over the first metal oxide layer can be suitably employed. In addition, it is particularly preferable to use gallium, aluminum, or tin as the element M. The element M in the first metal oxide layer and that in the second metal oxide layer may be the same or different from each other. For example, the first metal oxide layer and the second metal oxide layer may be IGZO layers having different compositions.

For example, a stacked-layer structure of the first metal oxide layer having In:Zn=4:1 [atomic ratio] or a composition in the neighborhood thereof and the second metal oxide layer having In:M:Zn=1:1:1 [atomic ratio] or a composition in the neighborhood thereof and being provided over the first metal oxide layer can be suitably used.

For example, a stacked-layer structure of any one selected from indium oxide, indium gallium oxide, and IGZO, and any one selected from IAZO, IAGZO, and ITZO (registered trademark) may be employed.

In the case where the first metal oxide layer including a first metal oxide and the second metal oxide layer including a second metal oxide form a stacked-layer structure and the first metal oxide and the second metal oxide have the same composition or substantially the same compositions, the boundary (interface) between the first metal oxide layer and the second metal oxide layer cannot clearly be observed in some cases.

It is preferable to use a metal oxide having crystallinity for the semiconductor layer 108 and the semiconductor layer 208. Examples of the structure of a metal oxide having crystallinity include a CAAC (c-axis aligned crystal) structure, a polycrystalline structure, and a nano-crystal (nc) structure. With use of a metal oxide having crystallinity, the density of defect states in the semiconductor layer 108 and the semiconductor layer 208 can be reduced, which enables the semiconductor device to have high reliability.

The semiconductor layer 108 and the semiconductor layer 208 are each preferably formed using a CAAC-OS or an nc-OS.

The CAAC-OS includes a plurality of layered crystals. The c-axis of the crystal is aligned in the normal direction of the formation surface. The semiconductor layer 108 and the semiconductor layer 208 each preferably include a layered crystal parallel or substantially parallel to the formation surface. For example, the semiconductor layer 108 preferably includes a layered crystal parallel or substantially parallel to the top surface of the conductive layer 112b in a region in contact with the top surface, and a layered crystal parallel or substantially parallel to the side surface of the conductive layer 112b in a region in contact with the side surface. In particular, in the opening 141, the semiconductor layer 108 preferably includes a layered crystal parallel or substantially parallel to the side surface of the insulating layer 110 serving as the formation surface. With such a structure, the layered crystals of the semiconductor layer 108 are formed substantially parallel to the channel length direction of the transistor 100, so that the on-state current of the transistor can be increased. Similarly, the semiconductor layer 208 preferably includes a layered crystal parallel or substantially parallel to the formation surface (here, the side surface of the insulating layer 110, the side surface of the conductive layer 212a, and the side surface of the conductive layer 212b). In particular, in a region overlapping with the conductive layer 204, the semiconductor layer 208 preferably includes a layered crystal parallel or substantially parallel to the side surface of the insulating layer 110 serving as the formation surface.

The use of a metal oxide having high crystallinity in a channel formation region can reduce the density of defect states in the channel formation region. By contrast, the use of a metal oxide having low crystallinity enables a transistor to flow a large amount of current.

In the case where the metal oxide is formed by a sputtering method, the crystallinity of the formed metal oxide can be increased as the substrate temperature at the time of formation is higher. For example, the substrate temperature at the time of formation can be adjusted by the temperature of the stage on which the substrate is placed at the time of formation. Furthermore, the higher the proportion of the flow rate of an oxygen gas to the total flow rate of the film formation gas used for the formation (also referred to as an oxygen flow rate ratio) or the oxygen partial pressure in a treatment chamber is, the higher the crystallinity of the formed metal oxide layer can be.

The crystallinity of the semiconductor layer 108 and the semiconductor layer 208 can be analyzed with X-ray diffraction (XRD), a transmission electron microscope (TEM), electron diffraction (ED), or the like, for example. Alternatively, such kinds of analysis methods may be performed in combination.

In the case where a metal oxide is used for the semiconductor layer 108 and the semiconductor layer 208, V_{O}H in the channel formation regions is preferably reduced as much as possible so that the semiconductor layer 108 and the semiconductor layer 208 become highly purified intrinsic or substantially highly purified intrinsic semiconductor layers. In order to obtain such a metal oxide with sufficiently reduced V_{O}H, it is important to remove impurities such as water and hydrogen in the metal oxide (this treatment is sometimes referred to as dehydration or dehydrogenation treatment) and supply oxygen to the metal oxide to repair oxygen vacancies (V_{O}). When a metal oxide in which impurities such as V_{O}H are sufficiently reduced is used for a channel formation region of a transistor, stable electrical characteristics can be given. Supplying oxygen to a metal oxide to repair oxygen vacancies (V_{O}) is sometimes referred to as oxygen adding treatment.

When a metal oxide is used for each of the semiconductor layer 108 and the semiconductor layer 208, the carrier concentration in the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm⁻³, yet still further preferably lower than 1×10¹² cm⁻³. Note that the lower limit of the carrier concentration in the channel formation region is not particularly limited and can be, for example, 1×10⁻⁹ cm⁻³.

A change in electrical characteristics of an OS transistor due to irradiation with radiation is small, i.e., an OS transistor has high resistance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

The semiconductor layer 108 and the semiconductor layer 208 may each include a layered material serving as a semiconductor. The layered substance is a general term of a group of materials having a layered crystal structure. The layered crystal structure is a structure in which layers formed by covalent bonding or ionic bonding are stacked with bonding such as the Van der Waals bonding, which is weaker than covalent bonding or ionic bonding. The layered substance has high electrical conductivity in a unit layer, that is, high two-dimensional electrical conductivity. When a material serving as a semiconductor and having high two-dimensional electrical conductivity is used for a channel formation region, a transistor having a high on-state current can be provided.

Examples of the layered substances include graphene, silicene, and chalcogenide. Chalcogenide is a compound including chalcogen (an element belonging to Group 16). Examples of chalcogenide include transition metal chalcogenide and chalcogenide of Group 13 elements. Specific examples of the transition metal chalcogenide that can be used for a channel formation region of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### [Insulating Layer 106]

The insulating layer 106 may have a single-layer structure or a stacked-layer structure of two or more layers. The insulating layer 106 preferably includes one or more inorganic insulating films. Examples of a material that can be used for the inorganic insulating film include an oxide, a nitride, an oxynitride, and a nitride oxide. For the insulating layer 106, a material usable for the insulating layer 110 can be used.

The insulating layer 106 includes a region in contact with the semiconductor layer 108 and a region in contact with the semiconductor layer 208. In the case where a metal oxide is used for the semiconductor layer 108 and the semiconductor layer 208, any of the above-described oxides and oxynitrides is preferably used for at least a film of the insulating layer 106 that is in contact with the semiconductor layer 108 and the semiconductor layer 208. It is further preferable that a film from which oxygen is released by heating be used for the insulating layer 106.

Specifically, in the case where the insulating layer 106 has a single-layer structure, the insulating layer 106 is preferably formed using an oxide or an oxynitride. Specifically, silicon oxide or silicon oxynitride can be suitably used for the insulating layer 106.

In the case where the insulating layer 106 has a stacked-layer structure, an insulating film in contact with the semiconductor layer 108 and the semiconductor layer 208 preferably includes an oxide or an oxynitride, and an insulating film in contact with the conductive layer 104 and the conductive layer 204 preferably includes a nitride or an nitride oxide. As the oxide or the oxynitride, for example, silicon oxide or silicon oxynitride can be suitably used. As the nitride or the nitride oxide, silicon nitride or silicon nitride oxide can be suitably used.

Silicon nitride and silicon nitride oxide release a smaller amount of impurities (e.g., water and hydrogen) and are less likely to transmit oxygen and hydrogen, and thus can be suitably used for the insulating layer 106. Diffusion of impurities from the insulating layer 106 to the semiconductor layer 108 and the semiconductor layer 208 is inhibited, whereby the transistors can have favorable electrical characteristics and high reliability.

A miniaturized transistor including a thin gate insulating layer might have a high leakage current. When a high dielectric constant material (also referred to as a high-k material) is used for the gate insulating layer, the voltage at the time of operation of the transistor can be reduced while the physical thickness is maintained. Examples of the high-k material usable for the insulating layer 106 include gallium oxide, hafnium oxide, zirconium oxide, an oxide including aluminum and hafnium, an oxynitride including aluminum and hafnium, an oxide including silicon and hafnium, an oxynitride including silicon and hafnium, and a nitride including silicon and hafnium.

### [Insulating Layer 195]

It is preferable to use a material that does not easily allow diffusion of impurities for the insulating layer 195 serving as a protective layer of the transistor 100 and the transistor 200. Providing the insulating layer 195 can effectively inhibit diffusion of impurities into the transistors from the outside and can increase the reliability of the semiconductor device. Examples of the impurities include water and hydrogen.

The insulating layer 195 can be an insulating layer including an inorganic material or an insulating layer including an organic material. For example, an inorganic material such as an oxide, an oxynitride, a nitride oxide, or a nitride can be suitably used for the insulating layer 195. Specifically, one or more of silicon nitride, silicon nitride oxide, silicon oxynitride, aluminum oxide, aluminum oxynitride, aluminum nitride, hafnium oxide, and hafnium aluminate can be used. As the organic material, for example, one or more of an acrylic resin and a polyimide resin can be used. As the organic material, a photosensitive material may be used. A stack including two or more of the above insulating films may also be used. The insulating layer 195 may have a stacked-layer structure of an insulating layer including an inorganic material and an insulating layer including an organic material.

### [Substrate 102]

There is no particular limitation on the properties of the material of the substrate 102 as long as the material has heat resistance high enough to withstand at least heat treatment to be performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. The substrate 102 may be provided with a semiconductor element. Note that the shape of the semiconductor substrate and an insulating substrate may be circular or square.

A flexible substrate may be used as the substrate 102, and the transistor 100 and the like may be formed directly on the flexible substrate. Alternatively, a separation layer may be provided between the substrate 102 and the transistor 100 and the like. With the separation layer, part or the whole of a semiconductor device completed thereover can be separated from the substrate 102 and transferred onto another substrate. In that case, the transistor 100 and the like can be transferred onto a substrate having low heat resistance or a flexible substrate as well.

As the substrate 102, the above-described substrate over which an insulating layer is stacked may be used.

A structure example of a semiconductor device whose structure is partly different from that of Structure example 1 shown above will be described below. Note that description of the same portions as those in Structure example 1 shown above is omitted below in some cases. Furthermore, in drawings that are referred to later, the same hatching pattern is applied to portions having functions similar to those in Structure example 1 shown above, and the portions are not denoted by reference numerals in some cases.

### <Structure Example 2 of Semiconductor Device>

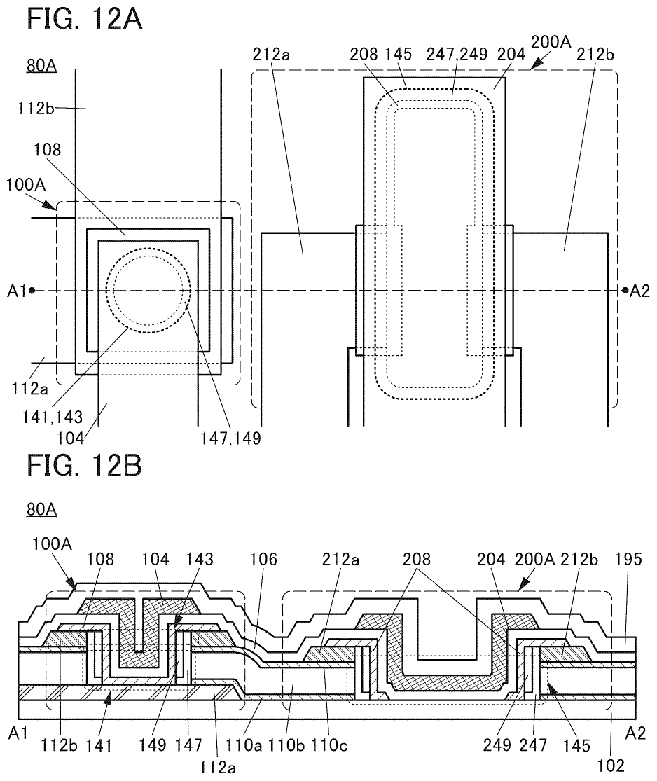

FIG. 12A shows a top view of a semiconductor device 80A of one embodiment of the present invention. FIG. 12B shows a cross-sectional view of a cross section along the dashed-dotted line A1-A2 in FIG. 12A.

The semiconductor device 80A includes a transistor 100A, a transistor 200A, and the insulating layer 110. The transistor 100A is different from the transistor 100 shown in FIG. 9A and the like mainly in that an insulating layer 147 and an insulating layer 149 are included and in that the semiconductor layer 108 is in contact with the top surface of the conductive layer 112b. The transistor 200A is different from the transistor 200 shown in FIG. 9A and the like mainly in that an insulating layer 247 and an insulating layer 249 are included and in that the semiconductor layer 208 is in contact with the top surface of the conductive layer 212a and the top surface of the conductive layer 212b.

In the transistor 200A, the insulating layer 247 and the insulating layer 249 are provided between the insulating layer 110 and the semiconductor layer 208, between the conductive layer 212a and the semiconductor layer 208, and between the conductive layer 212b and the semiconductor layer 208.

The insulating layer 147 and the insulating layer 247 are in contact with the side surface of the insulating layer 110, the side surface of the conductive layer 212a, the side surface of the conductive layer 212b, the top surface of the substrate 102, the side surface of the semiconductor layer 208, the side surface and the bottom surface of the insulating layer 249, and the bottom surface of the insulating layer 106. As shown in FIG. 12B, a protruding portion is formed in a portion of the insulating layer 247 that is in contact with the top surface of the substrate 102 in a cross-sectional view. An end portion of the protruding portion of the insulating layer 247 is in contact with the semiconductor layer 208. The protruding portion of the insulator 247 protrudes toward the center of the opening 145 more than the other portion of the insulator 247.

The insulating layer 147 and the insulating layer 247 each preferably have a barrier property against hydrogen and each particularly preferably have high capability of inhibiting diffusion of hydrogen. As the insulator 247, one or more of aluminum oxide, magnesium oxide, hafnium oxide, gallium oxide, silicon nitride, and silicon nitride oxide can be used, for example. For example, silicon nitride can be suitably used for the insulating layer 247. Providing the insulating layer 247 can inhibit diffusion of hydrogen in the semiconductor layer 208 from the outside of the transistor 200 through the insulating layer 247.

The insulating layer 149 and the insulating layer 249 are each in contact with the side surface of the insulating layer 247, the top surface of the protruding portion of the insulating layer 247, and the side surface and the bottom surface of the semiconductor layer 208. As shown in FIG. 12B, the side surface of the insulating layer 249 is flush with the side end portion of the protruding portion of the insulating layer 247 in the cross-sectional view in some cases.

The insulating layer 149 and the insulating layer 249 each preferably have a barrier property against hydrogen, and particularly preferably have high capability of capturing or fixing (also referred to as gettering) hydrogen. For the insulating layer 249, one or more of an oxide including magnesium and an oxide including one or both of aluminum and hafnium can be used, for example. These oxides preferably have an amorphous structure. In a metal oxide having an amorphous structure, an oxygen atom has a dangling bond and has a property of capturing or fixing hydrogen with the dangling bond in some cases. Note that these metal oxides preferably have an amorphous structure, but a crystal region may be partly formed. Examples of the material having high capability of inhibiting diffusion of hydrogen include silicon nitride and silicon nitride oxide. For the insulating layer 249, hafnium oxide can be suitably used, for example. With the insulating layer 249, hydrogen included in the insulating layer 110 can be captured or fixed by the insulating layer 249, for example. As shown in FIG. 12, the transistor 200A includes the insulating layer 247 and the insulating layer 249; thus, in the case where an oxide semiconductor is used for the semiconductor layer 208, hydrogen, water, or the like that might enter the oxide semiconductor can be removed, which enables the semiconductor device to have high reliability.

In the transistor 100A, the insulating layer 147 and the insulating layer 149 are provided between the insulating layer 110 and the semiconductor layer 108 and between the conductive layer 112b and the semiconductor layer 108.

The insulating layer 147 is in contact with the side surface of the insulating layer 110, the side surface of the conductive layer 112b, the top surface of the conductive layer 112a, the side surface of the semiconductor layer 108, the side surface and the bottom surface of the insulating layer 149, and the bottom surface of the insulating layer 106. As shown in FIG. 12B, a protruding portion is formed in a portion of the insulating layer 147 that is in contact with the top surface of the conductive layer 112a in a cross-sectional view. An end portion of the protruding portion of the insulating layer 147 is in contact with the semiconductor layer 108. The protruding portion of the insulator 147 protrudes toward the center of the opening 141 more than the other portion of the insulator 147.

For the insulating layer 147, a material usable for the insulating layer 247 can be used. The insulating layer 147 and the insulating layer 247 can be formed through the same steps. For example, a film to be the insulating layer 247 and the insulating layer 147 is formed and processed, so that the insulating layer 247 and the insulating layer 147 can be formed.

The insulating layer 149 is in contact with the side surface of the insulating layer 147, the top surface of the protruding portion of the insulating layer 147, and the side surface and the bottom surface of the semiconductor layer 108. As shown in FIG. 12B, the side surface of the insulating layer 149 is flush with the side end portion of the protruding portion of the insulating layer 147 in the cross-sectional view in some cases.

For the insulating layer 149, a material usable for the insulating layer 249 can be used. The insulating layer 149 and the insulating layer 249 can be formed through the same steps. For example, a film to be the insulating layer 249 and the insulating layer 149 is formed and processed, so that the insulating layer 249 and the insulating layer 149 can be formed.

Note that the structures of the insulating layer 147, the insulating layer 149, the insulating layer 247, the insulating layer 249, the semiconductor layer 108, and the semiconductor layer 208 described here can also be applied to other structure examples.

### <Structure Example 3 of Semiconductor Device>

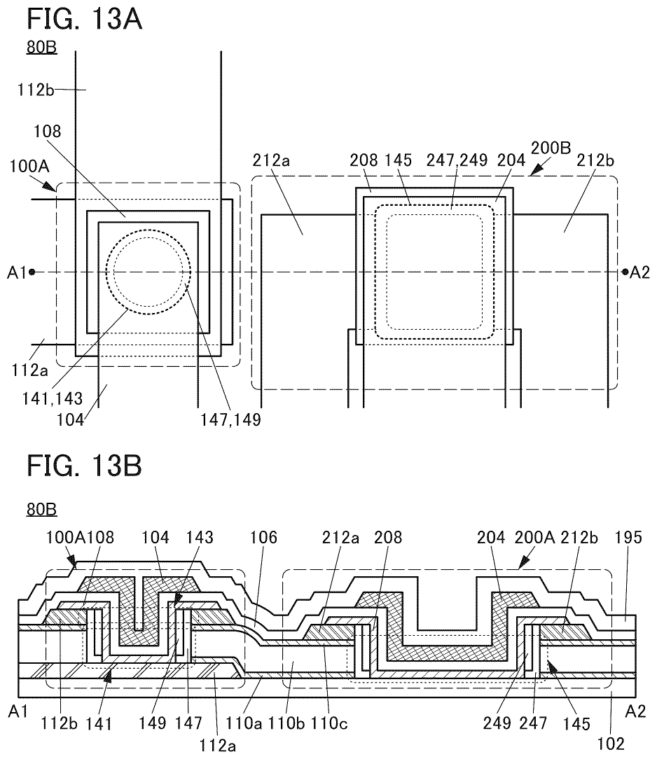

FIG. 13A is a top view of a semiconductor device 80B of one embodiment of the present invention. FIG. 13B is a cross-sectional view along the dashed-dotted line A1-A2 in FIG. 13A.

The semiconductor device 80B includes the transistor 100A, a transistor 200B, and the insulating layer 110. The transistor 200B is different from the transistor 200A shown in FIG. 13A and the like mainly in that the semiconductor layer 208 is provided also in the bottom portion of the opening 145. The transistor 200B employs the above-described structure of the transistor 200A.

Note that the structure of the semiconductor layer 208 described here can also be applied to other structure examples.

### <Manufacturing Method Example 1>

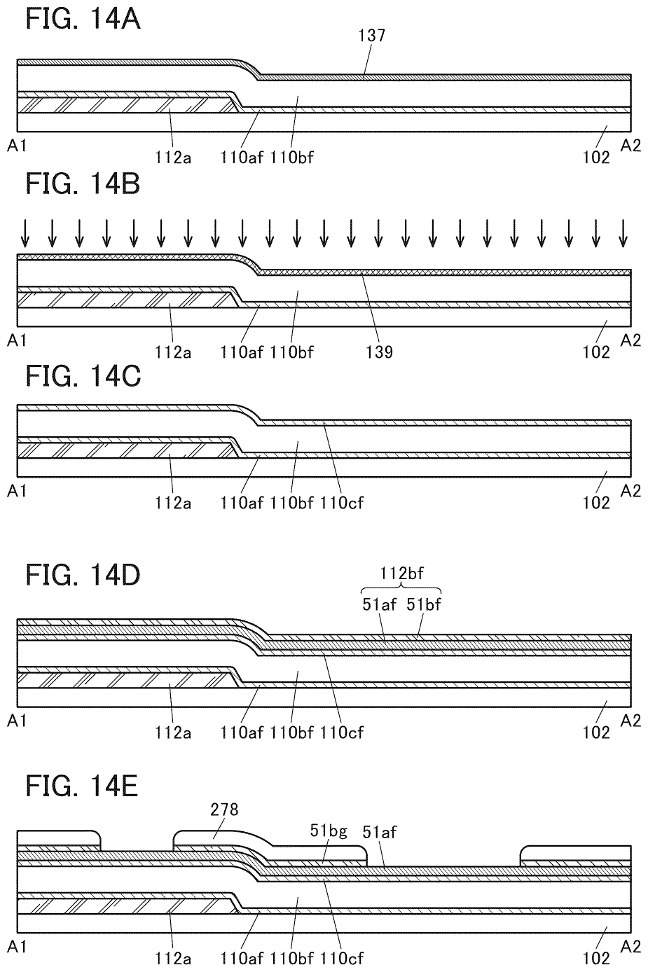

A method for manufacturing a semiconductor device of one embodiment of the present invention will be described below with reference to FIG. 14A to FIG. 19B. Note that as for a material and a formation method of each component, portions similar to the portions described in Embodiment 2 are not described in some cases.

Thin films included in the semiconductor device (e.g., insulating films, semiconductor films, and conductive films) can be formed by a sputtering method, a chemical vapor deposition (CVD) method, a vacuum evaporation method, a pulsed laser deposition (PLD) method, an ALD method, a molecular beam epitaxy (MBE) method, or the like. Examples of a CVD method include a PECVD method and a thermal CVD method. An example of a thermal CVD method is a metal organic CVD (MOCVD) method.

Thin films included in the semiconductor device (e.g., insulating films, semiconductor films, and conductive films) can be formed by a wet film formation method such as spin coating, dipping, spray coating, ink-jetting, dispensing, screen printing, offset printing, a doctor knife method, slit coating, roll coating, curtain coating, or knife coating.

When the thin films included in the semiconductor device are processed, a photolithography method or the like can be used. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of a photolithography method. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed. Alternatively, ultraviolet rays, KrF laser light, ArF laser light, or the like can be used. The light exposure may be performed by liquid immersion exposure technique. As the light used for the light exposure, extreme ultraviolet (EUV) light or X-rays may be used. Instead of the light used for the light exposure, an electron beam can be used. Extreme ultraviolet light, X-rays, or an electron beam is preferably used, in which case extremely fine processing can be performed. Note that a photomask is not needed when the light exposure is performed by scanning with a beam such as an electron beam.

For etching of thin films, one or more selected from a dry etching method, a wet etching method, and a sandblast method can be used.

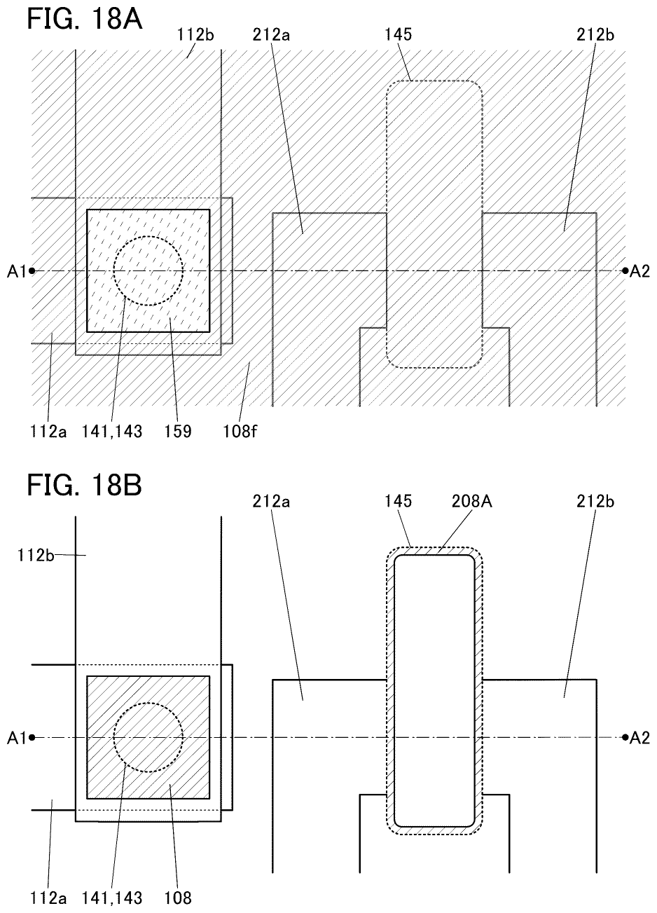

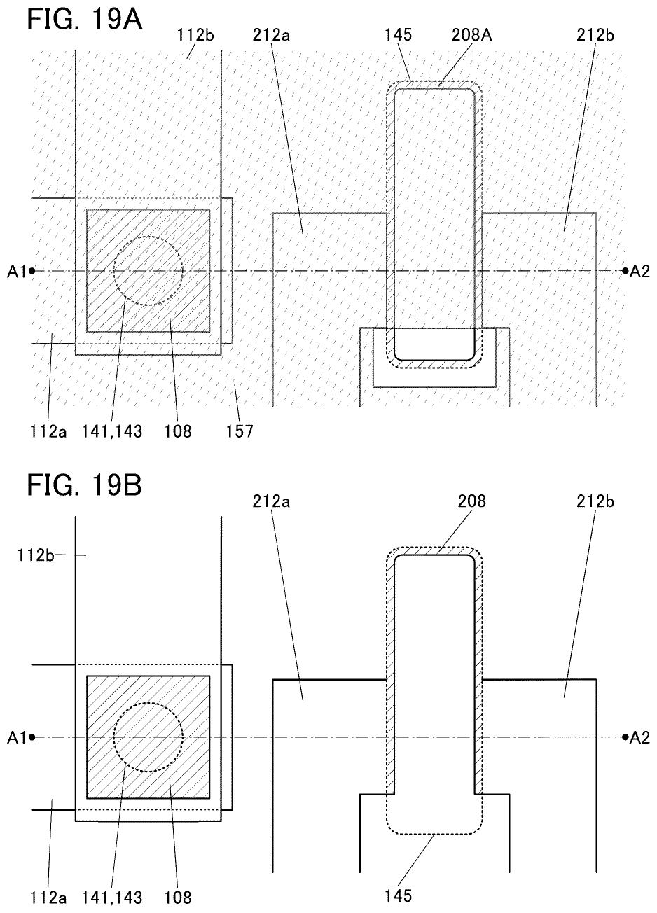

Here, an example of a method for manufacturing the semiconductor device 80 shown in FIG. 9A and FIG. 9B is described with reference to FIG. 14A to FIG. 19B. FIG. 14A to FIG. 17B each show a cross-sectional view taken along a dashed-dotted line A1-A2 in FIG. 9A. FIG. 18A to FIG. 19B show top views.

First, a film to be the conductive layer 112a is formed over the substrate 102, and the film is processed to form the conductive layer 112a. For the formation of the film, a sputtering method can be suitably used.

Next, the insulating film 110af to be the insulating layer 110a and the insulating film 110bf to be the insulating layer 110b are formed over the substrate 102 and the conductive layer 112a (FIG. 14A).

A sputtering method or a PECVD method can be suitably used for the formation of the insulating film 110af and the insulating film 110bf. It is preferable that the insulating film 110bf be formed in a vacuum successively after the formation of the insulating film 110af, without exposure of the surface of the insulating film 110af to the air. The successive formation of the insulating film 110af and the insulating film 110bf inhibits attachment of atmospherically derived impurities to the surface of the insulating film 110af. Examples of the impurities include water and organic substances.

The substrate temperatures at the time of forming the insulating film 110af and the insulating film 110bf are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperatures at the time of forming the insulating film 110af and the insulating film 110bf are in the above range, impurities (e.g., water and hydrogen) released from the insulating films themselves can be reduced, which inhibits diffusion of the impurities to the semiconductor layer 108. Consequently, a transistor with favorable electrical characteristics and high reliability can be obtained.

Note that since the insulating film 110af and the insulating film 110bf are formed earlier than the semiconductor layer 108 and the semiconductor layer 208, there is no need to consider the probability of oxygen release from the semiconductor layer 108 and the semiconductor layer 208 due to heat applied thereto at the time of forming the insulating film 110af and the insulating film 110bf.

After the insulating film 110bf is formed, oxygen may be supplied to the insulating film 110bf. As a method for supplying oxygen, an ion implantation method, an ion doping method, a plasma immersion ion implantation method, or plasma treatment can be used, for example. For the plasma treatment, an apparatus in which an oxygen gas is made to be plasma by high-frequency power can be suitably used. Examples of the apparatus in which a gas is made to be plasma by high-frequency power include a PECVD apparatus, a plasma etching apparatus, and a plasma ashing apparatus. The plasma treatment is preferably performed in an atmosphere including oxygen. For example, plasma treatment is preferably performed in an atmosphere including one or more of oxygen, dinitrogen monoxide (N₂O), nitrogen dioxide (NO₂), carbon monoxide, and carbon dioxide.

Note that the plasma treatment may be successively performed in a vacuum without exposure of the surface of the insulating film 110bf to the air. For example, in the case where a PECVD apparatus is used for forming the insulating film 110bf, the plasma treatment is preferably performed with the PECVD apparatus. Accordingly, the productivity can be increased. Specifically, after the insulating film 110bf is formed with the PECVD apparatus, N₂O plasma treatment can be successively performed in a vacuum.

The metal oxide layer 137 is preferably formed over the insulating film 110bf (FIG. 14A). The formation of the metal oxide layer 137 enables oxygen supply to the insulating film 110bf.

There is no limitation on the conductivity of the metal oxide layer 137. As the metal oxide layer 137, at least one of an insulating film, a semiconductor film, and a conductive film can be used. For the metal oxide layer 137, aluminum oxide, hafnium oxide, hafnium aluminate, indium oxide, indium tin oxide (ITO), or indium tin oxide including silicon (ITSO) can be used, for example.

An oxide material including one or more elements that are the same as those in the semiconductor layer 108 and the semiconductor layer 208 is preferably used for the metal oxide layer 137. It is particularly preferable to use an metal oxide material that can be used for the semiconductor layer 108 and the semiconductor layer 208.

At the time of forming the metal oxide layer 137, the amount of oxygen supplied into the insulating film 110bf can be increased with a higher oxygen flow rate ratio in the film formation gas introduced into a processing chamber of a film formation apparatus or with a higher oxygen partial pressure in the processing chamber. The oxygen flow rate ratio or the oxygen partial pressure is, for example, higher than or equal to 50% and lower than 100%, higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure be as close to 100% as possible.

When the metal oxide layer 137 is formed by a sputtering method in an atmosphere including oxygen in the above manner, oxygen can be supplied to the insulating film 110bf and release of oxygen from the insulating film 110bf can be prevented during the formation of the metal oxide layer 137. As a result, a large amount of oxygen can be enclosed in the insulating film 110bf. Moreover, a large amount of oxygen can be supplied to the semiconductor layer 108 by heat treatment performed later. Thus, the amounts of oxygen vacancies and V_{O}H in the semiconductor layer 108 can be reduced, whereby a transistor with favorable electrical characteristics and high reliability can be obtained.

After the metal oxide layer 137 is formed, heat treatment may be performed. By the heat treatment performed after the formation of the metal oxide layer 137, oxygen can be effectively supplied from the metal oxide layer 137 to the insulating film 110bf.

The temperature of the heat treatment is preferably higher than or equal to 150° C., higher than or equal to 200° C., higher than or equal to 230° C., or higher than or equal to 250° C. and lower than the strain point of the substrate, lower than or equal to 450° C., lower than or equal to 400° C., lower than or equal to 350° C., or lower than or equal to 300° C. The heat treatment can be performed in an atmosphere including one or more of a noble gas, nitrogen, and oxygen. As an atmosphere including nitrogen or an atmosphere including oxygen, clean dry air (CDA) may be used. The content of hydrogen, water, or the like in the atmosphere is preferably as low as possible. As the atmosphere, a high-purity gas with a dew point of −60° C. or lower, preferably −100° C. or lower is preferably used. With use of an atmosphere where the content of hydrogen, water, or the like is as low as possible, entry of hydrogen, water, or the like into the insulating film 110af and the insulating film 110bf can be prevented as much as possible. An oven, a rapid thermal annealing (RTA) apparatus, or the like can be used for the heat treatment. With the RTA apparatus, the heat treatment time can be shortened.

After the formation of the metal oxide layer 137 or after the above-described heat treatment, oxygen may be further supplied to the insulating film 110bf through the metal oxide layer 137. As a method for supplying oxygen, an ion implantation method, an ion doping method, a plasma immersion ion implantation method, or plasma treatment can be used, for example. The above description can be referred to for the plasma treatment; thus, the detailed description thereof is omitted.

Then, the metal oxide layer 137 is removed. There is no particular limitation on a method for removing the metal oxide layer 137, and a wet etching method can be suitably used. With use of a wet etching method, the insulating film 110bf can be inhibited from being etched at the time of removing the metal oxide layer 137. This can inhibit a reduction in the thickness of the insulating film 110bf and the thickness of the insulating layer 110b can be uniform.

After the metal oxide layer 137 is removed, oxygen may be further supplied to the insulating film 110bf. The above description can be referred to for a method for supplying oxygen. For example, as shown in FIG. 14B, a film 139 may be formed over the insulating film 110bf and oxygen may be supplied to the insulating film 110bf through the film 139. As the treatment, plasma treatment in an atmosphere including oxygen can be used. FIG. 14B schematically shows a state where oxygen is supplied to the insulating film 110bf by arrows.

As the film 139, a conductive film or a semiconductor film is preferably used. As the film 139, a metal oxide film, a metal film, or an alloy film can be used. The film 139 is preferably formed using a metal oxide in an atmosphere including oxygen by a sputtering method or the like, in which case oxygen can be supplied to the insulating film 110bf also at the time of forming the film 139.

The thickness of the film 139 is preferably small. Specifically, the thickness of the film 139 is preferably greater than or equal to 1 nm, greater than or equal to 2 nm, or greater than or equal to 3 nm and less than or equal to 20 nm, less than or equal to 15 nm, or less than or equal to 10 nm. Typically, the thickness can be approximately 5 nm.

The substrate temperature at the time of forming the film 139 is preferably lower than or equal to 350° C., further preferably lower than or equal to 340° C., still further preferably lower than or equal to 330° C., yet still further preferably lower than or equal to 300° C. Accordingly, the amount of oxygen supplied to the insulating film 110bf can be increased.

By providing the film 139, when a bias voltage is applied between a pair of electrodes at the time of supplying oxygen, ionized oxygen is easily drawn. Accordingly, the amount of oxygen supplied to the insulating film 110bf can be increased.

As a treatment apparatus for supplying oxygen, a dry etching apparatus, an ashing apparatus, or a PECVD apparatus can be suitably used. In particular, an ashing apparatus is preferably used. When a bias voltage is applied between a pair of electrodes in the treatment apparatus, the bias voltage may be higher than or equal to 10 V and lower than or equal to 1 kV, for example. The power density of the bias may be higher than or equal to 1 W/cm² and lower than or equal to 5 W/cm², for example.

Next, the film 139 is removed. For the removal of the film 139, a wet etching method can be suitably used.

The treatment for supplying oxygen to the insulating film 110bf is not necessarily performed in the above-described manner. For example, an oxygen radical, an oxygen atom, an oxygen atomic ion, or an oxygen molecular ion is supplied to the insulating film 110bf by an ion doping method, an ion implantation method, or plasma treatment. Alternatively, a film that inhibits oxygen release may be formed over the insulating film 110bf, and then oxygen may be supplied to the insulating film 110bf through the film. After the supply of oxygen, the film is preferably removed. As the film that inhibits oxygen release, a conductive film or a semiconductor film including one or more of indium, zinc, gallium, tin, aluminum, chromium, tantalum, titanium, molybdenum, nickel, iron, cobalt, and tungsten can be used.

Next, the insulating film 110cf to be the insulating layer 110c is formed over the insulating film 110bf (FIG. 14C). The description of the formation of the insulating film 110af and the insulating film 110bf can be referred to for the formation of the insulating film 110cf; thus, the detailed description thereof is omitted.

Next, the conductive film 51af to be the conductive layer 51a, the conductive layer 52a, and the conductive layer 53a is formed over the insulating film 110cf. Subsequently, the metal film 51bf to be the metal layer 51b, the metal layer 52b, and the metal layer 53b is formed (FIG. 14D). For the formation of each of the conductive film 51af and the metal film 51bf, FIG. 1A in the above embodiment can be referred to.

Next, an opening is provided in the metal film 51bf, so that the metal layer 51bg is formed (FIG. 14E). For the method for providing the opening in the metal film 51bf, FIG. 1A to FIG. 2A in the above embodiment can be referred to. Alternatively, FIG. 5A to FIG. 5C can be referred to. Here, an example in which the metal layer 51bg is formed using the coating film 278 with reference to FIG. 5A to FIG. 5C is described.

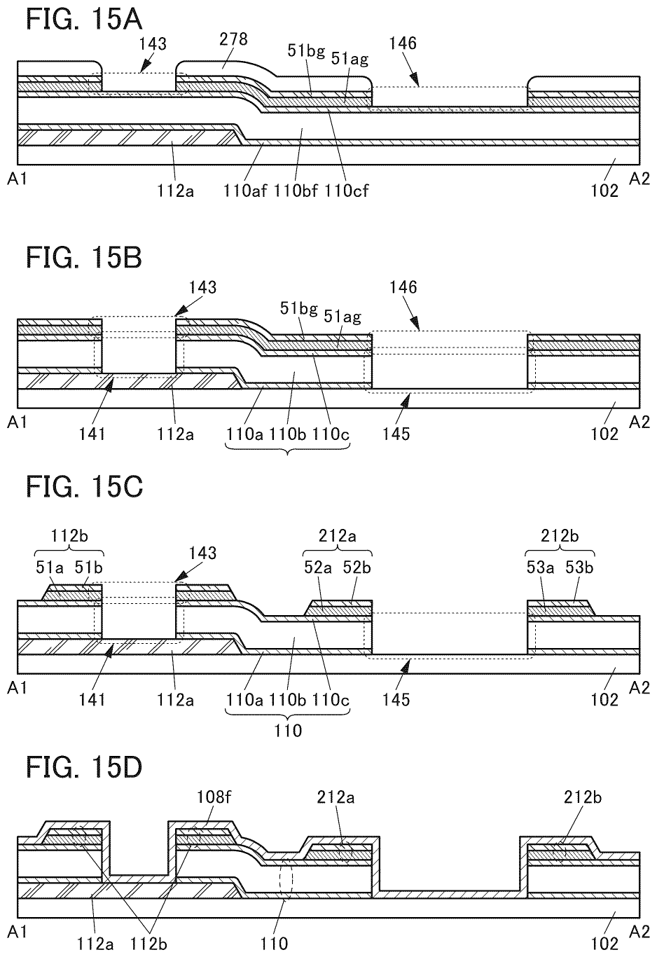

Next, the conductive film 51af is processed using the metal layer 51bg as a mask to form the conductive layer 51ag (FIG. 15A). For the formation of the conductive layer 51ag, FIG. 2B or FIG. 6A in the above embodiment can be referred to. Here, an example that refers to FIG. 6A is shown. Although the opening 143 is shown in FIG. 2B and FIG. 6A, the opening 143 and an opening 146 are provided here.

Next, part of the insulating film 110af, part of the insulating film 110bf, and part of the insulating film 110cf are removed using the metal layer 51bg as a mask, so that the insulating layer 110 including the opening 141 and the opening 145 is formed (FIG. 15B). For the formation of the insulating layer 110, FIG. 2C or FIG. 6B in the above embodiment can be referred to. Although the opening 141 is shown in FIG. 2C and FIG. 6B, the opening 141 and the opening 145 are provided here.

The opening 141 is provided in a region overlapping with the opening 143. The conductive layer 112a is exposed by the formation of the opening 141, and the substrate 102 is exposed by the formation of the opening 145. For the formation of the insulating layer 110, a dry etching method can be suitably used, for example.

Note that in the formation of the opening 141 or after the formation of the opening 141, part of the conductive layer 112a in a region overlapping with the opening 141 may be removed. When the thickness of the region of the conductive layer 112a that is in contact with the bottom surface of the semiconductor layer 108 is smaller than the thickness of the region of the conductive layer 112a that is not in contact with the semiconductor layer 108, the electric field of the gate electrode applied to the channel formation region in the vicinity of the conductive layer 112a can be intensified, leading to a high on-state current of the transistor.

Next, part of the metal layer 51bg and part of the conductive layer 51ag are etched to form the metal layer 51b and the conductive layer 51a, whereby the conductive layer 112b having the stacked-layer structure of the conductive layer 51a and the metal layer 51b is obtained (FIG. 15C). The etching conditions of the metal film 51bf and the conductive film 51af can be used as the etching conditions of the conductive layer 51ag and part of the metal layer 51bg, for example. The conductive layer 51ag and the part of the metal layer 51bg can be etched using a resist mask, for example.

Next, a metal oxide film 108f to be the semiconductor layer 108 and the semiconductor layer 208 is formed so as to cover the opening 141, the opening 143, and the opening 145 (FIG. 15D). The metal oxide film 108f is provided in contact with the top surface and the side surface of the conductive layer 112b, the top surface and the side surface of the insulating layer 110, the top surface of the conductive layer 112a, the top surface and the side surface of the conductive layer 212a, the top surface and the side surface of the conductive layer 212b, and the top surface of the substrate 102.

The metal oxide film 108f is preferably formed by a sputtering method using a metal oxide target. Alternatively, the metal oxide film 108f is preferably formed by an ALD method. An ALD method offers high coverage, and thus can be suitably used for forming the metal oxide film 108f provided to cover the opening 141, the opening 143, and the opening 145. By an ALD method, a metal oxide film can be formed also on the side surface of the insulating layer 110 with high coverage. In an ALD method, the film formation rate can be easily controlled, so that a thin film can be formed with high yield.

The metal oxide film 108f is preferably a dense film with as few defects as possible. The metal oxide film 108f is preferably a highly purified film in which impurities including a hydrogen element are reduced as much as possible. It is particularly preferable to use a metal oxide film having crystallinity as the metal oxide film 108f.

In forming the metal oxide film 108f, an oxygen gas is preferably used. With the use of an oxygen gas, oxygen can be suitably supplied into the insulating layer 110. For example, in the case of using an oxide or an oxynitride for the insulating layer 110b, oxygen can be suitably supplied into the insulating layer 110b.

By the supply of oxygen to the insulating layer 110b, oxygen is supplied to the channel formation region of the semiconductor layer 108 and the semiconductor layer 208 in a later step, so that oxygen vacancies and V_{O}H in the channel formation region can be reduced.

In forming the metal oxide film 108f, an oxygen gas and an inert gas (e.g., a helium gas, an argon gas, or a xenon gas) may be mixed. Note that when the proportion of the oxygen gas to the whole film formation gas (oxygen flow rate ratio) or the oxygen partial pressure in the treatment chamber is higher in forming the metal oxide film, the metal oxide film can have higher crystallinity and the transistor can have higher reliability. On the other hand, when the oxygen flow rate ratio or the oxygen partial pressure is lower, the metal oxide film can have lower crystallinity and higher electrical conductivity and the transistor can have a higher on-state current.

Here, when the oxygen flow rate ratio or the oxygen partial pressure is high, the metal oxide film has a polycrystalline structure in some cases. In the case of a metal oxide film having a polycrystalline structure, the grain boundary becomes a recombination center and captures carriers and thus might reduce the on-state current of the transistor. Thus, the oxygen flow rate ratio or the oxygen partial pressure is preferably adjusted so that the metal oxide film 108f does not have a polycrystalline structure. Since the ease of forming the polycrystalline structure depends on the composition of the metal oxide film, the oxygen flow rate ratio or the oxygen partial pressure is adjusted in accordance with the composition of the metal oxide film 108f.

When the substrate temperature is higher in forming the metal oxide film, a denser metal oxide film having higher crystallinity can be formed. On the other hand, as the substrate temperature becomes lower, a metal oxide film having lower crystallinity and higher electric conductivity can be formed.

The substrate temperature during the formation of the metal oxide film 108f is preferably higher than or equal to room temperature and lower than or equal to 250° C., further preferably higher than or equal to room temperature and lower than or equal to 200° C., still further preferably higher than or equal to room temperature and lower than or equal to 140° C. For example, the substrate temperature is preferably set higher than or equal to room temperature and lower than or equal to 140° C. to increase the productivity. When the metal oxide film 108f is formed with the substrate temperature set at room temperature or without heating the substrate, the metal oxide film 108f can have low crystallinity.

When the substrate temperature is high, the metal oxide film has a polycrystalline structure in some cases. The substrate temperature is preferably adjusted so that the metal oxide film 108f does not have a polycrystalline structure. The substrate temperature is adjusted in accordance with the composition employed for the metal oxide film 108f.

In the case of employing an ALD method, a film formation method such as a thermal ALD method or a PEALD (Plasma Enhanced ALD) is preferably employed. The thermal ALD method is preferable because of its capability of offering extremely high coverage. The PEALD method is preferable because of its capability of forming a film at low temperatures, in addition to its capability of offering high coverage.

For example, the metal oxide film can be formed by an ALD method using a precursor including a constituent metal element and an oxidizer.

For example, in the case where In—Ga—Zn oxide is formed, three precursors of a precursor including indium, a precursor including gallium, and a precursor including zinc can be used. Alternatively, two precursors of a precursor including indium and a precursor including gallium and zinc may be used.

Examples of the precursor including indium include triethylindium, tris(2,2,6,6-tetramethyl-3,5-heptanedionato) indium, cyclopentadienylindium, indium(III) chloride, and (3-(dimethylamino)propyl)dimethylindium.

Examples of the precursor including gallium include trimethylgallium, triethylgallium, gallium trichloride, tris(dimethylamido)gallium, gallium(III) acetylacetonate, tris(2,2,6,6-tetramethyl-3,5-heptanedionato) gallium, dimethylchlorogallium, diethylchlorogallium, and gallium(III) chloride.

Examples of the precursor including zinc include dimethylzinc, diethylzinc, bis(2,2,6,6-tetramethyl-3,5-heptanedionato) zinc, and zinc chloride.

Examples of the oxidizer include ozone, oxygen, and water.

As a method for controlling the composition of a film to be obtained, adjusting one or more of the kinds of source gases, the flow rate ratio of source gases, the flowing time of the source gases, and the order in which the source gases flow is given. By adjusting these, the composition of the metal oxide film 108f can be controlled. Moreover, by adjusting these, a film whose composition is continuously changed can also be formed. The composition of the metal oxide film 108f may be continuously changed.

Before the formation of the metal oxide film 108f, at least one of treatment for desorbing water, hydrogen, an organic substance, and the like adsorbed on the surface of the insulating layer 110, and treatment for supplying oxygen into the insulating layer 110 is preferably performed. For example, heat treatment can be performed at a temperature higher than or equal to 70° C. and lower than or equal to 200° C. in a reduced-pressure atmosphere. Alternatively, plasma treatment in an atmosphere including oxygen may be performed. Alternatively, oxygen may be supplied to the insulating layer 110 by performing plasma treatment in an atmosphere including an oxidizing gas such as dinitrogen monoxide (N₂O). When plasma treatment is performed using a dinitrogen monoxide gas, an organic substance on the surface of the insulating layer 110 can be suitably removed and oxygen can be supplied. The metal oxide film 108f is preferably formed successively after such treatment without exposure of the surface of the insulating layer 110 to the air.

Note that in the case where each of the semiconductor layer 108 and the semiconductor layer 208 has a stacked-layer structure, an upper metal oxide film is preferably formed successively after the formation of a lower metal oxide film without exposure of the surface of the lower metal oxide layer to the air.

In the case where the semiconductor layer 108 and the semiconductor layer 208 each have a stacked-layer structure, all the layers included in the semiconductor layer 108 and the semiconductor layer 208 may be formed by the same film formation method (e.g., a sputtering method or an ALD method) or the layers may be formed by different film formation methods. For example, the first metal oxide layer may be formed by a sputtering method and the second metal oxide layer may be formed by an ALD method.

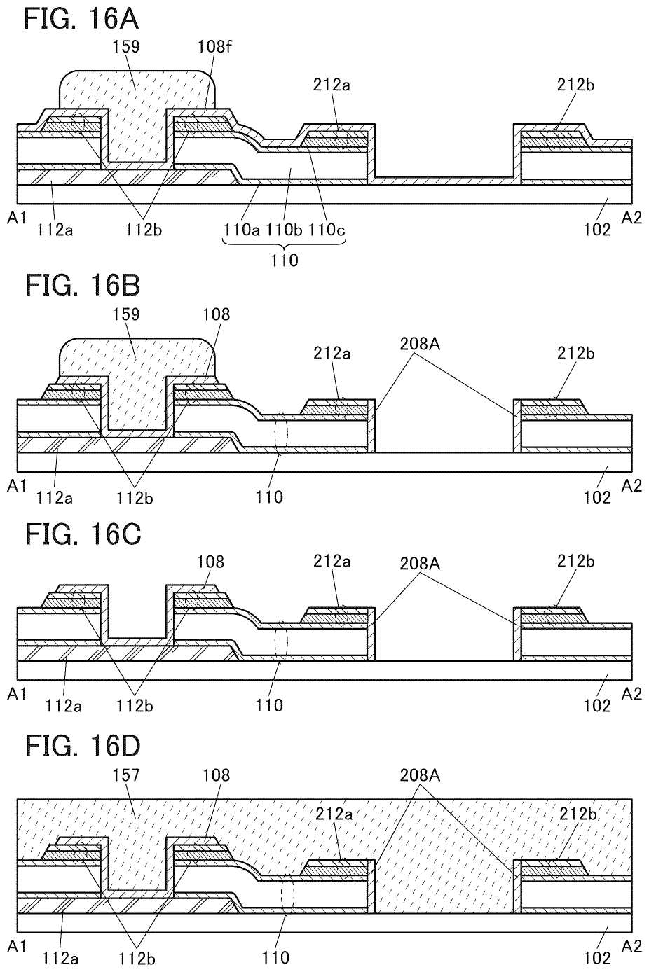

Then, a resist mask 159 is formed over the metal oxide film 108f (FIG. 16A and FIG. 18A). The resist mask 159 is provided in a region where the semiconductor layer 108 is formed so as to cover at least the opening 141 and the opening 143. Note that in FIG. 18A, the metal oxide film 108f and the resist mask 159 are shown with hatching patterns. For the sake of easy understanding of the structure below the metal oxide film 108f, the hatching pattern of the metal oxide film 108f is shown transparently.

Next, the metal oxide film 108f is processed into an island shape to form the semiconductor layer 108 and a semiconductor layer 208A to be the semiconductor layer 208 (FIG. 16B and FIG. 18B). For the formation of the semiconductor layer 108 and the semiconductor layer 208A, a dry etching method can be suitably used. In particular, for the formation of the semiconductor layer 108 and the semiconductor layer 208A, an anisotropic dry etching method can be suitably used. The semiconductor layer 108 is formed in a region of the metal oxide film 108f covered with the resist mask 159, and the semiconductor layer 208A is formed in a region in contact with the side surface of the opening 145. In FIG. 18B, the semiconductor layer 108 and the semiconductor layer 208A are shown with hatching patterns.

Next, the resist mask 159 is removed (FIG. 16C).

Subsequently, a resist mask 157 is formed over the semiconductor layer 108, the semiconductor layer 208A, the conductive layer 112b, the conductive layer 212a, the conductive layer 212b, the insulating layer 110, and the substrate 102 (FIG. 16(DC) and FIG. 19A). The resist mask 157 is provided to cover at least the semiconductor layer 108 and a region of the semiconductor layer 208A to be the semiconductor layer 208. At this time, a region of the semiconductor layer 208A that is not provided with the semiconductor layer 208 is exposed. In FIG. 19A, the semiconductor layer 108, the semiconductor layer 208A, and the resist mask 157 are shown with hatching patterns. For the sake of easy understanding of the structure below the resist mask 157, the hatching pattern of the resist mask 157 is shown transparently.

Next, the region of the semiconductor layer 208A not covered with the resist mask 157 is removed, so that the semiconductor layer 208 is formed. For the formation of the semiconductor layer 208, one or both of a wet etching method and a dry etching method can be used. In particular, a dry etching method can be suitably used.

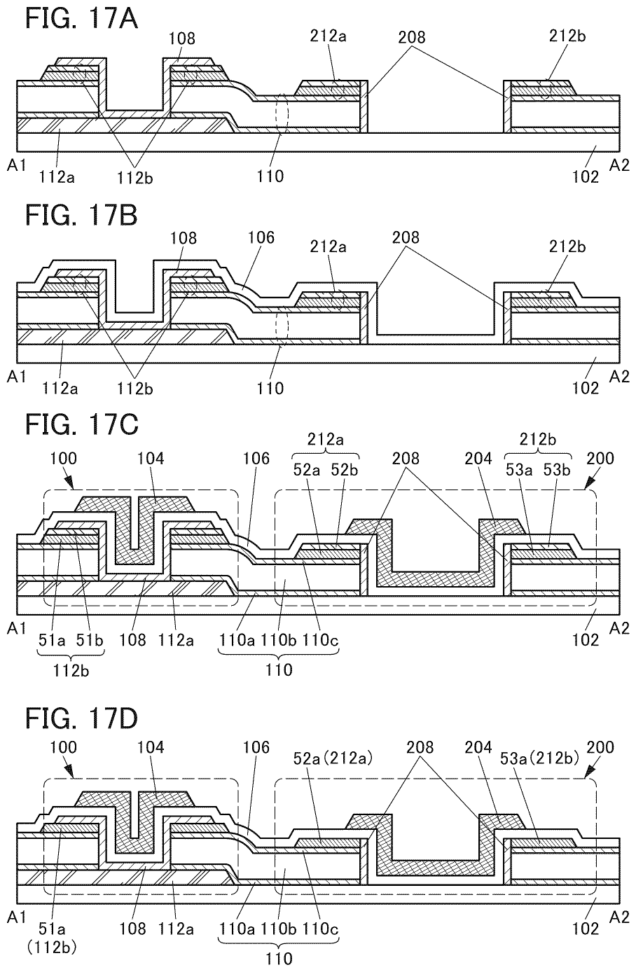

Next, the resist mask 157 is removed (FIG. 17A and FIG. 19B). In FIG. 19B, the semiconductor layer 108 and the semiconductor layer 208 are shown with hatching patterns.

Heat treatment is preferably performed after the metal oxide film 108f is formed or after the metal oxide film 108f is processed into the semiconductor layer 108 and the semiconductor layer 208. By the heat treatment, hydrogen or water included in the metal oxide film 108f or the semiconductor layer 108 and the semiconductor layer 208 or adsorbed on the surface of the metal oxide film 108f or the semiconductor layer 108 and the semiconductor layer 208 can be removed. Furthermore, the film quality of the metal oxide film 108f or the semiconductor layer 108 and the semiconductor layer 208 is improved (e.g., the number of defects is reduced or the crystallinity is increased) by the heat treatment in some cases.

Oxygen can be supplied from the insulating layer 110b to the metal oxide film 108f or the semiconductor layer 108 by heat treatment. Thus, oxygen vacancies (V_{O}) in the channel formation region can be reduced. In this case, it is further preferable that the heat treatment be performed before processing the metal oxide film 108f into the semiconductor layer 108 and the semiconductor layer 208. The above description can be referred to for the heat treatment; thus, the detailed description thereof is omitted. Note that supply of oxygen to the channel formation region may be performed not only through the heat treatment but also in a heat application step in and after the formation of the metal oxide film 108f (e.g., the step of forming the insulating layer 106).

The heat treatment is not necessarily performed when not needed. The heat treatment is not necessarily performed in this step, and heat treatment performed in a later step may also serve as the heat treatment in this step. In some cases, treatment at high temperatures (e.g., a film formation step) in a later step serves as the heat treatment in this step.

Then, the insulating layer 106 is formed to cover the semiconductor layer 108, the semiconductor layer 208, the insulating layer 110, and the substrate 102 (FIG. 17B). For the formation of the insulating layer 106, for example, a PECVD method or an ALD method can be suitably used.

In the case of using a metal oxide for the insulating layer 108 and the semiconductor layer 208, the insulating layer 106 preferably serves as a barrier film inhibiting diffusion of oxygen. When the insulating layer 106 has a function of inhibiting diffusion of oxygen, oxygen included in the semiconductor layer 108 and the semiconductor layer 208 is inhibited from being diffused to above the insulating layer 106, and an increase in oxygen vacancies (V_{O}) in the semiconductor layer 108 and the semiconductor layer 208 can be suppressed. Consequently, a transistor with favorable electrical characteristics and high reliability can be obtained.

In this specification and the like, a barrier film refers to a film having a barrier property. For example, an insulating layer having a barrier property can be referred to as a barrier insulating layer. In this specification and the like, a barrier property means a function of inhibiting diffusion of a particular substance (or low permeability) and/or a function of capturing or fixing (also referred to as gettering) a particular substance.

When the temperature at the time of forming the insulating layer 106 serving as the gate insulating layer is increased, an insulating layer with few defects can be obtained. However, the high temperature at the time of forming the insulating layer 106 sometimes allows release of oxygen from the semiconductor layer 108 and the semiconductor layer 208, which increases the amount of oxygen vacancies (V_{O}) and V_{O}H in the semiconductor layer 108 and the semiconductor layer 208 in some cases. The substrate temperature at the time of forming the insulating layer 106 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 106 is in the above range, release of oxygen from the semiconductor layer 108 and the semiconductor layer 208 can be inhibited while the defects in the insulating layer 106 can be reduced. Consequently, a transistor with favorable electrical characteristics and high reliability can be obtained.

It is preferable to perform plasma treatment on the surfaces of the semiconductor layer 108 and the semiconductor layer 208 before the formation of the insulating film 106. By the plasma treatment, impurities such as water adsorbed on the surfaces of the semiconductor layer 108 and the semiconductor layer 208 can be reduced. Thus, impurities at the interface between the semiconductor layer 108 and the insulating layer 106 and the interface between the semiconductor layer 208 and the insulating layer 106 can be reduced, and highly reliable transistors can be provided. The plasma treatment is particularly suitable in the case where the surfaces of the semiconductor layer 108 and the semiconductor layer 208 are exposed to the air in a period between the formation of the semiconductor layer 108 and the semiconductor layer 208 and the formation of the insulating layer 106. The plasma treatment can be performed in, for example, an atmosphere of oxygen, ozone, nitrogen, dinitrogen monoxide, argon, or the like. The plasma treatment and the formation of the insulating layer 106 are preferably performed successively without exposure to the air.

Then, a film to be the conductive layer 104 and the conductive layer 204 is formed over the insulating layer 106 and is processed, so that the conductive layer 104 and the conductive layer 204 are formed (FIG. 17C). For the formation of the film, a sputtering method, a thermal CVD method (including an MOCVD method), or an ALD method can be suitably used, for example.

Subsequently, the insulating layer 195 is formed to cover the conductive layer 104, the conductive layer 204, and the insulating layer 106 (FIG. 9B). For the formation of the insulating layer 195, a PECVD method can be suitably used.

Heat treatment may be performed after the formation of the insulating layer 195. Note that the heat treatment is not necessarily performed. The heat treatment is not necessarily performed in this step, and heat treatment performed in a later step may also serve as the heat treatment in this step. In the case where treatment at a high temperature (e.g., film formation step) is performed in a later step, such treatment can serve as the heat treatment in this step in some cases.

Through the above steps, the semiconductor device of one embodiment of the present invention can be manufactured.

### <Structure Example 4 of Semiconductor Device>

FIG. 17D shows a structure in which the conductive layer 112b has a single-layer structure of the conductive layer 51a, the conductive layer 212a has a single-layer structure of the conductive layer 52a, and the conductive layer 212b has a single-layer structure of the conductive layer 53a. The structure shown in FIG. 17D can be manufactured with reference to the manufacturing method in FIG. 3B in the above embodiment.

At least part of the structure examples, the drawings corresponding thereto, and the like described in this embodiment can be combined with the other structure examples, the other drawings corresponding thereto, and the like as appropriate.

### Embodiment 3

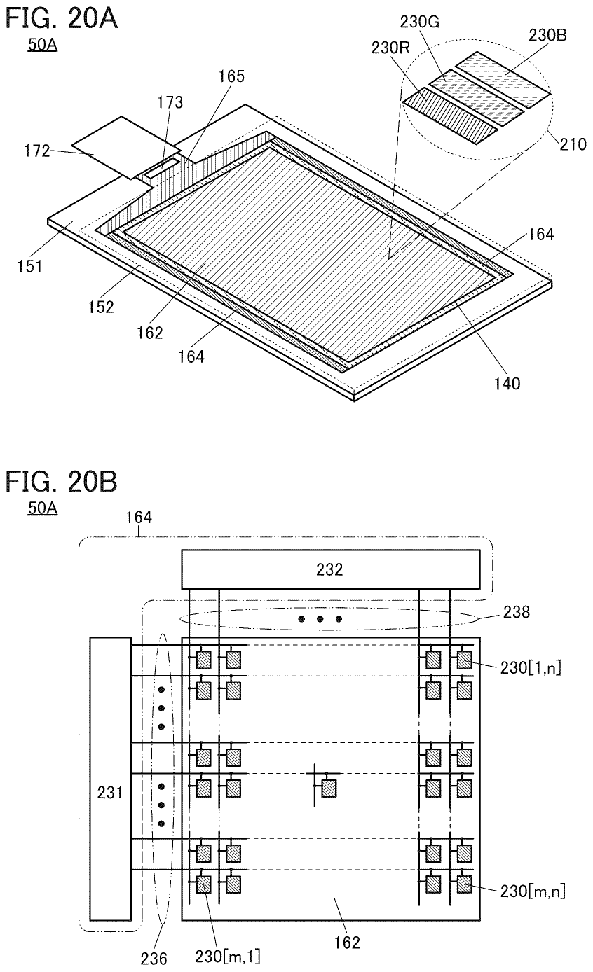

In this embodiment, a display apparatus of one embodiment of the present invention will be described with reference to FIG. 20 to FIG. 23.

The display apparatus of this embodiment can be a high-resolution display apparatus or a large-sized display apparatus. Accordingly, the display apparatus of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop computer, a monitor of a computer or the like, digital signage, and a large game machine such as a pachinko machine.

The display apparatus of this embodiment can be a display apparatus having high resolution. Accordingly, the display apparatus of this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The semiconductor device of one embodiment of the present invention can be used for a display apparatus or a module including the display apparatus. Examples of the module including the display apparatus are a module in which a connector such as a flexible printed circuit board (hereinafter referred to as an FPC) or a tape carrier package (TCP) is attached to the display apparatus and a module in which the display apparatus is mounted with an integrated circuit (IC) by a chip on glass (COG) method, a chip on film (COF) method, or the like.

The display apparatus of this embodiment may have a function of a touch panel. The display apparatus can employ any of a variety of sensor elements that can sense proximity or touch of a sensing target such as a finger, for example.

Examples of a sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The mutual capacitive type is preferably used, in which case multiple points can be sensed simultaneously.

Examples of a touch panel include an out-cell touch panel, an on-cell touch panel, and an in-cell touch panel. An in-cell touch panel has a structure where an electrode included in a sensor element is provided on one or both of a substrate supporting a display element (also referred to as a display device) and a counter substrate.

### <Structure Example 1 of Display Apparatus>

FIG. 20A is a perspective view of a display apparatus 50A.

In the display apparatus 50A, a substrate 152 and a substrate 151 are bonded to each other. In FIG. 20A, the substrate 152 is indicated by a dashed line.

The display apparatus 50A includes a display portion 162, a connection portion 140, a circuit portion 164, a conductive layer 165, and the like. FIG. 20A shows an example in which an IC 173 and an FPC 172 are mounted onto the display apparatus 50A. Thus, the structure shown in FIG. 20A can be regarded as a display module including the display device 50A, the IC, and the FPC.

The connection portion 140 is provided outside the display portion 162. The connection portion 140 can be provided along one or more sides of the display portion 162. The number of connection portions 140 may be one or more. FIG. 20A shows an example in which the connection portion 140 is provided to surround the four sides of the display portion. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The conductive layer 165 has a function of supplying a signal and power to the display portion 162 and the circuit portion 164. The signal and power are input to the conductive layer 165 from the outside through the FPC 172 or input to the conductive layer 165 from the IC 173.

FIG. 20A shows an example in which the IC 173 is provided on the substrate 151 by a COG method, a COF method, or the like. An IC including one or both of a scan line driver circuit and a signal line driver circuit can be used as the IC 173, for example. Note that the display apparatus 50A and the display module are not necessarily provided with an IC. The IC may be mounted on the FPC by a COF method or the like.

The semiconductor device of one embodiment of the present invention can be used for one or both of the display portion 162 and the circuit portion 164 of the display apparatus 50A, for example.

In the case where the semiconductor device of one embodiment of the present invention is used for a pixel circuit of a display apparatus, for example, the area occupied by the pixel circuit can be reduced and the display apparatus can have high resolution. In the case where the semiconductor device of one embodiment of the present invention is used for a driver circuit (e.g., one or both of a gate line driver circuit and a source line driver circuit) of a display apparatus, for example, the area occupied by the driver circuit can be reduced and the display apparatus can have a narrow bezel. Since the semiconductor device of one embodiment of the present invention has favorable electrical characteristics, a display apparatus can have increased reliability by using the semiconductor device.

The display portion 162 of the display apparatus 50A is a region where an image is to be displayed, and includes a plurality of pixels 210 that are periodically arranged. FIG. 20A is an enlarged view of one pixel 210.

There is no particular limitation on the arrangement of the pixels in the display apparatus of this embodiment, and any of a variety of arrangements can be employed. Examples of the arrangement of the pixels include stripe arrangement, S-stripe arrangement, matrix arrangement, delta arrangement, Bayer arrangement, and PenTile arrangement.

The pixel 210 shown in FIG. 20A includes a pixel 230R emitting red light, a pixel 230G emitting green light, and a pixel 230B emitting blue light. The pixel 230R, the pixel 230G, and the pixel 230B form one pixel 210, which achieves full-color display. The pixel 230R, the pixel 230G, and the pixel 230B each serve as a subpixel. The display apparatus 50A shown in FIG. 20A shows an example in which the pixels 230 each serving as a subpixel are arranged in a stripe pattern. The number of subpixels forming one pixel 210 is not limited to three, and may be four or more. For example, four subpixels emitting light of R, G, B, and white (W) may be included. Alternatively, four subpixels emitting light of four colors, R, G, B, and Y may be included.

The pixel 230R, the pixel 230G, and the pixel 230B each include a display element and a circuit for controlling the driving of the display element.

A variety of elements can be used as the display element, and a liquid crystal element (also referred to as a liquid crystal device) or a light-emitting device can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (quantum-dot LED) employing a light source and color conversion technology using quantum dot materials may be used.

As examples of a display apparatus using a liquid crystal element, a transmissive liquid display apparatus, a reflective liquid display apparatus, and a transflective liquid display apparatus can be given.

Examples of a mode that can be used for a display apparatus using a liquid crystal element include a vertical alignment (VA) mode, an FFS (Fringe Field Switching) mode, an IPS (In-Plane Switching) mode, a TN (Twisted Nematic) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, and a guest-host mode. Examples of the VA mode include an MVA (Multi-Domain Vertical Alignment) mode, a PVA (Patterned Vertical Alignment) mode, and an ASV (Advanced Super View) mode.

Examples of a liquid crystal material that can be used for the liquid crystal element, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, and an anti-ferroelectric liquid crystal. These liquid crystal materials exhibit a cholesteric phase, a smectic phase, a cubic phase, a chiral nematic phase, an isotropic phase, a blue phase, or the like depending on conditions. As the liquid crystal material, either a positive liquid crystal or a negative liquid crystal may be used, and the selection can be made in accordance with the mode or design that is used.

Examples of light-emitting devices are self-luminous type light-emitting devices such as an LED (Light Emitting Diode), an OLED (Organic LED), and a semiconductor laser. As the LED, for example, a mini LED, a micro LED, or the like can be used.

Examples of a light-emitting substance included in the light-emitting device include a substance that emits fluorescent light (a fluorescent material), a substance that emits phosphorescent light (a phosphorescent material), a substance exhibiting thermally activated delayed fluorescence (a thermally activated delayed fluorescent (TADF) material), and an inorganic compound (e.g., a quantum dot material).

The emission color of the light-emitting device can be infrared, red, green, blue, cyan, magenta, yellow, white, or the like. Furthermore, color purity can be increased when the light-emitting device has a microcavity structure.

One of the pair of electrodes of the light-emitting device serves as an anode, and the other electrode serves as a cathode.

Note that the display apparatus of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

In this embodiment, the case where a light-emitting device is used as the display element is mainly described as an example.

FIG. 20B is a block diagram showing the display apparatus 50A. The display apparatus 50A includes the display portion 162 and the circuit portion 164. The display portion 162 includes a plurality of pixels 230 arranged periodically (a pixel 230[1,1] to a pixel 230[m,n], where each of m and n is independently an integer greater than or equal to 2). The circuit portion 164 includes a first driver circuit portion 231 and a second driver circuit portion 232.

A circuit included in the first driver circuit portion 231 serves as, for example, a scan line driver circuit. A circuit included in the second driver circuit portion 232 serves as, for example, a signal line driver circuit. Note that some sort of circuit may be provided at a position facing the first driver circuit portion 231 with the display portion 162 therebetween. Some sort of circuit may be provided at a position facing the second driver circuit portion 232 with the display portion 162 therebetween.

Any of various circuits such as a shift register circuit, a level shifter circuit, an inverter circuit, a latch circuit, an analog switch circuit, a demultiplexer circuit, and a logic circuit can be used for the circuit portion 164. In the circuit portion 164, a transistor, a capacitor, and the like can be used. Transistors included in the circuit portion 164 may be formed in the same step as transistors included in the pixels 230.

The display apparatus 50A includes wirings 236 which are arranged substantially parallel to each other and whose potentials are controlled by the circuits included in the first driver circuit portion 231, and wirings 238 which are arranged substantially parallel to each other and whose potentials are controlled by the circuits included in the second driver circuit portion 232. FIG. 20B shows an example in which the wirings 236 and the wirings 238 are connected to the pixels 230. Note that the wirings 236 and the wirings 238 are examples, and the wirings connected to the pixels 230 are not limited to the wirings 236 and the wirings 238.

In the semiconductor device of one embodiment of the present invention, some formation steps can be common between a vertical transistor (VFET) having a submicron-sized channel length and a high on-state current and a TGSA transistor having a long channel length and favorable saturation characteristics. An oxide semiconductor (OS) can be suitably used for the channel formation regions of these transistors, so that the transistors can have a low off-state current. The semiconductor device of one embodiment of the present invention can be used for one or both of the display portion 162 and the circuit portion 164. Alternatively, the semiconductor device of one embodiment of the present invention can be used for both the display portion 162 and the circuit portion 164, that is, all the transistors included in the display apparatus can be OS transistors. When all the transistors included in the display apparatus are OS transistors in this manner, an effect of reducing the manufacturing cost can be obtained.

Using a latch circuit as an example, a structure example of a circuit that can be used in the circuit portion 164 will be described.

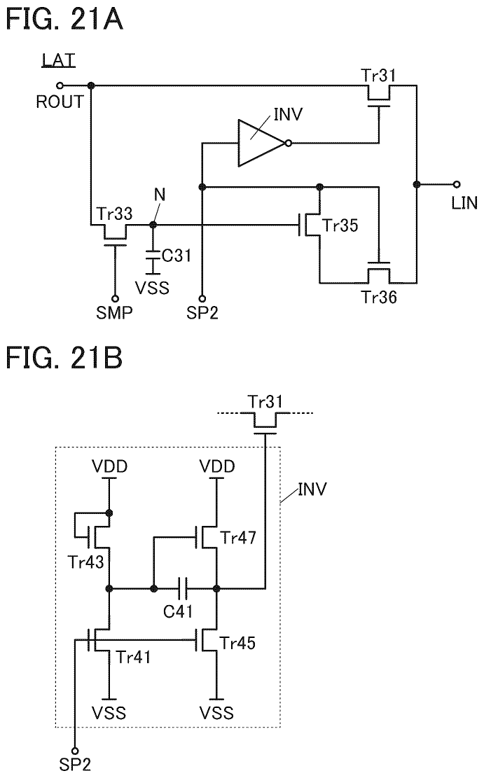

FIG. 21A is a circuit diagram showing a structure example of a latch circuit LAT. The latch circuit LAT shown in FIG. 21A includes a transistor Tr31, a transistor Tr33, a transistor Tr35, a transistor Tr36, a capacitor C31, and an inverter circuit INV. In FIG. 21A, a node where one of a source and a drain of the transistor Tr33, a gate of the transistor Tr35, and one electrode of the capacitor C31 are electrically connected to each other is referred to as a node N.

In the latch circuit LAT shown in FIG. 21A, when a high-potential signal is input to a terminal SMP, the transistor Tr33 is turned on. Thus, the potential of the node N becomes a potential corresponding to the potential of a terminal ROUT, and data corresponding to a signal input from the terminal ROUT to the latch circuit LAT is written to the latch circuit LAT. After data is written to the latch circuit LAT, the potential of the terminal SMP is set to a low potential, so that the transistor Tr33 is turned off. Thus, the potential of the node N is retained and the data written to the latch circuit LAT is retained. Specifically, when the potential of the node N is a low potential, data having a value “0” is retained in the latch circuit LAT and when the potential of the node N is a high potential, data having a value “1” is retained in the latch circuit LAT, for example.

A transistor with a low off-state current is preferably used as the transistor Tr33. An OS transistor can be suitably used as the transistor Tr33. In that case, the latch circuit LAT can retain data for a long period. Thus, the frequency of rewriting data to the latch circuit LAT can be lowered.

In this specification and the like, writing data to the latch circuit LAT such that a signal input from a terminal SP2 is output to a terminal LIN is simply referred to as “writing data to the latch circuit LAT”, in some cases. That is, writing data having a value “1”, for example, to the latch circuit LAT is simply referred to as “writing data to the latch circuit LAT”, in some cases.

The semiconductor device of one embodiment of the present invention can be suitably used for the latch circuit LAT. For example, the transistor 100 or the transistor 200 shown in FIG. 9B or the like can be used as one or more of the transistor Tr31, the transistor Tr33, the transistor Tr35, and the transistor Tr36.

FIG. 21B shows a structure example of the inverter circuit INV. The inverter circuit INV includes a transistor Tr41, a transistor Tr43, a transistor Tr45, a transistor Tr47, and a capacitor C41.

When the latch circuit LAT has the structure shown in FIG. 21A and the inverter circuit INV has the structure shown in FIG. 21B, all the transistors included in the latch circuit LAT can be transistors having the same polarity, for example, n-channel transistors. In that case, the transistor Tr31, the transistor Tr35, the transistor Tr36, the transistor Tr41, the transistor Tr43, the transistor Tr45, and the transistor Tr47 as well as the transistor Tr33 can be OS transistors, for example. Accordingly, all the transistors included in the latch circuit LAT can be formed in the same step.

The semiconductor device of one embodiment of the present invention can be suitably used for the inverter circuit INV. For example, the transistor 100 or the transistor 200 shown in FIG. 9B or the like can be used as one or more of the transistor Tr41, the transistor Tr43, the transistor Tr45, and the transistor Tr47.

Furthermore, one or both of the transistor 200 and the transistor 200A can be suitably used as the transistors that are required to have favorable saturation characteristics. Furthermore, with the use of the transistor 100, the occupied area can be reduced, so that a display apparatus with a narrow bezel can be provided. The transistor 100 can be suitably used as a transistor required to have a high on-state current. In that case, a high-performance display apparatus can be provided.

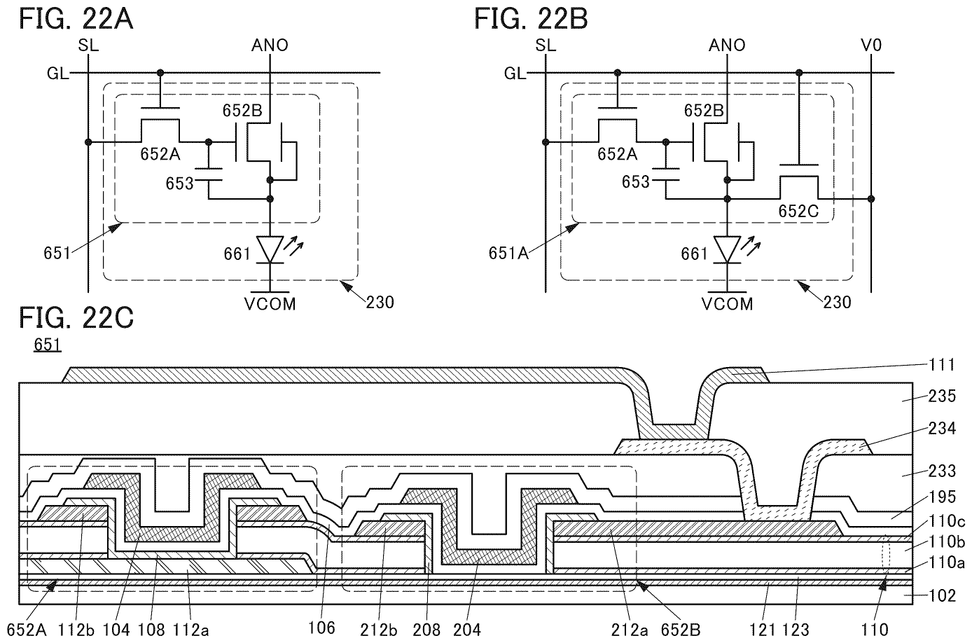

FIG. 22A shows a structure example of the pixel 230. The pixel 230 includes a pixel circuit 651 and a light-emitting device 661.

The pixel circuit 651 shown in FIG. 22A is a 2Tr1C-type pixel circuit including a transistor 652A, a transistor 652B, and a capacitor 653. Note that there is no particular limitation on the pixel circuit that can be used for the display apparatus of one embodiment of the present invention.

An anode of the light-emitting device 661 is electrically connected to one of a source and a drain of the transistor 652B and one electrode of the capacitor 653. The other of the source and the drain of the transistor 652B is electrically connected to a wiring ANO. A gate of the transistor 652B is electrically connected to one of a source and a drain of the transistor 652A and the other electrode of the capacitor 653. The other of the source and the drain of the transistor 652A is electrically connected to a wiring GL. A gate of the transistor 652A is electrically connected to the wiring GL. A cathode of the light-emitting device 661 is electrically connected to a wiring VCOM.

The wiring GL corresponds to the wiring 236, and a wiring SL corresponds to the wiring 238. The wiring VCOM is a wiring supplying a potential for supplying a current to the light-emitting device 661. The transistor 652A has a function of controlling electrical continuity and discontinuity between the wiring SL and the gate of the transistor 652B in accordance with the potential of the wiring GL. For example, VDD is supplied to the wiring ANO, and VSS is supplied to the wiring VCOM.

The transistor 652B has a function of controlling the amount of current flowing through the light-emitting device 661. The capacitor 653 has a function of retaining a gate potential of the transistor 652B. The intensity of light emitted by the light-emitting device 661 is controlled in accordance with an image signal supplied to the gate of the transistor 652B.

Some or all of the transistors included in the pixel circuit 651 may be provided with back gates. In the pixel circuit 651 shown in FIG. 22A, the transistor 652B includes a back gate, and the back gate is electrically connected to the one of the source and the drain of the transistor 652B. Note that a structure where the back gate of the transistor 652B is electrically connected to the gate of the transistor 652B may be employed as well.

The above-described semiconductor device can be suitably used for the pixel circuit 651. The transistor 652B serving as a driving transistor that controls a current flowing through the light-emitting device 661 preferably has more favorable saturation characteristics than the transistor 652A serving as a selection transistor for controlling a selection state of the pixel 230. The use of one type from the transistor 200 and the transistor 200A each having a long channel length as the transistor 652B enables the display apparatus to have high reliability. Furthermore, when the transistor 100 is used as the transistor 652A, the area occupied by the pixel circuit 651A can be reduced, so that a high-definition display apparatus can be obtained.

Note that the transistor 100 may also be used as the transistor 652B. The use of the transistor having a short channel length as the transistor 652B enables the display apparatus to have high luminance. Furthermore, the area occupied by the pixel circuit 651 can be reduced, so that a high-resolution display apparatus can be obtained.

FIG. 22B shows a structure example different from that of the pixel 230 shown in FIG. 22A. The pixel 230 includes the pixel circuit 651A and the light-emitting device 661.

The pixel circuit 651A shown in FIG. 22B is different from the pixel circuit 651 shown in FIG. 22A mainly in including a transistor 652C. The pixel circuit 651A is a 3Tr1C-type pixel circuit including the transistor 652A, the transistor 652B, the transistor 652C, and the capacitor 653.

One of a source and a drain of the transistor 652C is electrically connected to the one of the source and the drain of the transistor 652B. The other of the source and the drain of the transistor 652C is electrically connected to a wiring V0. For example, a reference potential is supplied to the wiring V0. A gate of the transistor 652C is electrically connected to the wiring GL.

The transistor 652C has a function of controlling electrical continuity and discontinuity between the wiring V0 and the one of the source electrode and the drain electrode of the transistor 652B in accordance with the potential of the wiring GL. Variation in the gate-source potential of the transistor 652B can be inhibited by the reference potential of the wiring V0 supplied through the transistor 652C.

A current value that can be used for setting pixel parameters can be obtained with the use of the wiring V0. Specifically, the wiring V0 can serve as a monitor line for outputting, to the outside, a current flowing through the transistor 652B or a current flowing through the light-emitting device 661. A current output to the wiring V0 is converted into a voltage by a source follower circuit and can be output to the outside. Alternatively, the current is converted into a digital signal by an AD converter, and can be output to the outside.

The above-described semiconductor device can be suitably used for the pixel circuit 651A. The use of one type from the transistor 200 and the transistor 200A having a long channel length as the transistor 652B enables the display apparatus to have high reliability. Furthermore, when the transistor 100 is used as each of the transistor 652A and the transistor 652C, the area occupied by the pixel circuit 651A can be reduced, so that a high-definition display apparatus can be obtained. Note that the transistor 100 may also be used as the transistor 652B.

FIG. 22C shows a structure example of the pixel circuit 651. FIG. 22C is a cross-sectional view of the pixel circuit 651. FIG. 22C selectively shows the transistor 652A, the transistor 652B, and the pixel electrode included in the light-emitting device 661. Note that the electrical connection between the transistor 652A and the transistor 652B is not shown.

The transistor 652A includes the conductive layer 104, the insulating layer 106, the semiconductor layer 108, the conductive layer 112a, and the conductive layer 112b. The transistor 652B includes the insulating layer 106, the semiconductor layer 208, the conductive layer 204, the conductive layer 212a, and the conductive layer 212b. The above description can be referred to for the transistor 652A and the transistor 652B; thus, the detailed description is omitted.

The transistor 652A and the transistor 652B are provided over the substrate 102. FIG. 22C shows a structure in which an insulating layer 121 and an insulating layer 123 are provided between the substrate 102 and each of the transistor 652A and the transistor 652B. Note that the semiconductor layer 108 of the transistor 652A is provided over the conductive layer 112a, and the semiconductor layer 208 of the transistor 652B is provided over the insulating layer 123. When the layers over which the semiconductor layers of the two transistors are provided are different in this manner, the transistors having different structures can be easily formed over the same substrate.

The insulating layer 121 preferably has a barrier property against hydrogen, and particularly preferably has high capability of capturing or fixing (gettering) hydrogen. For the insulating layer 121, a material usable for the insulating layer 149 and the insulating layer 249 can be suitably used, for example. For the insulating layer 121, hafnium oxide can be suitably used, for example. For the insulating layer 123 provided over the insulating layer 121, a material usable for the insulating layer 110 can be suitably used, for example. For the insulating layer 123, silicon oxide can be suitably used, for example.

The insulating layer 195 is provided to cover the transistor 652A, the transistor 652B, and the capacitor 653, an insulating layer 233 is provided to cover the insulating layer 195, and an insulating layer 235 is provided to cover the insulating layer 233. The light-emitting device 661 can be provided over the insulating layer 235. FIG. 22C shows a pixel electrode 111 serving as one electrode of the light-emitting device 661. The insulating layer 195 and the insulating layer 233 include a first opening reaching the conductive layer 212a, and a conductive layer 234 is provided to cover the first opening. The conductive layer 234 is electrically connected to the conductive layer 212a through the first opening. The insulating layer 235 includes a second opening reaching the conductive layer 234, and the pixel electrode 111 is provided to cover the second opening. The pixel electrode 111 is electrically connected to the conductive layer 234 through the second opening. The above description can be referred to for the insulating layer 195; thus, the detailed description thereof is omitted. The insulating layer 233 and the insulating layer 235 have a function of reducing unevenness due to the transistor 652A, the transistor 652B, and the transistor 652C and making the formation surface of the light-emitting device 661 flatter. Note that in this specification and the like, each of the insulating layer 233 and the insulating layer 235 is referred to as a planarization layer in some cases.

An organic insulating film is suitable for each of the insulating layer 233 and the insulating layer 235. Examples of a material usable for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The insulating layer 235 preferably has a stacked-layer structure of an organic insulating film and an inorganic insulating film over the organic insulating film. Thus, the inorganic insulating film can serve as an etching protective layer at the time of forming the light-emitting device 661. Specifically, partial etching of the insulating layer 235, which forms a depressed portion in the insulating layer 235, can be inhibited at the time of forming the pixel electrode 111. Alternatively, a depressed portion may be formed in the insulating layer 235 at the time of forming the pixel electrode 111. Similarly, the insulating layer 233 may have a stacked-layer structure of an organic insulating film and an inorganic insulating film.

### <Structure Example 2 of Display Apparatus>

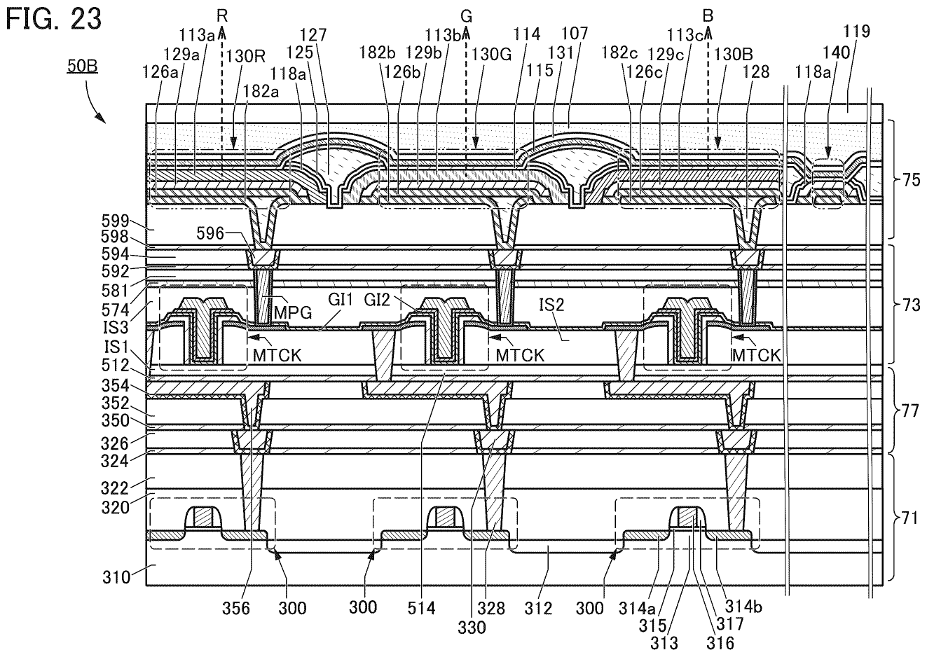

FIG. 23 shows a structure example different from the structure in the above description. A display apparatus 50B has a structure provided with a pixel circuit, a driver circuit, and the like over a substrate 310. The display apparatus 50B includes an element layer 71, an element layer 73, an element layer 75, and a wiring layer 77. The wiring layer 77 is a layer provided with a wiring.

The element layer 71 includes the substrate 310, and a transistor 300 is formed over the substrate 310. The wiring layer 77 is provided above the transistor 300, and the wiring layer 77 is provided with a wiring that electrically connects the transistor 300, a transistor MTCK, a light-emitting device 130R, a light-emitting device 130G, and a light-emitting device 130B. The element layer 73 and the element layer 75 are provided above the wiring layer 77, and the element layer 73 includes the transistor MTCK and the like. The element layer 75 includes the light-emitting devices 130 (the light-emitting device 130R, the light-emitting device 130G, and the light-emitting device 130B in FIG. 23), for example.

The transistor 300 can be a transistor included in the element layer 71. The transistor MTCK can be a transistor included in the element layer 73. The light-emitting device 130 can be a light-emitting device included in the element layer 75.

As the substrate 310, a semiconductor substrate (e.g., a single crystal substrate including silicon or germanium as a material) can be used, for example. Besides the semiconductor substrate, for example, an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film including a fibrous material can be used as the substrate 310. In the description in this embodiment, the substrate 310 is a semiconductor substrate including silicon as a material. Thus, a transistor included in the element layer 71 can be a Si transistor.

The transistor 300 includes an element isolation layer 312, a conductive layer 316, an insulating layer 315, an insulating layer 317, a semiconductor region 313 that is part of the substrate 310, and a low-resistance region 314a and a low-resistance region 314b that serve as a source region and a drain region. Thus, the transistor 300 is a Si transistor. Although FIG. 23 shows a structure in which one of a source and a drain of the transistor 300 is electrically connected to a conductive layer 330, a conductive layer 356, and a conductive layer 514, which are described later, through a conductive layer 328 described later, the electrical connection structure in the display apparatus of one embodiment of the present invention is not limited thereto. The display apparatus of one embodiment of the present invention may have a structure in which, for example, a gate of the transistor 300 is electrically connected to the conductive layer 514 through the conductive layer 328.

The transistor 300 can be a fin type when, for example, the top surface of the semiconductor region 313 and the side surface thereof in the channel width direction are covered with the conductive layer 316 with the insulating layer 315 serving as a gate insulating layer therebetween. The effective channel width can be increased in the fin-type transistor 300, so that the on-state characteristics of the transistor 300 can be improved. In addition, contribution of the electric field of a gate electrode can be increased, so that the off-state characteristics of the transistor 300 can be improved. The transistor 300 may have a planar structure instead of a fin-type structure.

Note that the transistor 300 may be either a p-channel transistor or an n-channel transistor. Alternatively, a plurality of the transistors 300 may be provided and both the p-channel transistor and the n-channel transistor may be used.

A region of the semiconductor region 313 where a channel is formed, a region in the vicinity thereof, and the low-resistance region 314a and the low-resistance region 314b that serve as the source region and the drain region preferably include a silicon-based semiconductor, specifically, preferably include single crystal silicon. Alternatively, each of the regions may be formed using germanium, silicon germanium, gallium arsenide, aluminum gallium arsenide, or gallium nitride, for example. A structure using silicon whose effective mass is controlled by applying stress to the crystal lattice and changing the lattice spacing may be employed. Alternatively, the transistor 300 may be a HEMT (High Electron Mobility Transistor) using gallium arsenide and aluminum gallium arsenide, for example.

For the conductive layer 316 serving as a gate electrode, a semiconductor material such as silicon including an element that imparts n-type conductivity, such as arsenic or phosphorus, or an element that imparts p-type conductivity, such as boron or aluminum, can be used. Alternatively, for the conductive layer 316, a conductive material such as a metal material, an alloy material, or a metal oxide material can be used, for example.

Note that since the work function depends on the material of a conductor, the threshold voltage of the transistor can be adjusted by selecting the material of the conductor. Specifically, it is preferable to use one or both of titanium nitride and tantalum nitride as the material of the conductor. Moreover, in order to ensure both conductivity and embeddability, it is preferable to use stacked layers of metal materials of one or both of tungsten and aluminum for the conductor, and it is particularly preferable to use tungsten in terms of heat resistance.

The element isolation layer 312 is provided to separate a plurality of transistors formed on the substrate 310 from each other. The element isolation layer can be formed by, for example, a LOCOS (Local Oxidation of Silicon) method, an STI (Shallow Trench Isolation) method, or a mesa isolation method.

Over the transistor 300 shown in FIG. 23, an insulating layer 320 and an insulating layer 322 are sequentially stacked from the substrate 310 side.

For each of the insulating layer 320 and the insulating layer 322, one or more selected from silicon oxide, silicon oxynitride, silicon nitride oxide, silicon nitride, aluminum oxide, aluminum oxynitride, aluminum nitride oxide, and aluminum nitride are used, for example.

Note that in this specification and the like, oxynitride refers to a material that includes more oxygen than nitrogen in its composition, and nitride oxide refers to a material that includes more nitrogen than oxygen in its composition. For example, in the case where silicon oxynitride is described, it refers to a material that includes more oxygen than nitrogen in its composition. In the case where silicon nitride oxide is described, it refers to a material that includes more nitrogen than oxygen in its composition.

The insulating layer 322 may have a function of a planarization film for eliminating a level difference caused by the transistor 300 or the like covered with the insulating layer 320 and the insulating layer 322. For example, the top surface of the insulating layer 322 may be planarized by planarization treatment using a chemical mechanical polishing (CMP) method or the like to increase planarity.

The conductive layer 328 connected to the transistor MTCK and the like provided above the insulating layer 322 is embedded in the insulating layer 320 and the insulating layer 322. Note that the conductor 328 has a function of a plug or a wiring. Thus, for the conductive layer 328, a material usable for a conductive layer MPG described above can be used.

In the display apparatus 50B, the wiring layer 77 is provided over the transistor 300. The wiring layer 77 includes, for example, an insulating layer 324, an insulating layer 326, the conductive layer 330, an insulating layer 350, an insulating layer 352, an insulating layer 354, and the conductive layer 356.

Over the insulating layer 322 and the conductive layer 328, the insulating layer 324 and the insulating layer 326 are sequentially stacked. An opening is formed in the insulator 324 and the insulator 326 in a region overlapping with the conductor 328. In addition, the conductor 330 is embedded in the opening.

The insulating layer 350, the insulating layer 352, and the insulating layer 354 are sequentially stacked over the insulating layer 326 and the conductive layer 330. An opening is formed in the insulating layer 350, the insulating layer 352, and the insulating layer 354 in a region overlapping with the conductive layer 330. The conductive layer 356 is embedded in the opening.

The conductive layer 330 and the conductive layer 356 have a function of a plug or a wiring that is connected to the transistor 300. Note that the conductive layer 330 and the conductive layer 356 can be provided using a material similar to that for the conductive layer 328 or a conductive layer 596.

Note that like an insulating layer 592, for example, each of the insulating layer 324 and the insulating layer 350 is preferably formed using an insulator having a barrier property against one or more selected from hydrogen, oxygen, and water. Like an insulating layer 594, each of the insulating layer 326, the insulating layer 352, and the insulating layer 354 is preferably formed using an insulator having a comparatively low relative permittivity to reduce parasitic capacitance generated between wirings. Each of the insulating layer 326, the insulating layer 352, and the insulating layer 354 has functions of an interlayer insulating film and a planarization film. Furthermore, each of the insulating layer 326, the insulating layer 352, and the insulating layer 354 preferably includes an insulator having a barrier property against one or more selected from hydrogen, oxygen, and water.

Note that for the conductor having a barrier property against hydrogen, tantalum nitride is preferably used, for example. The use of a stack including tantalum nitride and tungsten that has high conductivity can inhibit diffusion of hydrogen from the transistor 300 while the conductivity of a wiring is kept. In that case, a tantalum nitride layer having a barrier property against hydrogen is preferably in contact with the insulating layer 350 having a barrier property against hydrogen.

An insulating layer 512 is provided above the insulating layer 354 and the conductor 356. An insulating layer IS1 is provided over the insulating layer 512. The conductor 514 serving as a plug or a wiring is embedded in the insulating layer IS1 and the insulating layer 512. Accordingly, one of the source and the drain of the transistor MTCK is electrically connected to the one of the source and the drain of the transistor 300. Note that for the conductor 514, a material usable for the conductive layer MPG can be used, for example.

The transistor MTCK is provided over the insulating layer IS1 and the conductive layer 514. An insulating layer 574 is formed over the transistor MTCK, and an insulating layer 581 is formed over the insulating layer 574. The conductive layer MPG serving as a plug or a wiring is embedded in an insulating layer IS3, the insulating layer 574, and the insulating layer 581. Note that Embodiment 2 is referred to for the insulating layer, the conductive layer, and the semiconductor layer around the transistor MTCK.

The insulating layer IS3 is formed above the transistor MTCK. The insulating layer 574 and the insulating layer 581 are stacked in this order over the insulating layer IS3.

The insulating layer 574 preferably has a function of inhibiting diffusion of impurities such as water and hydrogen (e.g., one or both of a hydrogen atom and a hydrogen molecule). In other words, the insulating layer 574 preferably serves as a barrier insulating film that inhibits the entry of the impurities into the transistor MTCK. Moreover, the insulating layer 574 preferably has a function of inhibiting diffusion of oxygen (e.g., one or both of an oxygen atom and an oxygen molecule). For example, the insulating layer 574 preferably has a lower oxygen permeability than an insulating layer IS2 and the insulating layer IS3.

Thus, the insulating layer 574 preferably serves as a barrier insulating film that inhibits diffusion of impurities such as water and hydrogen. Accordingly, it is preferable to use, for the insulating layer 574, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the impurities are less likely to pass). Alternatively, it is preferable to use an insulating material having a function of inhibiting diffusion of oxygen (e.g., one or both of an oxygen atom and an oxygen molecule) (an insulating material through which the oxygen is less likely to pass).

An insulator having a function of inhibiting the passage of oxygen and impurities such as water and hydrogen can be formed to have a single layer or a stacked layer including an insulator including one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting the passage of oxygen and impurities such as water and hydrogen include oxides including aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for the insulating layer 574. Accordingly, it is possible to inhibit diffusion of impurities such as water and hydrogen into the transistor MTCK from above the insulating layer 574. In addition, it is possible to inhibit diffusion of oxygen included in the insulating layer IS3 or the like to above the insulating layer 574.

The insulating layer 581 is preferably a film serving as an interlayer film and having a lower permittivity than the insulating layer 574. When a material with a low permittivity is used for an interlayer film, parasitic capacitance generated between wirings can be reduced. The relative permittivity of the insulating layer 581 is preferably lower than 4, further preferably lower than 3, for example. The relative permittivity of the insulating layer 581 is, for example, preferably 0.7 times or less, further preferably 0.6 times or less the relative permittivity of the insulating layer 574. When a material with a low permittivity is used for the insulating layer 581 serving as an interlayer film, parasitic capacitance generated between wirings can be reduced.

The concentration of impurities such as water and hydrogen in the insulating layer 581 is preferably reduced. In this case, for the insulating layer 581, silicon oxide, silicon oxynitride, silicon nitride oxide, or silicon nitride can be used, for example. Alternatively, for the insulating layer 581, silicon oxide to which fluorine is added, silicon oxide to which carbon is added, silicon oxide to which carbon and nitrogen are added, or porous silicon oxide can be used, for example. In particular, silicon oxide and silicon oxynitride, which are thermally stable, are preferable. Materials such as silicon oxide, silicon oxynitride, and porous silicon oxide are particularly preferable because a region including oxygen to be released by heating can be easily formed. Alternatively, for the insulating layer 581, a resin can be used. A material that can be used for the insulating layer 581 may be an appropriate combination of the above-described materials.

The insulating layer 592 and the insulating layer 594 are stacked in this order over the insulating layer 574 and the insulating layer 581.

For the insulating layer 592, it is preferable to use an insulating film having a barrier property (referred to as a barrier insulating film) which prevents diffusion of impurities such as water and hydrogen from the substrate 310 or the transistor MTCK to a region above the insulating layer 592 (e.g., the region where the light-emitting device 130R, the light-emitting device 130G, the light-emitting device 130B, and the like are provided). Accordingly, for the insulating layer 592, it is preferable to use an insulating material that has a function of inhibiting diffusion of impurities such as a hydrogen atom, a hydrogen molecule, and a water molecule (an insulating material through which the above impurities are less likely to pass). Furthermore, depending on the situation, it is preferable to use, for the insulating layer 592, an insulating material having a function of inhibiting diffusion of impurities such as a nitrogen atom, a nitrogen molecule, a nitrogen oxide molecule (e.g., N₂O, NO, or NO₂), and a copper atom (an insulating material through which the oxygen is less likely to pass). It is preferable that the insulating layer 592 have a function of inhibiting diffusion of oxygen (e.g., one or both of an oxygen atom and an oxygen molecule).

For the film having a barrier property against hydrogen, for example, silicon nitride formed by a CVD method can be used.

The amount of released hydrogen can be analyzed by thermal desorption spectrometry (TDS), for example. The amount of hydrogen released from the insulating layer 324 that is converted into hydrogen atoms per area of the insulating layer 324 is less than or equal to 10×10¹⁵ atoms/cm², preferably less than or equal to 5×10¹⁵ atoms/cm² in the TDS in a film-surface temperature range of 50° C. to 500° C., for example.

Like the insulating layer 581, the insulating layer 594 is preferably an interlayer film with a low permittivity. Thus, for the insulating layer 594, a material usable for the insulating layer 581 can be used.

Note that the insulating layer 594 preferably has a lower permittivity than the insulating layer 592. The relative permittivity of the insulating layer 594 is preferably lower than 4, further preferably lower than 3, for example. The relative permittivity of the insulating layer 594 is, for example, preferably 0.7 times or less, further preferably 0.6 times or less the relative permittivity of the insulating layer 592. When a material with a low permittivity is used for the insulating layer 594 serving as an interlayer film, parasitic capacitance generated between wirings can be reduced.

The conductive layer MPG serving as a plug or a wiring is embedded in an insulating layer GI1 and the insulating layer IS3, and the conductor 596 serving as a plug or a wiring is embedded in the insulating layer 592 and the insulating layer 594. In particular, the conductive layer MPG and the conductive layer 596 are electrically connected to the light-emitting device or the like provided above the insulating layer 594. A plurality of conductive layers each having a function of a plug or a wiring are collectively denoted by the same reference numeral in some cases. Moreover, in this specification and the like, a wiring and a plug connected to the wiring may be a single component. That is, part of a conductive layer serves as a wiring in some cases and part of the conductive layer serves as a plug in other cases.

As a material of each of plugs and wirings (e.g., the conductive layer MPG and the conductive layer 596), a single layer or a stacked layer of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used for formation. The use of a low-resistance conductive material can reduce wiring resistance.

An insulating layer 598 and an insulating layer 599 are sequentially formed over the insulating layer 594 and the conductive layer 596.

Like the insulating layer 592, for example, the insulating layer 598 is preferably formed using an insulator having a barrier property against one or more selected from hydrogen, oxygen, and water. Like the insulating layer 594, the insulating layer 599 is preferably formed using an insulator having a comparatively low relative permittivity to reduce parasitic capacitance generated between wirings. The insulating layer 599 has functions of an interlayer insulating film and a planarization film.

The light-emitting device 130 and the connection portion 140 are formed over the insulating layer 599.

The connection portion 140 is referred to as a cathode contact portion in some cases, and is electrically connected to cathode electrodes of the light-emitting device 130R, the light-emitting device 130G, and the light-emitting device 130B. The connection portion 140 in FIG. 23 includes one or more conductive layers selected from a conductive layer 182a to a conductive layer 182c described later, at least one of a conductive layer 126a to a conductive layer 126c described later, one or more conductive layers selected from a conductive layer 129a to a conductive layer 129c described later, a common layer 114 described later, and a common electrode 115 described later.

Note that the connection portion 140 may be provided to surround four sides of the display portion in the plan view, or may be provided in the display portion (e.g., between adjacent light-emitting devices 130) (not shown).

The light-emitting device 130R includes the conductive layer 182a, the conductive layer 126a over the conductive layer 182a, and the conductive layer 129a over the conductive layer 126a. All of the conductive layer 182a, the conductive layer 126a, and the conductive layer 129a can be referred to as pixel electrodes, or one or two of them can be referred to as pixel electrodes. The light-emitting device 130G includes a conductive layer 182b, a conductive layer 126b over the conductive layer 182b, and a conductive layer 129b over the conductive layer 126b. As in the light-emitting device 130R, all of the conductive layer 182b, the conductive layer 126b, and the conductive layer 129b can be referred to as a pixel electrode, or one or two of them can be referred to as a pixel electrode. The light-emitting device 130B includes the conductive layer 182c, the conductive layer 126c over the conductive layer 182c, and the conductive layer 129c over the conductive layer 126c. As in the light-emitting device 130R and the light-emitting device 130G, all of the conductive layer 182c, the conductive layer 126c, and the conductive layer 129c can be referred to as a pixel electrode, or one or two of them can be referred to as a pixel electrode.

For each of the conductive layer 182a to the conductive layer 182c and the conductive layer 126a to the conductive layer 126c, a conductive layer serving as a reflective electrode can be used, for example. For the conductive layer serving as a reflective electrode, a conductor with high visible-light reflectance such as silver, aluminum, or an alloy film of silver (Ag), palladium (Pd), and copper (Cu) (an Ag—Pd—Cu (APC) film) can be used. For each of the conductive layer 182a to the conductive layer 182c and the conductive layer 126a to the conductive layer 126c, a stacked-layer film in which a pair of titanium films sandwich aluminum (a film in which Ti, Al, and Ti are stacked in this order), or a stacked-layer film in which a pair of indium tin oxide films sandwich silver (a film in which ITO, Ag, and ITO are stacked in this order) can be used.

For example, a conductive layer serving as a reflective electrode may be used for each of the conductive layer 182a to the conductive layer 182c, and a material with a high light-transmitting property may be used for each of the conductive layer 126a to the conductive layer 126c. Examples of the material with a high light-transmitting property include an alloy of silver and magnesium and indium tin oxide (sometimes referred to as ITO).

A conductive layer serving as a transparent electrode can be used for each of the conductive layer 129a to the conductive layer 129c. For the conductive layer serving as a transparent electrode, for example, the above-described conductive layer with a high light-transmitting property can be used.

A microcavity structure may be provided in the light-emitting device 130 to be described in detail later. The microcavity structure refers to a structure in which the distance between the bottom surface of the light-emitting layer and the top surface of a lower electrode is set to a thickness depending on a wavelength of color of light emitted from the light-emitting layer. In that case, a light-transmitting and light-reflective conductive material is preferably used for each of the conductive layer 129a to the conductive layer 129c which serve as an upper electrode (a common electrode), and a light-reflective conductive material is preferably used for each of the conductive layer 182a to the conductive layer 182c and the conductive layer 126a to the conductive layer 126c which serve as lower electrodes (pixel electrodes).

The microcavity structure refers to a structure in which the optical distance between the lower electrode and the light-emitting layer is adjusted to be (2n−1)λ/4 (n is an integer greater than or equal to 1, and λ is a wavelength of emitted light desired to be amplified). Thus, light that is reflected back by the lower electrode (reflected light) considerably interferes with light that directly enters the upper electrode from the light-emitting layer (incident light). Accordingly, the phases of the reflected light and the incident light each having the wavelength λ can be aligned with each other, and the light emitted from the light-emitting layer can be further amplified. Meanwhile, in the case where the reflected light and the incident light each have a wavelength other than the wavelength λ, their phases are not aligned with each other, resulting in attenuation without resonation.

The conductive layer 182a is connected to the conductive layer 596 embedded in the insulating layer 594 through an opening provided in the insulating layer 599. An end portion of the conductive layer 126a is positioned outward from an end portion of the conductive layer 182a. The end portion of the conductive layer 126a and an end portion of the conductive layer 129a are aligned or substantially aligned with each other.

Detailed description of the conductive layer 182b, the conductive layer 126b, and the conductive layer 129b of the light-emitting device 130G and the conductive layer 182c, the conductive layer 126c, and the conductive layer 129c of the light-emitting device 130B is omitted because these conductive layers are similar to the conductive layer 182a, the conductive layer 126a, and the conductive layer 129a of the light-emitting device 130R.

Depressed portions are formed in the conductive layer 182a, the conductive layer 182b, and the conductive layer 182c to cover the openings provided in the insulating layer 599. A layer 128 is embedded in the depression portions.

The layer 128 has a function of filling the depression portions of the conductor 182a to the conductor 182c. The conductive layer 126a to the conductive layer 126c electrically connected to the conductive layer 182a to the conductive layer 182c, respectively, are provided over the conductive layer 182a to the conductive layer 182c and the layer 128. Thus, regions overlapping with the depression portions of the conductive layer 182a to the conductive layer 182c can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer including an organic material can be suitably used for the layer 128. For the layer 128, an acrylic resin, a polyimide resin, an epoxy resin, a polyamide resin, a polyimide-amide resin, a siloxane resin, a benzocyclobutene-based resin, a phenol resin, or a precursor of any of these resins can be used, for example. A photosensitive resin can also be used for the layer 128. As the photosensitive resin, a positive material or a negative material is given.

When a photosensitive resin is used, the layer 128 can be formed through only light-exposure and development steps, reducing the influence of dry etching method or a wet etching method on the surfaces of the conductive layer 182a, the conductive layer 182b, and the conductive layer 182c. When the layer 128 is formed using a negative photosensitive resin, the layer 128 can sometimes be formed using the same photomask (light-exposure mask) as the photomask used for forming the opening in the insulating layer 599.

The light-emitting device 130R includes a first layer 113a, the common layer 114 over the first layer 113a, and the common electrode 115 over the common layer 114. The light-emitting device 130G includes a second layer 113b, the common layer 114 over the second layer 113b, and the common electrode 115 over the common layer 114. The light-emitting device 130B includes a third layer 113c, the common layer 114 over the third layer 113c, and the common electrode 115 over the common layer 114.

The first layer 113a is formed to cover the top surface and side surface of the conductive layer 126a and the top surface and side surface of the conductive layer 129a. Similarly, the second layer 113b is formed to cover the top surface and side surface of the conductive layer 126b and the top surface and side surface of the conductive layer 129b. Similarly, the third layer 113c is formed to cover the top surface and side surface of the conductive layer 126c and the top surface and side surface of the conductive layer 129c. Accordingly, regions provided with the conductive layer 126a, the conductive layer 126b, and the conductive layer 126c can be entirely used as the light-emitting regions of the light-emitting device 130R, the light-emitting device 130G, and the light-emitting device 130B, increasing the aperture ratio of the pixels.

In the light-emitting device 130R, the first layer 113a and the common layer 114 can be collectively referred to as an EL layer. Similarly, in the light-emitting device 130G, the second layer 113b and the common layer 114 can be collectively referred to as an EL layer. Similarly, in the light-emitting device 130B, the third layer 113c and the common layer 114 can be collectively referred to as an EL layer.

There is no particular limitation on the structure of the light-emitting device in this embodiment, and the light-emitting device can have a single structure or a tandem structure.

The first layer 113a, the second layer 113b, and the third layer 113c each have an island shape after being processed by a photolithography method. At each of end portions of the first layer 113a, the second layer 113b, and the third layer 113c, an angle formed between the top surface and side surface is approximately 90°. By contrast, for example, an organic film formed using an FMM (Fine Metal Mask) tends to have a thickness that gradually decreases with decreasing distance to an end portion, and has the top surface forming a slope in an area extending greater than or equal to 1 μm and less than or equal to 10 μm from the end portion, for example; thus, such an organic film has a shape whose top surface and side surface cannot be easily distinguished from each other.

The top surface and side surface of each of the first layer 113a, the second layer 113b, and the third layer 113c are clearly distinguished from each other. Accordingly, as for the first layer 113a and the second layer 113b which are adjacent to each other, one of the side surfaces of the first layer 113a and one of the side surfaces of the second layer 113b face to each other. This applies to a combination of any of the first layer 113a, the second layer 113b, and the third layer 113c.

The first layer 113a, the second layer 113b, and the third layer 113c each include at least a light-emitting layer. For example, a structure is preferable in which the first layer 113a includes a light-emitting layer that emits red light, the second layer 113b includes a light-emitting layer that emits green light, and the third layer 113c includes a light-emitting layer that emits blue light. Other than the above colors, cyan, magenta, yellow, or white can be employed for the light-emitting layers.

The first layer 113a, the second layer 113b, and the third layer 113c each preferably include a light-emitting layer and a carrier-transport layer (an electron-transport layer or a hole-transport layer) over the light-emitting layer. Since the surfaces of the first layer 113a, the second layer 113b, and the third layer 113c may be exposed in the manufacturing process of the display apparatus, providing the carrier-transport layer over the light-emitting layers inhibits the light-emitting layers from being exposed on the outermost surface, so that damage to the light-emitting layers can be reduced. Accordingly, the reliability of the light-emitting devices can be improved.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting device 130R, the light-emitting device 130G, and the light-emitting device 130B.

The common electrode 115 is shared between the light-emitting device 130R, the light-emitting device 130G, and the light-emitting device 130B. As shown in FIG. 23, the common electrode 115 shared by the plurality of light-emitting devices is electrically connected to conductive layers included in the connection portion 140.

An insulating layer 125 preferably has a function of a barrier insulating layer against one or both of water and oxygen. Alternatively, the insulating layer 125 preferably has a function of inhibiting diffusion of one or both of water and oxygen. Alternatively, the insulating layer 125 preferably has a function of capturing or fixing (also referred to as gettering) one or both of water and oxygen. When the insulating layer 125 has a function of a barrier insulating layer or a gettering function, entry of impurities (typically, one or both of water and oxygen) that would be diffused into the light-emitting devices from the outside can be inhibited. With this structure, a highly reliable light-emitting device and a highly reliable display panel can be provided.

The insulating layer 125 preferably has a low impurity concentration. In that case, degradation of the EL layer due to entry of impurities into the EL layer from the insulating layer 125 can be inhibited. In addition, when the impurity concentration is reduced in the insulating layer 125, a barrier property against one or both of water and oxygen can be increased. For example, the insulating layer 125 preferably has one of a sufficiently low hydrogen concentration and a sufficiently low carbon concentration, desirably has both of them.

As an insulating layer 127, an insulating layer including an organic material can be suitably used. As the organic material, a photosensitive organic resin is preferably used; for example, a photosensitive resin composition including an acrylic resin may be used. The viscosity of the material for the insulating layer 127 is greater than or equal to 1 cP and less than or equal to 1500 cP, and is preferably greater than or equal to 1 cP and less than or equal to 12 cP. By setting the viscosity of the material for the insulating layer 127 in the above range, the insulating layer 127 having a tapered shape, which is to be described later, can be formed relatively easily. Note that in this specification and the like, an acrylic resin refers to not only a polymethacrylic acid ester or a methacrylic resin, but also all the acrylic-based polymers in a broad sense in some cases.

Note that in this specification and the like, a tapered shape indicates a shape in which at least part of a side surface of a structure is inclined to a substrate surface. For example, the tapered shape preferably includes a region where the angle formed between the inclined side surface and the substrate surface (the angle is also referred to as a taper angle) is less than 90°.

Note that the organic material that can be used for the insulating layer 127 is not limited to the above as long as the insulating layer 127 has a tapered side surface as described later. For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, or a precursor of any of these resins can be used in some cases, for example. Alternatively, an organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be employed for the insulating layer 127 in some cases. For the insulating layer 127, for example, a photoresist can be used as the photosensitive resin in some cases. Note that as the photosensitive resin, a positive material or a negative material can be used.

For the insulating layer 127, a material absorbing visible light may be used. When the insulating layer 127 absorbs light from the light-emitting device, leakage of light (stray light) from the light-emitting device to the adjacent light-emitting device through the insulating layer 127 can be inhibited. Thus, the display quality of the display panel can be improved. Since the display quality of the display panel can be improved without using a polarizing plate, the weight and thickness of the display panel can be reduced.

Examples of the material absorbing visible light include materials including pigment of black or the like, materials including dye, light-absorbing resin materials (e.g., polyimide), and resin materials that can be used for color filters (color filter materials). A resin material obtained by stacking or mixing color filter materials of two colors or three or more colors is particularly preferably used to enhance the effect of blocking visible light. Specifically, mixing color filter materials of three or more colors enables formation of a black or nearly black resin layer.

For example, the insulating layer 127 can be formed by a wet film formation method such as spin coating, dipping, spray coating, ink-jetting, dispensing, screen printing, offset printing, doctor blade coating, slit coating, roll coating, curtain coating, or knife coating. Specifically, an organic insulating film that is to be the insulating layer 127 is preferably formed by spin coating.

The insulating layer 127 is formed at a temperature lower than the upper temperature limit of the EL layer. The typical substrate temperature in formation of the insulating layer 127 is lower than or equal to 200° C., preferably lower than or equal to 180° C., further preferably lower than or equal to 160° C., still further preferably lower than or equal to 150° C., yet still further preferably lower than or equal to 140° C.

The description is made below on the structure of the insulating layer 127 or the like using the structure of the insulating layer 127 between the light-emitting device 130R and the light-emitting device 130G as an example. Note that the same applies to the insulating layer 127 between the light-emitting device 130G and the light-emitting device 130B, the insulating layer 127 between the light-emitting device 130B and the light-emitting device 130R, and the like. In the description below, an end portion of the insulating layer 127 over the second layer 113b is used as an example in some cases, and the same can apply to an end portion of the insulating layer 127 over the first layer 113a, an end portion of the insulating layer 127 over the third layer 113c, and the like.

The insulating layer 127 preferably has the tapered side surface with a taper angle θ1 in the cross-sectional view of the display apparatus. The taper angle θ1 is an angle formed by the side surface of the insulating layer 127 and the substrate surface. Note that the taper angle θ1 is not limited to the angle with the substrate surface, and may be an angle formed between the side surface of the insulating layer 127 and the top surface of the flat portion of the insulating layer 125 or the top surface of the flat portion of the second layer 113b. When the side surface of the insulating layer 127 has a tapered shape, the side surface of the insulating layer 125 and the side surface of a mask layer 118a also have a tapered shape in some cases.

The taper angle θ1 of the insulating layer 127 is less than 90°, preferably less than or equal to 60°, and further preferably less than or equal to 45°. Such a forward tapered shape of an end portion of the side surface of the insulating layer 127 can prevent disconnection, local thinning, or the like from occurring in the common layer 114 and the common electrode 115 which are provided over the end portion of the side surface of the insulating layer 127, leading to film formation with good coverage. Accordingly, the in-plane uniformity of the common layer 114 and the common electrode 115 can be improved, leading to higher display quality of the display apparatus.

The top surface of the insulating layer 127 preferably has a convex shape in a cross-sectional view of the display apparatus. The convex shape of the top surface of the insulating layer 127 is preferably a shape gently bulged toward the center. The convex portion at the center of the top surface of the insulating layer 127 preferably has a shape connected continuously to the tapered portion of the end portion of the side surface. When the insulating layer 127 has such a shape, the common layer 114 and the common electrode 115 can be formed with good coverage over the entire insulating layer 127.

The insulating layer 127 is formed in a region between two EL layers (e.g., a region between the first layer 113a and the second layer 113b). At this time, part of the insulating layer 127 is placed at a position sandwiched between an end portion of the side surface of one of the EL layers (e.g., the first layer 113a) and an end portion of the side surface of the other of the EL layers (e.g., the second layer 113b).

One end portion of the insulating layer 127 preferably overlaps with the conductive layer 126a serving as a pixel electrode, and the other end portion of the insulating layer 127 preferably overlaps with the conductive layer 126b serving as a pixel electrode. With such a structure, the end portion of the insulating layer 127 can be formed over a substantially flat region of the first layer 113a (the second layer 113b). This makes it relatively easy to process the tapered shape of the insulating layer 127 as described above.

By providing the insulating layer 127 and the like as described above, a disconnected portion and a locally thinned portion can be prevented from being formed in the common layer 114 and the common electrode 115 from a substantially flat region in the first layer 113a to a substantially flat region in the second layer 113b. Thus, between the light-emitting devices, a connection defect caused by the disconnected portion and an increase in electrical resistance caused by the locally thinned portion can be inhibited from occurring in the common layer 114 and the common electrode 115.

In the display apparatus of this embodiment, the distance between the light-emitting devices can be short. Specifically, the distance between the light-emitting devices, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where a distance between two adjacent island-shaped EL layers is less than or equal to 1 μm, preferably less than or equal to 0.5 μm (500 nm), further preferably less than or equal to 100 nm. When the distance between the light-emitting devices is shortened in this manner, a display apparatus with high definition and a high aperture ratio can be provided.

A protective layer 131 is provided over the light-emitting device 130. The protective layer 131 is a film serving as a passivation film for protecting the light-emitting devices 130. Provision of the protective layer 131 covering the light-emitting device can inhibit an impurity such as water and oxygen from entering the light-emitting device, and increase the reliability of the light-emitting device 130. For the protective layer 131, aluminum oxide, silicon nitride, or silicon nitride oxide can be used, for example.

The protective layer 131 and a substrate 119 are bonded to each other with an adhesive layer 107. A solid sealing structure, a hollow sealing structure, or the like can be employed to seal the light-emitting devices. In FIG. 23, a solid sealing structure is employed in which a space between the substrate 310 and the substrate 110 is filled with the adhesive layer 107. Alternatively, a hollow sealing structure may be employed, in which the space is filled with an inert gas (e.g., nitrogen or argon). Here, the adhesive layer 107 may be provided not to overlap with the light-emitting devices. The space may be filled with a resin other than the frame-shaped adhesive layer 107.

For the adhesive layer 107, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. An adhesive sheet may be used.

The display apparatus 50B has a top-emission structure. Light from the light-emitting device is emitted toward the substrate 119 side. Thus, for the substrate 119, a material having a high visible-light-transmitting property is preferably used. For example, a substrate having a high visible-light-transmitting property may be selected as the substrate 119 from substrates usable as the substrate 310. The pixel electrode includes a material that reflects visible light, and a counter electrode (the common electrode 115) includes a material that transmits visible light.

Note that the display apparatus of one embodiment of the present invention may be not a top-emission display apparatus but a bottom-emission display apparatus where light from the light-emitting device is emitted to the substrate 310 side. In that case, a substrate having a high visible-light-transmitting property is selected as the substrate 310.

When one of the above structure examples is applied to a display apparatus, the display apparatus having high resolution and high definition can be achieved in some cases. Specifically, for example, a display apparatus with a resolution of HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320) can be achieved in some cases. Furthermore, specifically, for example, a display apparatus with a definition of higher than or equal to 100 ppi, higher than or equal to 300 ppi, higher than or equal to 500 ppi, higher than or equal to 1000 ppi, higher than or equal to 2000 ppi, higher than or equal to 3000 ppi, higher than or equal to 5000 ppi, or higher than or equal to 6000 ppi can be achieved in some cases.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

At least part of the structure examples, the drawings corresponding thereto, and the like described in this embodiment can be combined with the other structure examples, the other drawings corresponding thereto, and the like as appropriate.

At least part of the structure examples, the drawings corresponding thereto, and the like described in this embodiment can be combined with the other structure examples, the other drawings corresponding thereto, and the like as appropriate.

### Embodiment 4

In this embodiment, description is made on a memory cell, a memory device, and the like in each of which the stack of one embodiment of the present invention is used.

Structures of a memory cell including a transistor and a capacitor, a structure of a memory device including the memory cell, and the like will be described below.

### <Structure Example 1 of Memory Cell>

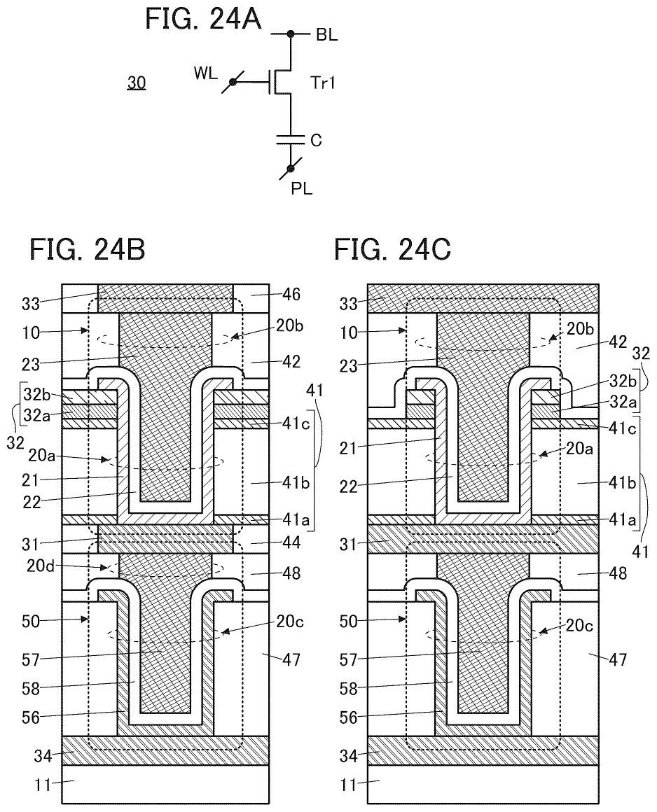

FIG. 24A is a circuit diagram of a memory cell 30. The memory cell 30 includes one transistor Tr1 and one capacitor C and is also referred to as 1Tr1C. A gate of the transistor Tr1 is connected to a wiring WL, one of a source and a drain of the transistor Tr1 is connected to a wiring BL, and the other thereof is connected to one electrode of the capacitor C. The other electrode of the capacitor C is connected to a wiring PL.

In the memory cell 30, a data potential input from the wiring BL through the transistor Tr1 is retained in the capacitor C, whereby data can be stored. When the transistor Tr1 is brought into a non-conduction state, the data can be retained. When the transistor Tr1 is brought into a conduction state, a potential corresponding to the retained data is output to the wiring BL, which allows data reading. A signal for controlling the conduction or non-conduction of the transistor Tr1 is supplied to the wiring WL. A predetermined potential (e.g., a fixed potential) is supplied to the wiring PL.

FIG. 24B and FIG. 24C are cross-sectional views of the memory cell 30. FIG. 24A is a cross-sectional view along the extending direction of a conductive layer 32, and FIG. 24B is a cross-sectional view along the extending directions of a conductive layer 31 and a conductive layer 33. The memory cell 30 has a structure in which a transistor 10 is stacked over a capacitor 50. The transistor 10 and the capacitor 50 correspond to the transistor Tr1 and the capacitor C, respectively.

The transistor 10 includes a conductive layer 31 serving as one of a source electrode and a drain electrode, the semiconductor layer 21, an insulating layer 22 serving as a gate insulating layer, a conductive layer 23 serving as a gate electrode, and the conductive layer 32 serving as the other of the source electrode and the drain electrode. The conductive layer 31 and the conductive layer 32 serve also as wirings. The conductive layer 32 has a stacked-layer structure of a conductive layer 32a and a conductive layer 32b over the conductive layer 32a.

The conductive layer 31 is provided over an insulating layer 11, and an insulating layer 41 is provided over the conductive layer 31. The conductive layer 32 is provided over the insulating layer 41. The insulating layer 41 includes an opening 20a reaching the conductive layer 31. The semiconductor layer 21 is provided in contact with the side surface (also referred to as an inner wall or a sidewall) of the opening 20a in the insulating layer 41, and is in contact with the top surface of the conductive layer 31 and the top surface and the side surface of the conductive layer 32. The insulating layer 22 is provided to cover the conductive layer 32 and the semiconductor layer 21. A portion of the insulating layer 22 that is positioned in the opening 20a is provided along the top surface of the semiconductor layer 21.

An insulating layer 42 is provided over the insulating layer 22. The insulating layer 42 includes an opening 20b that overlaps with the opening 20a and reaches the insulating layer 22. The conductive layer 23 is provided in contact with the surface of the insulating layer 22 to be embedded in the opening 20a and the opening 20b.

The top surfaces of the insulating layer 42 and the insulating layer 23 are planarized and substantially level with each other. A conductive layer 33 serving as a wiring is provided over the insulating layer 42. The conductive layer 33 is provided in contact with the top surface of the conductive layer 23. The conductive layer 33 serves as, for example, a gate wiring.

Here, the conductive layer 31 is embedded in an insulating layer 44. The conductive layer 33 is embedded in an insulating layer 46. Furthermore, the top surfaces thereof are planarized, whereby the top surfaces of the conductive and insulating layers are substantially level with each other. Such a structure is preferable because the effect of a step can be eliminated. The insulating layer 44 and the insulating layer 46 serve as interlayer insulating layers. For example, an inorganic insulating material with a low permittivity, such as silicon oxide or silicon oxynitride, is preferably used.

As shown in FIG. 24B, FIG. 24C, and the like, the insulating layer 41 may have a stacked-layer structure of an insulating layer 41a, an insulating layer 41b over the insulating layer 41a, and an insulating layer 41c over the insulating layer 41b.

The components and the manufacturing method of the stack described in the above embodiment, the components and the manufacturing method of the transistor 100 described above, and the like can be referred to for the components, the manufacturing method, and the like of the transistor 10.

For example, the conductive layer 112a, the conductive layer 112b, the conductive layer 51a, and the metal layer 51b described in the above embodiment can be respectively referred to for the conductive layer 31, the conductive layer 32, the conductive layer 32a, and the conductive layer 32b. The semiconductor layer 401, the semiconductor layer 108, and the like described in the above embodiment can be referred to for the semiconductor layer 21. The insulating layer 106 described in the above embodiment can be referred to for the insulating layer 22. The conductive layer 104 and the like described in the above embodiment can be referred to for the conductive layer 23. The insulating layer 110, the insulating layer 110a, the insulating layer 110b, and the insulating layer 110c can be respectively referred to for the insulating layer 41, the insulating layer 41a, the insulating layer 41b, and the insulating layer 41c.

Note that the example of using the transistor 10 shown here is a non-limiting example, and the transistor 10 can be replaced with any of the variety of transistors described in this specification.

The capacitor 50 includes a conductive layer 56, a conductive layer 57, and an insulating layer 58 sandwiched therebetween. The capacitor 50 forms what is called a MIM (Metal-Insulator-Metal) capacitor.

The capacitor 50 is provided over the insulating layer 11. A conductive layer 34 is provided over the insulating layer 11, and an insulating layer 47 is provided over the conductive layer 34. In the insulating layer 47, an opening 20c reaching the conductive layer 34 is provided. In the opening 20c, the conductive layer 56 is provided in contact with the side surface of the insulating layer 47 and the top surface of the conductive layer 34. The insulating layer 58 is provided to cover the insulating layer 47 and the conductive layer 56. An insulating layer 48 is provided over the insulating layer 58, and an opening 20d overlapping with the opening 20c is provided in the insulating layer 48. The conductive layer 57 is provided to be embedded in the opening 20d and the opening 20c.

The top surfaces of the conductive layer 57 and the insulating layer 48 are planarized and substantially level with each other. The insulating layer 44 and the conductive layer 31 are provided over the conductive layer 57 and the insulating layer 48. The conductive layer 31 is provided in contact with the top surface of the conductive layer 57.

In FIG. 24B and FIG. 24C, the conductive layer 32 corresponds to the wiring BL, the conductive layer 33 corresponds to the wiring WL, and the conductive layer 34 corresponds to the wiring PL.

For the conductive layer 34, the conductive layer 56, and the conductive layer 57, a low-resistance conductive material can be used. For example, any of the materials usable for the conductive layer 23 can be used.

The insulating layer 58 serves as a dielectric layer of the capacitor 50; thus, the capacitance of the capacitor 50 can be increased as the insulating layer 58 has a smaller thickness and a higher relative permittivity. For example, a high-k material usable for the insulating layer 22 is preferably used.

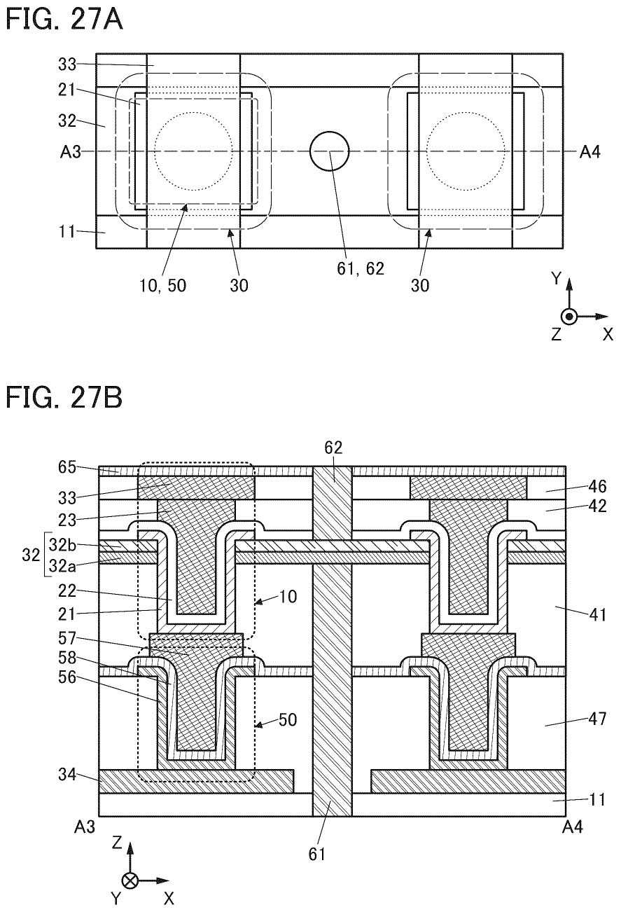

FIG. 27A and FIG. 27B show an example of a memory device in which two memory cells 30 are connected to a common wiring. FIG. 27A is a schematic top view of the memory device, and FIG. 27B is a schematic cross-sectional view along the cutting line A3-A4 in FIG. 27A.

The conductive layer 33 serving as the wiring WL is provided in each of the two memory cells 30. The conductive layer 32 serving as the wiring BL is provided to be shared by the two memory cells 30.

The conductive layer 32 serving as the wiring BL is embedded in an interlayer insulating layer and electrically connected to a conductive layer 61 and a conductive layer 62 serving as plugs (also referred to as connection electrodes). A structure may be employed in which the conductive layer 61 is electrically connected to a sense amplifier (not shown) provided below the insulating layer 11. The conductive layer 61 may be configured to be electrically connected to the conductive layer 32 of a memory cell stacked above an insulating layer 65.

The insulating layer 65 serves as a barrier layer and has a function of preventing diffusion of impurities such as water and hydrogen from the outside into the memory device.

### <Structure Example of Memory Cell Array>

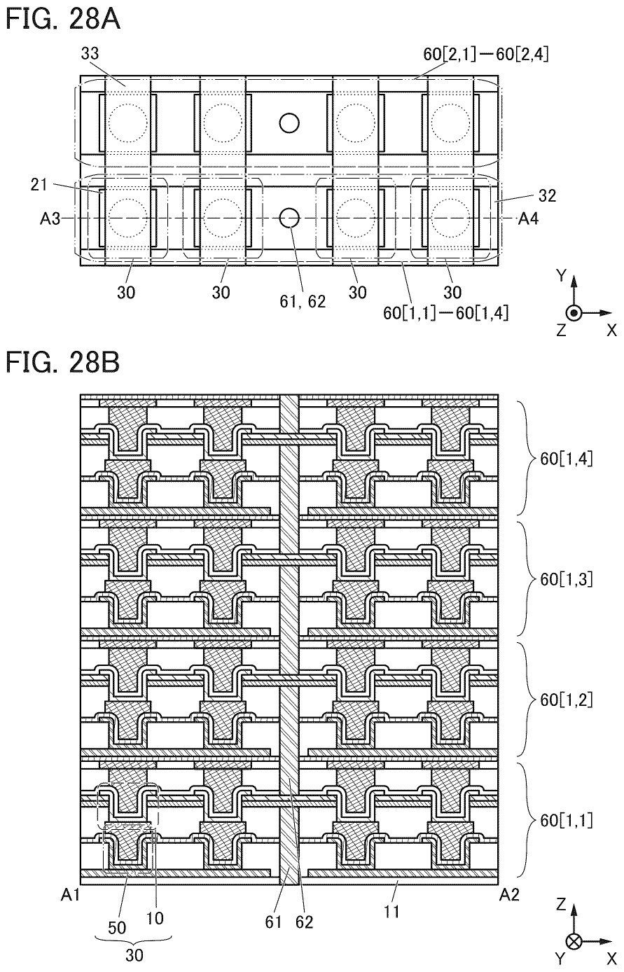

The memory cells 30 can be three-dimensionally arranged in a matrix to form a memory cell array. As an example of the memory cell array, FIG. 28A and FIG. 28B show an example of a memory device in which 4×2×4 memory cells 30 are arranged in the X direction, the Y direction, and the Z direction. FIG. 28A is a plan view of the memory device, and FIG. 28B is a cross-sectional view taken along the cutting line A3-A4 in FIG. 28A.

A group consisting of four memory cells 30 can be referred to as a memory unit 60. FIG. 28A and FIG. 28B show eight memory units (a memory unit 60[1,1] to a memory unit 60[2,4]). In the memory unit 60[a,b] (a and b are each a positive integer), a represents an address in the Y direction and b represents an address in the Z direction.

In the memory unit 60, two memory cells 30 are arranged symmetrically with the conductive layer 61 or the conductive layer 62 as the center. The conductive layer 62 electrically connects the conductive layers 32 of the memory units 60 stacked in the Z direction. When a plurality of memory units 60 are stacked in this manner, storage capacity per unit area can be increased, and a memory device that can be miniaturized or highly integrated can be provided.

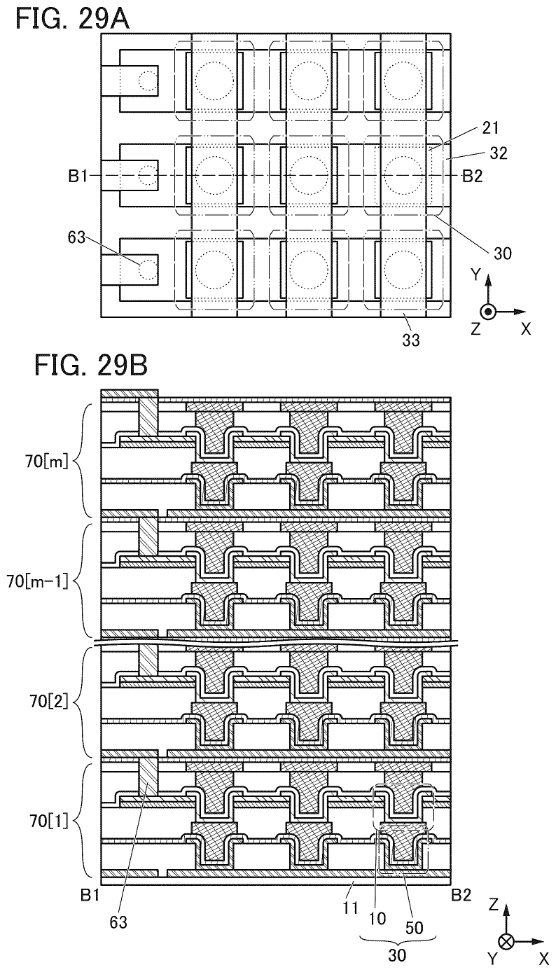

FIG. 29A and FIG. 29B show an example in which a connection portion is placed at an end of the memory unit. FIG. 29A is a plan view of the memory device, and FIG. 29B is a cross-sectional view. Shown here is an example of the memory device in which 3×3×m (m is an integer greater than or equal to 2) memory cells 30 are arranged as an example of a memory cell array. Among layers including the memory cells 30, a first layer and an m-th (uppermost) layer are denoted by a layer 70[1] and a layer 70[m], respectively.

A conductive layer 63 is provided outside the memory unit. The conductive layer 63 may be connected to a wiring in a layer above the layer 70 including the conductive layer 63. For example, the conductive layer 63 provided in the layer 70[1] is electrically connected to a wiring provided in a layer 70[2]. Note that without limitation thereto, the conductive layer 63 may be configured to be electrically connected to a wiring in the layer 70 positioned below the layer 70 including the conductive layer 63 itself.

### <Structure Example 2 of Memory Cell>

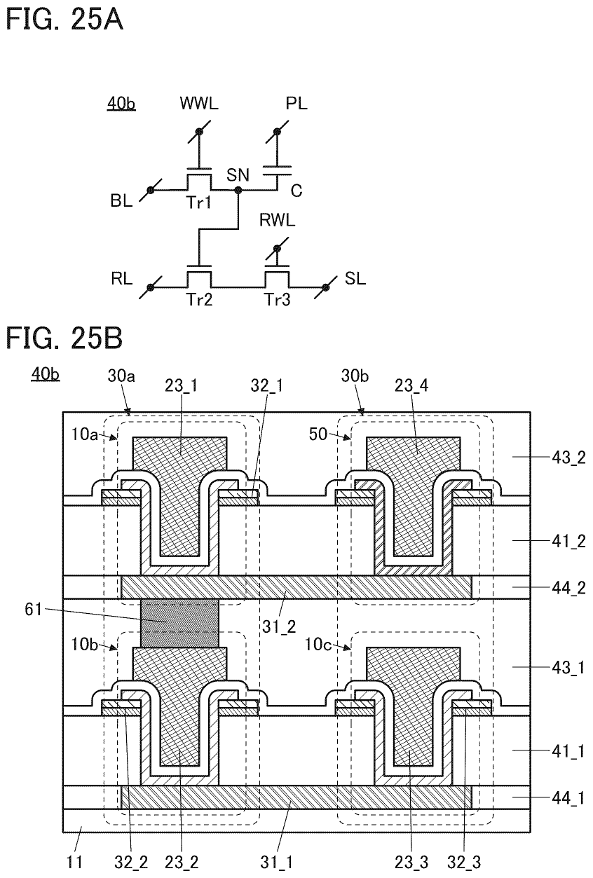

A memory cell 40b shown in FIG. 25A includes three transistors (the transistor Tr1, a transistor Tr2, and a transistor Tr3) and one capacitor C and is also referred to as 3Tr1C. In the memory cell 40b, a gate of the transistor Tr1 is electrically connected to a wiring WWL, one of a source and a drain thereof is electrically connected to the wiring BL, and the other of the source and the drain thereof is electrically connected to the one electrode of the capacitor C. The other electrode of the capacitor C is connected to the wiring PL. A gate of the transistor Tr2 is connected to the other of the source and the drain of the transistor Tr1 and the one electrode of the capacitor C, one of a source and a drain of the transistor Tr2 is connected to a wiring RL, and the other of the source and the drain of the transistor Tr2 is connected to one of a source and a drain of the transistor Tr3. A gate of the transistor Tr3 is electrically connected to a wiring RWL, and the other of the source and the drain of the transistor Tr3 is electrically connected to the wiring SL.

The wiring BL serves as a write bit line and is supplied with a data potential. The wiring WWL serves as a write word line and is supplied with a control signal for controlling on/off of the transistor Tr1. The data potential is charged in the capacitor C through the transistor Tr1, and data is written to a node SN. When an OS transistor is used as the transistor Tr1, long-term data retention in the node SN can be achieved. One of the wiring RL and the wiring SL serves as a read line and is connected to a read circuit such as a sense amplifier, and the other of the wiring RL and the wiring SL is supplied with a fixed potential or a signal. The wiring PL is supplied with a fixed potential or a ground potential.

One example of a method for reading data will be described. First, the wiring SL is precharged, so that a potential difference is generated between the wiring RL and the wiring SL. Here, for example, the wiring SL is set to a high potential, and the wiring RL is set to a ground potential. Then, the transistor Tr3 is brought into an on state. The transistor Tr2 is brought into an on state or an off state in accordance with data written to the node SN. In the case of an on state, a current that is to flow changes depending on the data written. The amount of a current flowing through the wiring SL is determined in accordance with the state of the transistor Tr2. By reading the amount of the current flowing through the wiring SL, the data written to the node SN can be read.

In the memory cell 40b shown in FIG. 25A, the transistor Tr3 is brought into an on state when reading is performed and the transistor Tr3 is brought into an off state when reading is not performed, inhibiting a potential application from the wiring SL to the node SN in the memory cell 40b where reading is not performed.

FIG. 25B is a cross-sectional view of the memory cell 40b. The memory cell 40b includes a transistor 10a, a transistor 10b, a transistor 10c, and the capacitor 50 which are over the insulating layer 11. The transistor 10b and the transistor 10c are provided below the transistor 10a and the capacitor 50.

The transistor 10a, the transistor 10b, and the transistor 10c each have a structure similar to that of the transistor 10 in the description of the memory cell 30. The transistor 10a includes a conductive layer 23_1, a conductive layer 31_2, and a conductive layer 32_1. The transistor 10b includes a conductive layer 23_2, a conductive layer 31_1, and a conductive layer 32_2. The transistor 10c includes a conductive layer 23_3, the conductive layer 31_1, and a conductive layer 32_3. The capacitor 50 includes the conductive layer 31_2 and a conductive layer 23_4. In FIG. 25B, an insulating layer 44_1, an insulating layer 41_1, an insulating layer 43_1, an insulating layer 44_2, an insulating layer 41_2, and an insulating layer 43_2 are provided to be stacked from the insulating layer 11 side. The conductive layer 31_2 is connected to the conductive layer 23_2 through the conductive layer 61 embedded in the insulating layer 43_1 and serving as a connection electrode (plug).

The conductive layer 31_1 is embedded in the insulating layer 44_1. The insulating layer 41_1 having a plurality of openings is provided over the conductive layer 31_1; a semiconductor layer of the transistor 10b is provided along the side surface of one opening among the plurality of openings in the insulating layer 41_1; and a semiconductor layer of the transistor 10c is provided along the side surface of another opening among the plurality of openings. The conductive layer 32_2 and the conductive layer 32_3 are provided over the insulating layer 41_1.

The conductive layer 31_2 is embedded in the insulating layer 44_2. The insulating layer 41_2 having a plurality of openings is provided over the conductive layer 31_2; a semiconductor layer of the transistor 10a is provided along the side surface of one opening among the plurality of openings in the insulating layer 41_2; a conductive layer of the capacitor 50 is provided along the side surface of another opening among the plurality of openings; the conductive layer is provided so as to be electrically connected to the conductive layer 31_2; a layer serving as a dielectric of the capacitor 50 is provided over the insulating layer; and the conductive layer 23_4 is provided over the layer serving as a dielectric. The conductive layer 32_1 is provided over the insulating layer 41_1.

For the conductive layer 31_1 and the conductive layer 31_2, the description of the function, the usable material, the structure, and the like of the conductive layer 31 included in the transistor 10 can be referred to. For the conductive layer 23_1, the conductive layer 23_2, and the conductive layer 23_3, the description of the function, the usable material, the structure, and the like of the conductive layer 23 included in the transistor 10 can be referred to.

The conductive layer 23_4 can be formed using the same conductive film as the conductive layer 23_1.

The transistor 10a, the transistor 10b, the transistor 10c, and the capacitor C correspond to the transistor Tr1, the transistor Tr2, the transistor Tr3, and the capacitor 50, respectively. The conductive layer 23_1, the conductive layer 32_1, the conductive layer 23_4, the conductive layer 32_2, the conductive layer 23_3, and the conductive layer 32_3 correspond to the wiring WWL, the wiring BL, the wiring PL, the wiring RL, the wiring RWL, and the wiring SL, respectively.

In FIG. 25B, the transistor 10b and the transistor 10a overlap with each other, and the transistor 1c and the capacitor 50 overlap with each other. Such a stacked-layer structure allows the area occupied by the memory cell 40b in a plan view to be reduced as compared with the case where each transistor and the capacitor 50 do not overlap with each other.

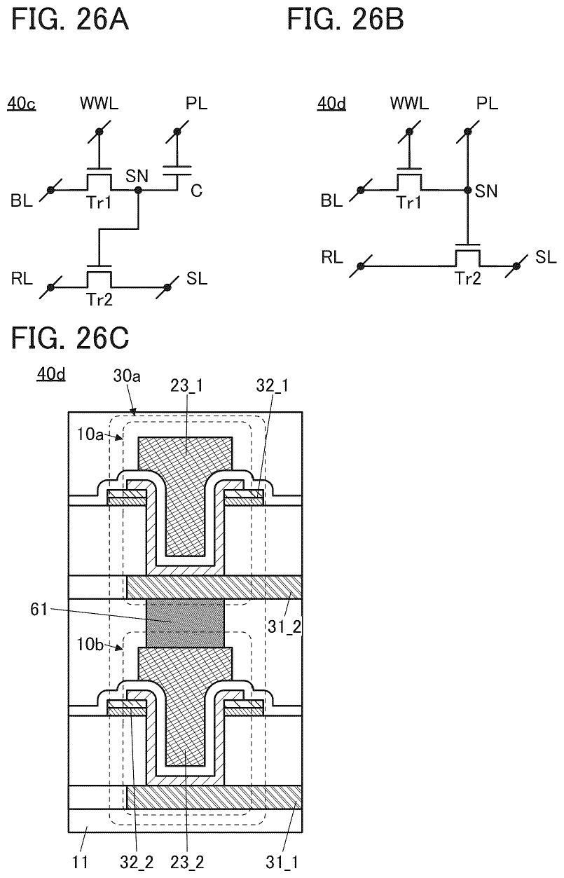

Note that as in a memory cell 40c shown in FIG. 26A, the transistor Tr3 can be omitted. Alternatively, as in a memory cell 40d shown in FIG. 26B, the transistor Tr3 and the capacitor C can be omitted. When an OS transistor is used as the transistor Tr1, the leakage current in the case where the transistor Tr1 is turned off is extremely low. Thus, data can be retained in the node SN even when the capacitor is not provided.

FIG. 26C is a cross-sectional view of the memory cell 40d. The memory cell 40d includes the transistor 10a and the transistor 10b which are over the insulating layer 11. The transistor 10a and the transistor 10b correspond to the transistor Tr1 and the transistor Tr2, respectively.

### <Cross-Sectional Structure Example of Memory Device>

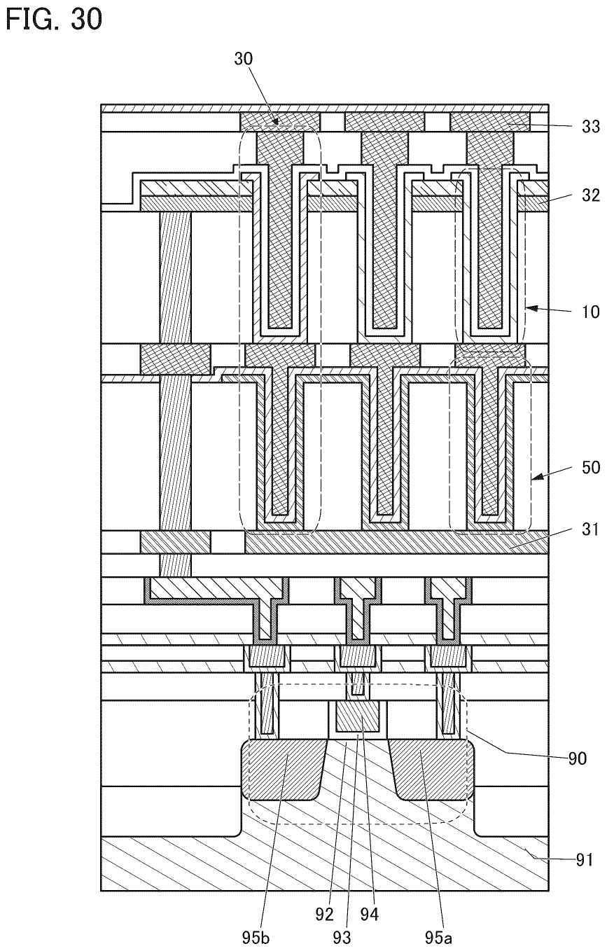

FIG. 30 shows a cross-sectional structure example of a memory device in which a layer including the memory cells 30 is stacked over a layer where a driver circuit including a sense amplifier is provided.

FIG. 30 shows an example in which the capacitor 50 is stacked over a transistor 90 and the transistor 10 is stacked thereover. The transistor 90 is one of the transistors included in the sense amplifier.

With the structure in which the sense amplifier is provided to overlap with the memory cell 30, a bit line can be shortened. This reduces the load on the bit line, so that the read sensitivity of the sense amplifier can be improved. Thus, the storage capacitance of the memory cell can be reduced.

The transistor 90 is provided on a substrate 91 and includes a conductive layer 94 serving as a gate, an insulating layer 93 serving as a gate insulating layer, a semiconductor region 92 formed of part of the substrate 91, and a low-resistance region 95a and a low-resistance region 95b serving as a source region and a drain region. The transistor 90 may be either a p-channel transistor or an n-channel transistor.

Here, in the transistor 90 shown in FIG. 30, the semiconductor region 92 (part of the substrate 91) where a channel is formed has a convex shape. The conductive layer 94 is provided to cover the side surface and the top surface of the semiconductor region 92 with the insulating layer 93 therebetween. Such a transistor 90 is also referred to as a FIN-type transistor because it utilizes the convex portion of the semiconductor substrate.

A structure in which an interlayer insulating layer and a wiring layer are alternately stacked (also referred to as a multilayer wiring layer) is preferably provided between a layer including the transistor 90 and a layer including the memory cell 30. FIG. 30 shows an example in which the low-resistance region 95b of the transistor 90 is electrically connected to the conductive layer 32 serving as a bit line of the memory cell 30 through a wiring and a plug.

At least part of this embodiment can be implemented in combination with the other embodiments described in this specification as appropriate.

### Embodiment 5

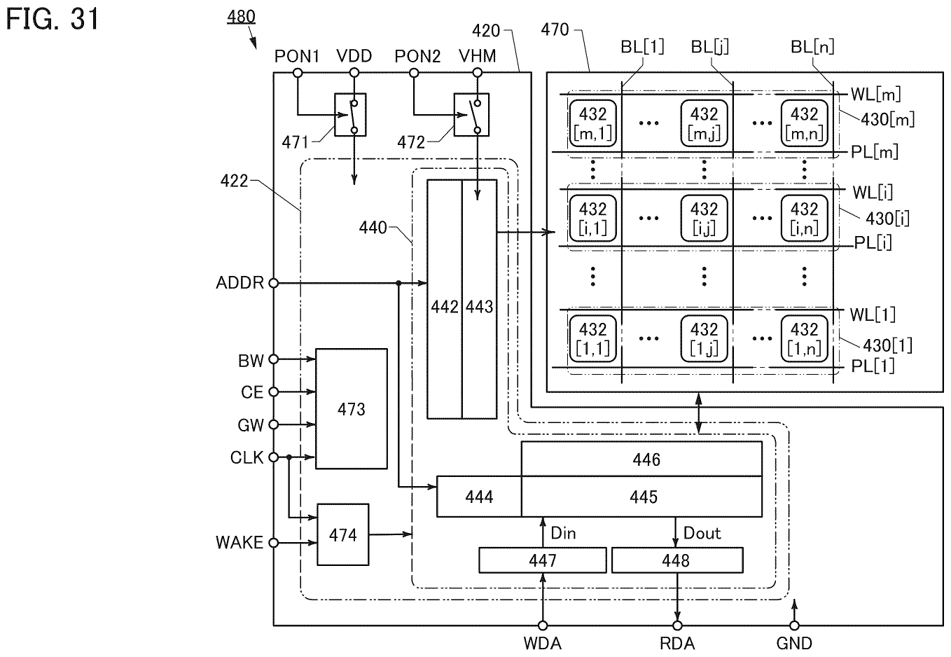

In this embodiment, a memory device of one embodiment of the present invention will be described with reference to FIG. 31 to FIG. 34. A structure example of a memory device in which a layer including memory cells is provided to be stacked over a layer provided with a driver circuit including a sense amplifier will be described in this embodiment.

### <Structure Example of Memory Device>

FIG. 31 is a block diagram illustrating a structure example of a memory device 480 according to one embodiment of the present invention. The memory device 480 shown in FIG. 31 includes a layer 420 and a layer 470 stacked thereover.

The layer 420 is a layer including Si transistors. The layer 470 is provided with element layers 430[1] to 430[m] (m is an integer greater than or equal to 2) as stacked layers. The element layers 430[1] to 430[m] are layers each including an OS transistor. The layer 470 provided with the stacked layers each including the OS transistor can be provided to be stacked over the layer 420.

Elements such as OS transistors and capacitors included in the element layers 430[1] to 430[m] form memory cells. FIG. 31 shows an example in which the element layers 430[1] to 430[m] include a plurality of memory cells 432 arranged in a matrix of m rows and n columns (n is an integer greater than or equal to 2).

In FIG. 31, the memory cell 432 in the first row and the first column is denoted as a memory cell 432[1,1], and the memory cell 432 in the m-th row and the n-th column is denoted as a memory cell 432[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 432 in the i-th row and the j-th column is denoted as a memory cell 432[i,j]. Note that in this embodiment and the like, “i+α” (α is a positive or negative integer) is not below 1 and does not exceed m. Similarly, “j+α” is not below 1 and does not exceed n.

FIG. 31 shows, as an example, m wirings WL extending in a row direction, m wirings PL extending in the row direction, and n wirings BL extending in a column direction. In this embodiment and the like, the first (first row) wiring WL is denoted as a wiring WL[1] and the m-th (m-th row) wiring WL is denoted as a wiring WL[m]. Similarly, the first (first row) wiring PL is denoted as a wiring PL[1] and the m-th (m-th row) wiring PL is denoted as a wiring PL[m]. Similarly, the first (first column) wiring BL is denoted as a wiring BL[1] and the n-th (n-th column) wiring BL is denoted as a wiring BL[n]. Note that the number of the element layers 430[1] to 430[m] is not necessarily the same as the number of the wirings WL (and the wirings PL).

The plurality of memory cells 432 provided in the i-th row are electrically connected to the wiring WL in the i-th row (wiring WL[i]) and the wiring PL in the i-th row (wiring PL[i]). The plurality of memory cells 432 provided in the j-th column are electrically connected to the wiring BL in the j-th column (wiring BL[j]).

The wiring BL serves as a bit line for writing and reading data. The wiring WL serves as a word line for controlling on or off (a conduction state or a non-conduction state) of an access transistor serving as a switch. The wiring PL has a function of a constant potential line connected to a capacitor. Note that a wiring for transmitting a back gate potential can be additionally provided.

The memory cells 432 included in each of the element layers 430[1] to 430[m] are connected to a sense amplifier 446 through the wiring BL. The wiring BL can be provided horizontally and perpendicularly to the surface of the substrate where the layer 420 is provided. When the wiring BL extending from the memory cells 432 included in the element layers 430[1] to 430[m] is formed using a wiring provided perpendicularly to the substrate surface as well as a wiring provided horizontally to the substrate surface, the length of the wiring between the element layers 430 and the sense amplifier 446 can be shortened. The signal transmission distance between the memory cell and the sense amplifier can be shortened and the resistance and parasitic capacitance of the bit line can be significantly reduced, so that power consumption and signal delay can be reduced. Thus, power consumption and signal delay of the memory device 480 can be reduced. Moreover, operation is possible even when the capacitance of the capacitors included in the memory cells 432 is reduced. Thus, the memory device 480 can be downsized.

The layer 420 includes a PSW 471, a PSW 472, and a peripheral circuit 422. The PSW 471 and the PSW 472 are each a power switch. The peripheral circuit 422 includes a driver circuit 440, a control circuit 473, and a voltage generation circuit 474. Note that each circuit included in the layer 420 is a circuit including a Si transistor.

In the memory device 480, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 473.

The control circuit 473 is a logic circuit having a function of controlling the entire operation of the memory device 480. For example, the control circuit performs logical operation on the signal CE, the signal GW, and the signal BW to determine an operation mode (e.g., write operation or read operation) of the memory device 480. Alternatively, the control circuit 473 generates a control signal for the driver circuit 440 so that the operation mode is executed.

The voltage generation circuit 474 has a function of generating negative voltage. The signal WAKE has a function of controlling the input of the signal CLK to the voltage generation circuit 474. For example, when an H-level signal is supplied as the signal WAKE, the signal CLK is input to the voltage generation circuit 474, and the voltage generation circuit 474 generates negative voltage.

The driver circuit 440 is a circuit for writing and reading data to/from the memory cells 432. The driver circuit 440 includes the above-described sense amplifier 446 in addition to a row decoder 442, a column decoder 444, a row driver 443, a column driver 445, an input circuit 447, and an output circuit 448.

The row decoder 442 and the column decoder 444 have a function of decoding the signal ADDR. The row decoder 442 is a circuit for specifying a row to be accessed, and the column decoder 444 is a circuit for specifying a column to be accessed. The row driver 443 has a function of selecting the wiring WL specified by the row decoder 442. The column driver 445 has a function of writing data to the memory cells 432, a function of reading data from the memory cells 432, a function of retaining the read data, and the like.

The input circuit 447 has a function of retaining the signal WDA. Data retained by the input circuit 447 is output to the column driver 445. Data output from the input circuit 447 is data Din to be written to the memory cells 432. Data Dout read from the memory cells 432 by the column driver 445 is output to the output circuit 448. The output circuit 448 has a function of retaining Dout. In addition, the output circuit 448 has a function of outputting Dout to the outside of the memory device 480. Data output from the output circuit 448 is the signal RDA.

The PSW 471 has a function of controlling the supply of VDD to the peripheral circuit 422. The PSW 472 has a function of controlling the supply of VHM to the row driver 443. Here, in the memory device 480, a high power supply voltage is VDD and a low power supply voltage is GND (a ground potential). In addition, VHM is a high power supply voltage used to set the word line at a high level and is higher than VDD. The on/off of the PSW 471 is controlled by the signal PON1, and the on/off of the PSW 472 is controlled by the signal PON2. The number of power domains to which VDD is supplied is one in the peripheral circuit 422 in FIG. 31 but can be more than one. In that case, a power switch is provided for each power domain.

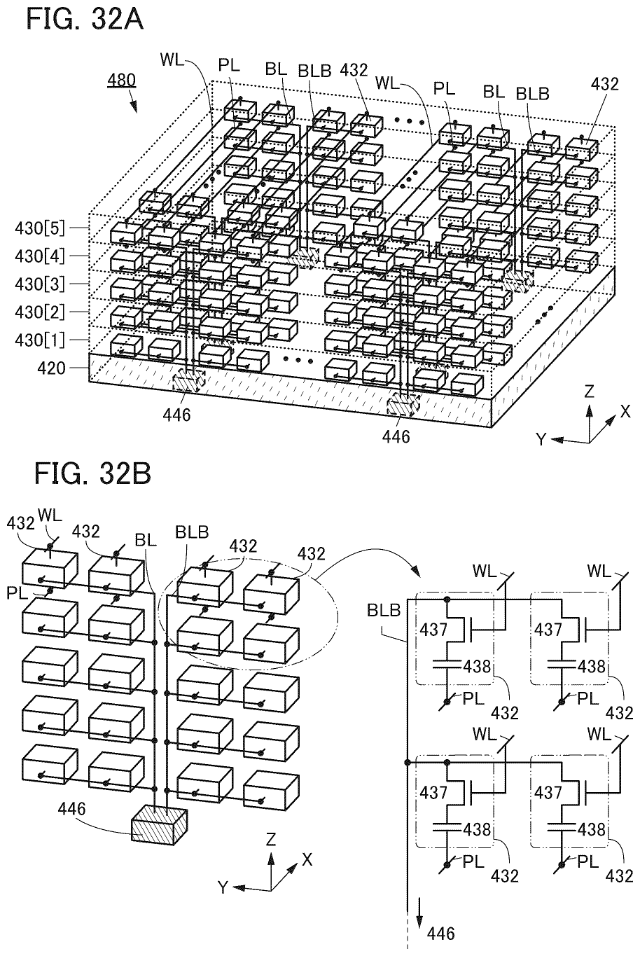

The element layers 430[1] to 430[m] can be provided over the layer 420 to overlap with the layer 420. FIG. 32A shows a perspective view of the memory device 480 in which five (m=5) element layers 430[1] to 430[5] are provided over the layer 420 to overlap with the layer 420.

In FIG. 32A, the element layer 430 provided in the first layer is denoted as the element layer 430[1], the element layer 430 provided in the second layer is denoted as the element layer 430[2], and the element layer 430 provided in the fifth layer is denoted as the element layer 430[5]. FIG. 32A also shows the wiring WL and the wiring PL provided to extend in the X direction and the wiring BL and a wiring BLB provided to extend in the Y direction and the Z direction (the direction perpendicular to the surface of the substrate where the driver circuit is provided). The wiring BLB is an inverted bit line. Note that for easy viewing of the drawing, some of the wirings WL and the wirings PL included in the element layers 430 are not shown.

FIG. 32B shows a schematic view illustrating a structure example of the sense amplifier 446, which is connected to the wiring BL and the wiring BLB, and the memory cells 432 included in the element layers 430[1] to 430[5], which are connected to the wiring BL and the wiring BLB, shown in FIG. 32A. Note that a structure where a plurality of memory cells (memory cells 432) are electrically connected to one wiring BL and one wiring BLB is also referred to as a “memory string.”

FIG. 32B shows an example of a circuit structure of the memory cell 432 connected to the wiring BLB. The memory cell 432 includes a transistor 437 and a capacitor 438. As for the transistor 437, the capacitor 438, and the wirings (BL, WL, and the like), for example, the wiring BL[1] and the wiring WL[1] are referred to as the wiring BL and the wiring WL in some cases.

The memory cell 30 shown as an example in the above embodiment can be used as the memory cell 432, for example. In other words, the transistor 10 can be used as the transistor 437, and the capacitor 50 can be used as the capacitor 438. As the transistor included in the sense amplifier 446, the transistor 90 (see FIG. 30) can be used.

In the memory cell 432, one of a source and a drain of the transistor 437 is connected to the wiring BL. The other of the source and the drain of the transistor 437 is connected to one electrode of the capacitor 438. The other electrode of the capacitor 438 is connected to the wiring PL. A gate of the transistor 437 is connected to the wiring WL.

The wiring PL is a wiring for supplying a constant potential for retaining the potential of the capacitor 438. When a plurality of wirings PL are connected to each other and used as one wiring, the number of wirings can be reduced.

In one embodiment of the present invention, OS transistors are provided to be stacked and a wiring serving as a bit line is provided in the direction perpendicular to the surface of the substrate where the layer 420 is provided. In addition, the transistors 437 and the capacitors 438 included in the memory cells 432 are arranged in the direction perpendicular to the surface of the substrate where the layer 420 is provided. When the elements and the wirings are provided in the direction perpendicular to the substrate surface, the length of the wiring between the element layers can be shortened and the density of the elements per unit area can be increased. Thus, the memory device can have excellent memory capacity and be excellent in reducing power consumption.

### [Structure Examples of Memory Cell 432 and Sense Amplifier 446]

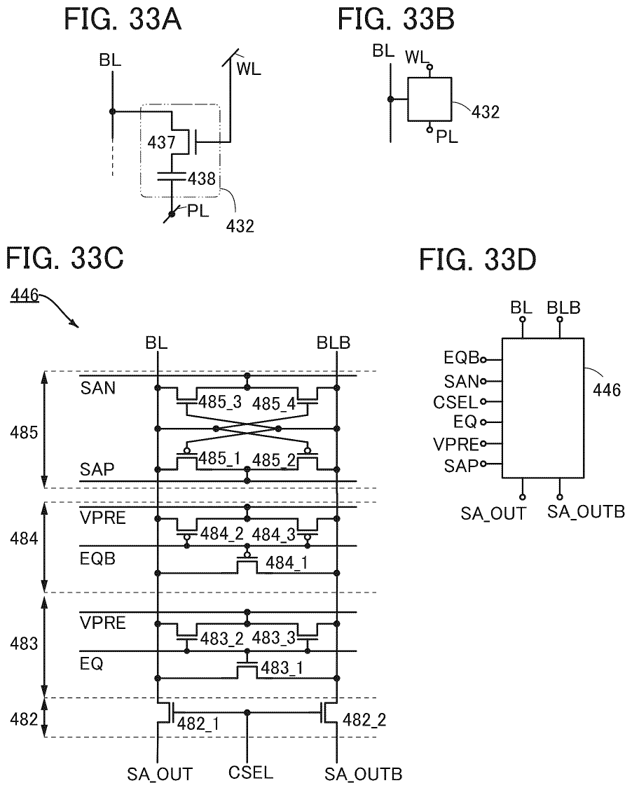

FIG. 33A and FIG. 33B show a circuit diagram corresponding to the above-described memory cell 432 and a circuit block diagram corresponding to the circuit diagram. As shown in FIG. 33A and FIG. 33B, the memory cell 432 is shown as a block in the drawing and the like in some cases. Note that the same can be applied to the case where the wiring BL shown in FIG. 33A and FIG. 33B is replaced with the wiring BLB.

FIG. 33C and FIG. 33D show a circuit diagram corresponding to the above-described sense amplifier 446 and a circuit block diagram corresponding to the circuit diagram. As the sense amplifier 446, a switch circuit 482, a precharge circuit 483, a precharge circuit 484, and an amplifier circuit 485 are shown. In addition to the wiring BL and the wiring BLB, a wiring SA_OUT and a wiring SA_OUTB that output a read signal are shown.

The switch circuit 482 includes, for example, an n-channel transistor 482_1 and an n-channel transistor 482_2, as shown in FIG. 33C. The transistor 482_1 and the transistor 482_2 switch a conduction state between a wiring pair of the wiring SA_OUT and the wiring SA_OUTB and a wiring pair of the wiring BL and the wiring BLB in response to a signal CSEL.

The precharge circuit 483 includes an n-channel transistor 483_1 to an n-channel transistor 483_3, as shown in FIG. 33C. The precharge circuit 483 is a circuit for precharging the wiring BL and the wiring BLB with an intermediate potential VPRE corresponding to a potential VDD/2 in response to a signal EQ.

The precharge circuit 484 includes a p-channel transistor 484_1 to a p-channel transistor 484_3, as shown in FIG. 33C. The precharge circuit 484 is a circuit for precharging the wiring BL and the wiring BLB with the intermediate potential VPRE corresponding to the potential VDD/2 in response to a signal EQB.

The amplifier circuit 485 includes a p-channel transistor 485_1 and a p-channel transistor 485_2 and an n-channel transistor 485_3 and an n-channel transistor 485_4 that are connected to a wiring SAP or a wiring SAN, as shown in FIG. 33C. The wiring SAP or the wiring SAN is a wiring having a function of supplying VDD or VSS. The transistor 485_1 to the transistor 485_4 are transistors that form an inverter loop.

FIG. 33D shows a circuit block diagram corresponding to the sense amplifier 446 described with reference to FIG. 33C or the like. As shown in FIG. 33D, the sense amplifier 446 is shown as a block in the drawing and the like in some cases.

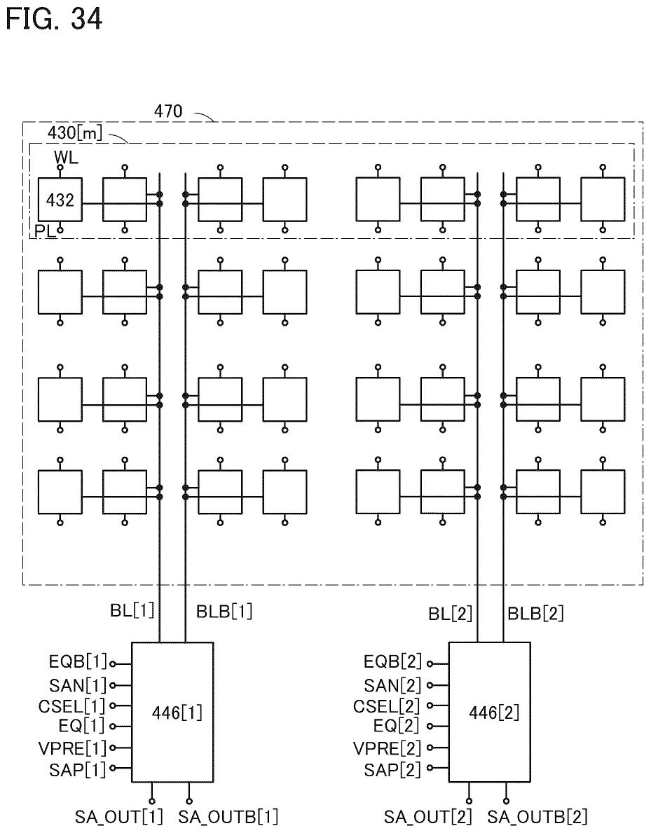

FIG. 34 is a circuit diagram of the memory device 480 in FIG. 31. In FIG. 34, the circuit blocks shown in FIG. 34A to FIG. 34D are used.

As shown in FIG. 34, the layer 470 including the element layer 430[m] includes the memory cells 432. The memory cells 432 shown in FIG. 34 are connected to a pair of the wiring BL[1] and a wiring BLB[1], or a pair of a wiring BL[2] and a wiring BLB[2], for example. The memory cells 432 connected to the wiring BL are memory cells to/from which data is written or read.

The wiring BL[1] and the wiring BLB[1] are connected to a sense amplifier 446[1], and the wiring BL[2] and the wiring BLB[2] are connected to a sense amplifier 446[2]. The sense amplifier 446[1] and the sense amplifier 446[2] can perform data reading in accordance with the various signals described with reference to FIG. 33C.

At least part of this embodiment can be implemented in combination with the other embodiments described in this specification as appropriate.

### Embodiment 6

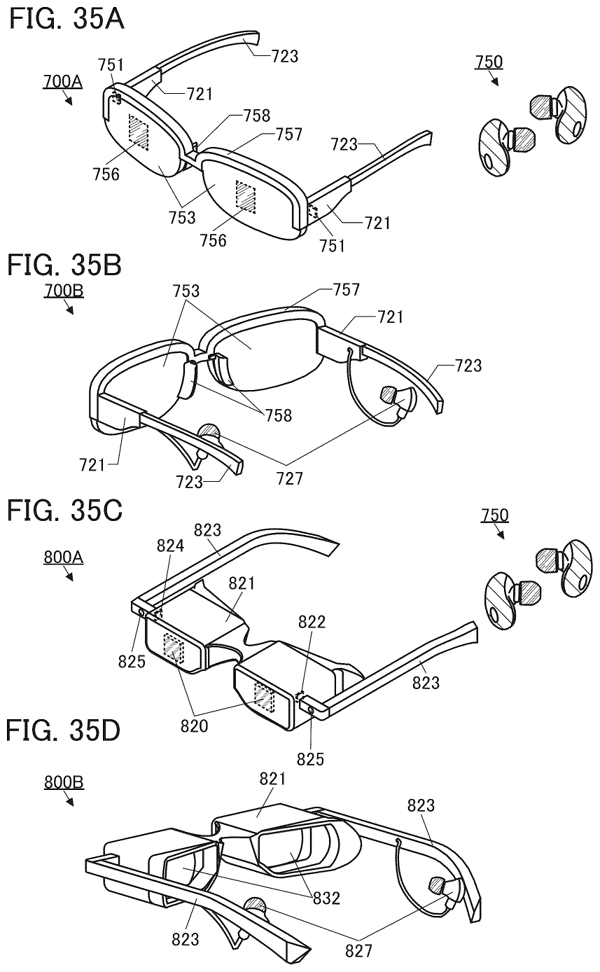

In this embodiment, electronic appliances of one embodiment of the present invention will be described with reference to FIG. 35 to FIG. 37.

### [Electronic Appliance]

Electronic appliances in this embodiment each include the display panel (display device) employing the transistor of one embodiment of the present invention in a display portion. The display device of one embodiment of the present invention can easily achieve higher resolution and higher definition and can achieve high display quality. Thus, the display device of one embodiment of the present invention can be used for display portions of a variety of electronic appliances.

Examples of the electronic appliances include a digital camera, a digital video camera, a digital photo frame, a cellular phone, a portable game machine, a portable information terminal, and an audio reproducing device, in addition to electronic appliances with comparatively large screens, such as a television device, a desktop or laptop personal computer, a monitor for a computer or the like, digital signage, and a large game machine such as a pachinko machine.

In particular, the display panel of one embodiment of the present invention can have higher resolution, and thus can be suitably used for an electronic appliance having a comparatively small display portion. Examples of such an electronic appliance include wristwatch-type and bracelet-type information terminal devices (wearable devices) and a wearable device that can be worn on a head, such as a device for VR such as a head-mounted display, a glasses-type device for AR, or a device for MR.

The definition of the display panel of one embodiment of the present invention is preferably as high as HD (pixel count: 1280×720), FHD (pixel count: 1920×1080), WQHD (pixel count: 2560×1440), WQXGA (pixel count: 2560×1600), 4K (pixel count: 3840×2160), or 8K (pixel count: 7680×4320). In particular, the definition of 4K, 8K, or higher is preferable. In addition, the pixel density (resolution) of the display panel of one embodiment of the present invention is preferably higher than or equal to 100 ppi, further preferably higher than or equal to 300 ppi, still further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With the use of such a display panel with one or both of high definition and high resolution, realistic sensation, sense of depth, and the like can be further increased. Furthermore, there is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic appliance in this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, a current, a voltage, power, radiation, flow rate, humidity, a gradient, oscillation, odor, or infrared rays).

The electronic appliance in this embodiment can have a variety of functions. For example, the electronic appliance can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of wearable devices that can be worn on a head are described with reference to FIG. 35A to FIG. 35D. These wearable devices have one or both of a function of displaying AR contents and a function of displaying VR contents. Note that the wearable devices may have a function of displaying SR or MR contents, in addition to AR and VR contents. The electronic appliance having a function of displaying contents of at least one of AR, VR, SR, MR, and the like enables the user to reach a higher level of immersion.

An electronic appliance 700A shown in FIG. 35A and an electronic appliance 700B shown in FIG. 35B each include a pair of display panels 751, a pair of housings 721, a communication portion (not shown), a pair of wearing portions 723, a control portion (not shown), an imaging portion (not shown), a pair of optical members 753, a frame 757, and a pair of nose pads 758.

The display panel of one embodiment of the present invention can be employed for the display panel 751. Thus, the electronic appliance can perform display with extremely high resolution.

The electronic appliance 700A and the electronic appliance 700B can each project images displayed on the display panels 751 onto display regions 756 of the optical members 753. Since the optical members 753 have a light-transmitting property, the user can see images displayed on the display regions that are superimposed on transmission images seen through the optical members 753. Thus, the electronic appliance 700A and the electronic appliance 700B are electronic appliances capable of AR display.

In each of the electronic appliance 700A and the electronic appliance 700B, a camera capable of capturing images of the front side may be provided as the imaging portion. Furthermore, when each of the electronic appliance 700A and the electronic appliance 700B is provided with an acceleration sensor such as a gyroscope sensor, the orientation of a user's head can be sensed and an image corresponding to the orientation can be displayed on the display region 756.

The communication portion includes a wireless communication device, and a video signal and the like can be supplied by the wireless communication device. Note that instead of the wireless communication device or in addition to the wireless communication device, a connector to which a cable supplied with a video signal and a power potential can be connected may be provided.

Each of the electronic appliance 700A and the electronic appliance 700B is provided with a battery so that charging can be performed wirelessly and/or by wire.

A touch sensor module may be provided in the housing 721. The touch sensor module has a function of detecting a touch on an outer surface of the housing 721. A tap operation, a slide operation, or the like by the user can be detected with the touch sensor module, so that a variety of processing can be executed. For example, processing such as a pause or a restart of a moving image can be executed by a tap operation, and processing such as fast forward or fast rewind can be executed by a slide operation. When the touch sensor module is provided in each of the two housings 721, the range of the operation can be increased.

A variety of touch sensors can be employed for the touch sensor module. For example, touch sensors of a variety of types such as a capacitive type, a resistive film type, an infrared type, an electromagnetic induction type, a surface acoustic wave type, and an optical type can be employed. In particular, a capacitive sensor or an optical sensor is preferably employed for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic appliance 800A shown in FIG. 35C and an electronic appliance 800B shown in FIG. 35D each include a pair of display portions 820, a housing 821, a communication portion 822, a pair of wearing portions 823, a control portion 824, a pair of imaging portions 825, and a pair of lenses 832.

The display panel of one embodiment of the present invention can be employed in the display portion 820. Thus, the electronic appliance can perform display with extremely high resolution. This enables the user to feel a high sense of immersion.

The display portions 820 are positioned inside the housing 821 to be seen through the lenses 832. Furthermore, when the pair of display portions 820 display different images, 3D display using parallax can be also performed.

Each of the electronic appliance 800A and the electronic appliance 800B can be regarded as an electronic appliance for VR. The user who wears the electronic appliance 800A or the electronic appliance 800B can see images displayed on the display portions 820 through the lenses 832.

The electronic appliance 800A and the electronic appliance 800B each preferably include a mechanism for adjusting the lateral positions of the lenses 832 and the display portions 820 so that the lenses 832 and the display portions 820 are positioned optimally in accordance with the positions of the user's eyes. In addition, a mechanism for adjusting focus by changing the distance between the lens 832 and the display portion 820 is preferably included.

The electronic appliance 800A or the electronic appliance 800B can be worn on the user's head with the wearing portions 823. Note that FIG. 35C and the like show examples where the wearing portion 823 has a shape like a temple of glasses; however, one embodiment of the present invention is not limited thereto. The wearing portion 823 can have any shape with which the user can wear and can have a shape of a helmet or a band, for example.

The imaging portion 825 has a function of obtaining external information. Data obtained by the imaging portion 825 can be output to the display portion 820. An image sensor can be used for the imaging portion 825. Moreover, a plurality of cameras may be provided to support a plurality of fields of view, such as a telescope field of view and a wide field of view.

Note that although an example where the imaging portion 825 is included is shown here, a range sensor that is capable of measuring the distance between the user and an object (hereinafter such a sensor is also referred to as a sensing portion) is provided. In other words, the imaging portion 825 is one embodiment of the sensing portion. For the sensing portion, an image sensor or a distance image sensor such as LIDAR (Light Detection and Ranging) can be used, for example. By using images obtained by a camera and images obtained by the distance image sensor, more information can be obtained and a gesture operation with higher accuracy is possible.

The electronic appliance 800A may include a vibration mechanism that functions as bone-conduction earphones. For example, any one or more of the display portion 820, the housing 821, and the wearing portion 823 can include the vibration mechanism. Thus, without additionally requiring an audio device such as headphones, earphones, or a speaker, the user can enjoy a video and sound only by wearing the electronic appliance 800A.

The electronic appliance 800A and the electronic appliance 800B may each include an input terminal. To the input terminal, a cable for supplying a video signal from a video output device or the like, power for charging a battery provided in the electronic appliance, and the like can be connected.

An electronic appliance of one embodiment of the present invention may have a function of performing wireless communication with earphones 750. The earphones 750 include a communication portion (not shown) and have a wireless communication function. The earphones 750 can receive information (e.g., audio data) from the electronic appliance with the wireless communication function. For example, the electronic appliance 700A shown in FIG. 35A has a function of transmitting information to the earphones 750 with the wireless communication function. As another example, the electronic appliance 800A shown in FIG. 35C has a function of transmitting information to the earphones 750 with the wireless communication function.

Alternatively, the electronic appliance may include an earphone portion. The electronic appliance 700B shown in FIG. 35B includes earphone portions 727. For example, a structure in which the earphone portions 727 and the control portion are connected to each other by wire can be employed. Part of a wiring that connects the earphone portions 727 and the control portion may be positioned inside the housing 721 or the wearing portion 723.

Similarly, the electronic appliance 800B shown in FIG. 35D includes earphone portions 827. For example, a structure in which the earphone portions 827 and the control portion 824 are connected to each other by wire can be employed. Part of a wiring that connects the earphone portions 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

Note that the electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of what is called a headset by including the audio input mechanism.

As described above, both the glasses-type device (the electronic appliance 700A, the electronic appliance 700B, or the like) and the goggles-type device (the electronic appliance 800A, the electronic appliance 800B, or the like) are suitable for the electronic appliance of one embodiment of the present invention.

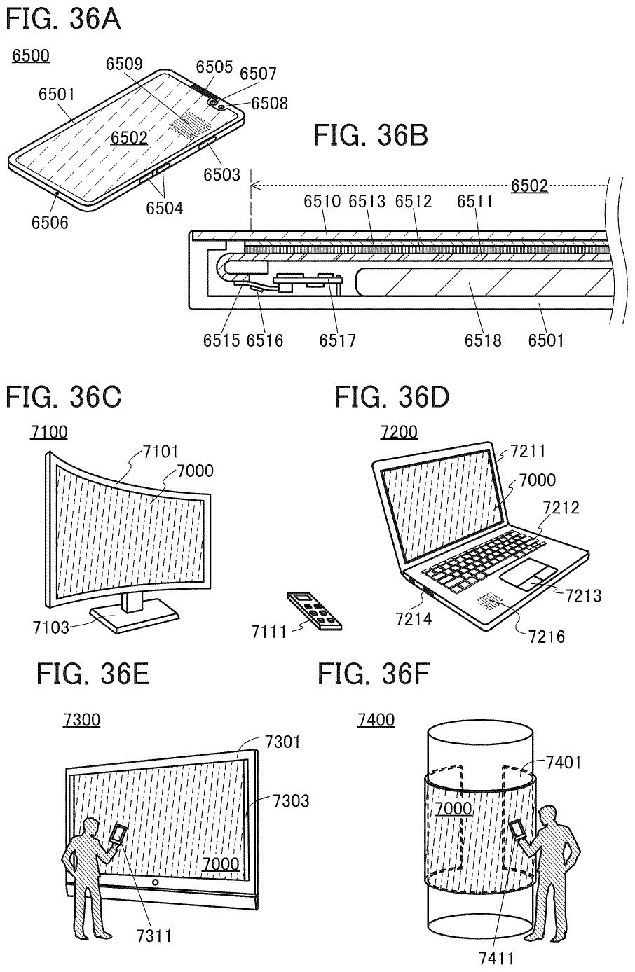

An electronic appliance 6500 shown in FIG. 36A is a portable information terminal device that can be used as a smartphone.

The electronic appliance 6500 includes a housing 6501, a display portion 6502, a power button 6503, buttons 6504, a speaker 6505, a microphone 6506, a camera 6507, a light source 6508, a control device 6509, and the like. The display portion 6502 has a touch panel function. Note that one or more selected from a CPU, a GPU, and a memory device are included as the control device 6509, for example. The semiconductor device of one embodiment of the present invention can be employed for the display portion 6502, the control device 6509, and the like. The semiconductor device of one embodiment of the present invention is suitably used for the control device 6509 because power consumption can be reduced.

The display panel of one embodiment of the present invention can be employed for the display portion 6502.

FIG. 36B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not shown).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be employed for the display panel 6511. Thus, an extremely lightweight electronic appliance can be achieved. In addition, since the display panel 6511 is extremely thin, the battery 6518 with high capacity can be mounted while the thickness of the electronic appliance is reduced. Moreover, part of the display panel 6511 is folded back so that a connection portion with the FPC 6515 is provided on the back side of a pixel portion, so that an electronic appliance with a narrow bezel can be achieved.

FIG. 36C shows an example of a television device. In a television device 7100, a display portion 7000 is incorporated in a housing 7101. Here, a structure in which the housing 7101 is supported by a stand 7103 is shown.

Operation of the television device 7100 shown in FIG. 36C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and a video displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 36D shows an example of a laptop personal computer. A laptop personal computer 7200 includes a housing 7211, a keyboard 7212, a pointing device 7213, an external connection port 7214, a control device 7216, and the like. The display portion 7000 is incorporated in the housing 7211. One or more selected from a CPU, a GPU, and a memory device are included as the control device 7216, for example. The semiconductor device of one embodiment of the present invention can be employed for the display portion 7000, the control device 7216, and the like. The semiconductor device of one embodiment of the present invention is suitably used for the control device 7216 because power consumption can be reduced.

FIG. 36E and FIG. 36F show examples of digital signage.

Digital signage 7300 shown in FIG. 36E includes a housing 7301, the display portion 7000, a speaker 7303, and the like. Furthermore, the digital signage 7300 can include an LED lamp, an operation key (including a power switch or an operation switch), a connection terminal, a variety of sensors, a microphone, and the like.

FIG. 36F is digital signage 7400 attached to a cylindrical pillar 7401. The digital signage 7400 includes the display portion 7000 provided along a curved surface of the pillar 7401.

The larger display portion 7000 can increase the amount of information that can be provided at a time. The larger display portion 7000 attracts more attention, so that advertising effects can be increased, for example.

The use of a touch panel in the display portion 7000 is preferable because in addition to display of an image or a moving image on the display portion 7000, an intuitive operation by the user is possible. Moreover, in the case where the display panel of one embodiment of the present invention is used for providing information such as route information or traffic information, usability can be increased by an intuitive operation.

As shown in FIG. 36E and FIG. 36F, it is preferable that the digital signage 7300 or the digital signage 7400 can work with an information terminal device 7311 or an information terminal device 7411 such as a user's smartphone through wireless communication. For example, information of an advertisement displayed on the display portion 7000 can be displayed on a screen of the information terminal device 7311 or the information terminal device 7411. Furthermore, by the operation of the information terminal device 7311 or the information terminal device 7411, display on the display portion 7000 can be switched.

It is also possible to make the digital signage 7300 or the digital signage 7400 execute a game with the use of the screen of the information terminal device 7311 or the information terminal device 7411 as an operation means (a controller). Thus, an unspecified number of users can join in and enjoy the game concurrently.

The display panel of one embodiment of the present invention can be employed for the display portion 7000 shown in each of FIG. 36C to FIG. 36F.

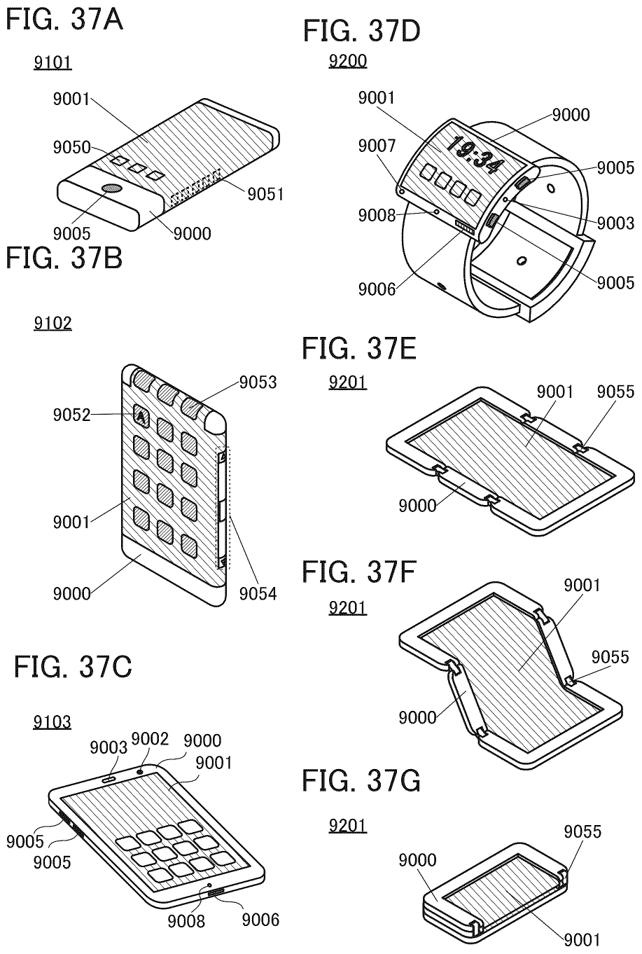

Electronic appliances shown in FIG. 37A to FIG. 37G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, a position, speed, acceleration, angular velocity, rotational frequency, a distance, light, liquid, magnetism, temperature, a chemical substance, sound, time, hardness, an electric field, a current, a voltage, power, radiation, flow rate, humidity, a gradient, oscillation, an odor, or infrared rays), a microphone 9008, and the like.

The electronic appliances shown in FIG. 37A to FIG. 37G have a variety of functions. For example, the electronic appliances can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data recorded in a recording medium. Note that the functions of the electronic appliances are not limited thereto, and the electronic appliances can have a variety of functions. The electronic appliances may include a plurality of display portions. In addition, the electronic appliance may each be provided with a camera or the like and have a function of taking a still image or a moving image and storing the taken image in a recording medium (an external recording medium or a recording medium incorporated in the camera), a function of displaying the taken image on the display portion, or the like.

The electronic appliance shown in FIG. 37A to FIG. 37G are described in detail below.

FIG. 37A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. In addition, the portable information terminal 9101 can display characters and image information on its plurality of surfaces. FIG. 37A shows an example in which three icons 9050 are displayed. Furthermore, information 9051 indicated by dashed rectangles can be displayed on another surface of the display portion 9001. Examples of the information 9051 include notification of incoming e-mails, SNS, calls, and the like; the titles and senders of e-mails, SNS, and the like; dates; time; remaining battery; and radio field intensity. Alternatively, the icon 9050 or the like may be displayed at the position where the information 9051 is displayed.

FIG. 37B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is shown. For example, the user can check the information 9053 in a position that can be observed from above the portable information terminal 9102, with the portable information terminal 9102 put in a breast pocket of his/her clothes. The user can see display without taking out the portable information terminal 9102 from the pocket and determine whether to answer a call, for example.

FIG. 37C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on a front surface of the housing 9000; the operation keys 9005 as buttons for operations on a left side surface of the housing 9000; and the connection terminal 9006 on a bottom surface.

FIG. 37D is a perspective view illustrating a wristwatch-type portable information terminal 9200. For example, the portable information terminal 9200 can be used as a Smartwatch (registered trademark). A display surface of the display portion 9001 is provided to be curved, and display can be performed along the curved display surface. Mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 37E to FIG. 37G are perspective views illustrating a foldable portable information terminal 9201. FIG. 37E is a perspective view of an opened state of the portable information terminal 9201, FIG. 37G is a perspective view of a folded state thereof, and FIG. 37F is a perspective view of a state in the middle of change from one of FIG. 37E and FIG. 37G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. For example, the display portion 9001 can be bent with a radius of curvature greater than or equal to 0.1 mm and less than or equal to 150 mm.

At least part of this embodiment can be implemented in combination with the other embodiments described in this specification as appropriate.

### Embodiment 7

In this embodiment, application examples of a semiconductor device of one embodiment of the present invention will be described. The semiconductor device of one embodiment of the present invention can be used for an electronic component, an electronic appliance, a large computer, space equipment, and a data center (also referred to as DC), for example. An electronic component, an electronic appliance, a large computer, space equipment, and a data center each using the semiconductor device of one embodiment of the present invention are effective in achieving high performance, e.g., reducing power consumption.

An electronic component or the like employing the semiconductor device of one embodiment of the present invention can be applied to the electronic appliance shown as an example in Embodiment 5.

### [Electronic Component]

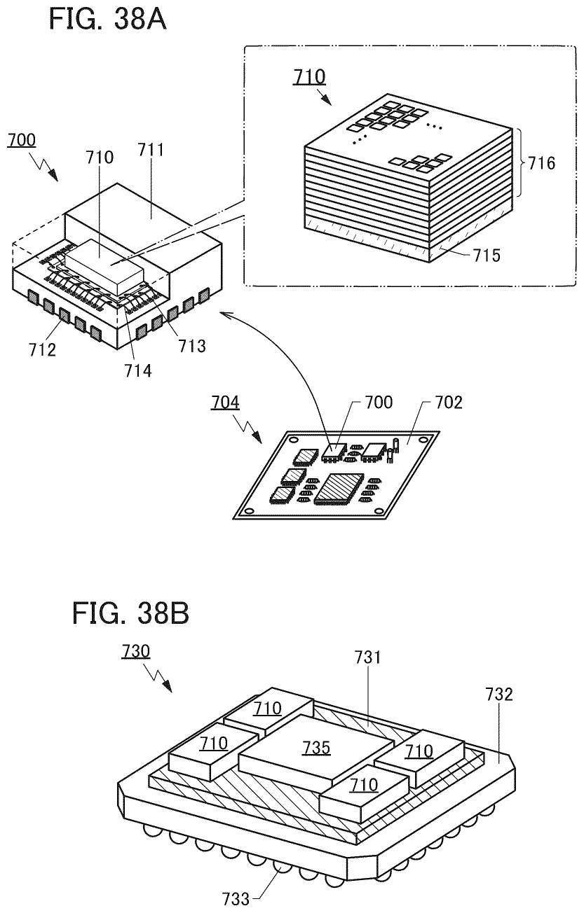

FIG. 38A shows a perspective view of a substrate (a mounting board 704) on which an electronic component 700 is mounted. The electronic component 700 shown in FIG. 38A includes a semiconductor device 710 in a mold 711. Some components are omitted in FIG. 38A to show the inside of the electronic component 700. The electronic component 700 includes lands 712 outside the mold 711. The land 712 is electrically connected to an electrode pad 713, and the electrode pad 713 is electrically connected to the semiconductor device 710 via a wire 714. The electronic component 700 is mounted on a printed circuit board 702, for example. A plurality of such electronic components are combined and electrically connected on the printed circuit board 702, so that the mounting board 704 is completed.

The semiconductor device 710 includes a driver circuit layer 715 and a memory layer 716. Note that the memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu—Cu direct bonding. The monolithic stacked-layer structure of the driver circuit layer 715 and the memory layer 716 enables, for example, what is called an on-chip memory structure where a memory is directly formed on a processor. The on-chip memory structure allows an interface portion between the processor and the memory to operate at high speed.

With the on-chip memory structure, the size of a connection wiring and the like can be made smaller than that when the technique using through electrodes such as TSVs is employed; thus, the number of connection pins can be increased. The increase in the number of connection pins enables parallel operation, which can improve the bandwidth of the memory (also referred to as memory bandwidth).

It is preferable that the plurality of memory cell arrays included in the memory layer 716 be formed using OS transistors and be monolithically stacked. The monolithic stacked-layer structure of a plurality of memory cell arrays can improve one or both of the bandwidth of the memory and the access latency of the memory. Note that the bandwidth refers to the data transfer amount per unit time, and the access latency refers to time between data access and start of data transmission. Note that in the case where Si transistors are used for the memory layer 716, the monolithic stacked-layer structure is difficult to form as compared with the case where OS transistors are used for the memory layer 716. Therefore, the OS transistors are superior to the Si transistors in the monolithic stacked-layer structure.

The semiconductor device 710 may be called a die. Note that in this specification and the like, a die refers to a chip piece obtained by, for example, forming a circuit pattern on a disc-like substrate (also referred to as a wafer) or the like and cutting the substrate into dies in a process of manufacturing a semiconductor chip. Note that examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 38B shows a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of semiconductor devices 710 are provided on the interposer 731.

The electronic component 730 using the semiconductor devices 710 as high bandwidth memories (HBM) is shown as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. The interposer 731 also has a function of electrically connecting an integrated circuit provided on the interposer 731 to an electrode provided on the package substrate 732. Accordingly, the interposer is sometimes referred to as a “redistribution substrate” or an “intermediate substrate.” In some cases, a through electrode is provided in the interposer 731 to be used for electrically connecting an integrated circuit and the package substrate 732. In a silicon interposer, a TSV can also be used as the through electrode.

In an HBM, many wirings need to be connected to achieve wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like each using a silicon interposer, a decrease in reliability due to a difference in the expansion coefficient between an integrated circuit and the interposer is less likely to occur. Furthermore, a surface of a silicon interposer has high planarity, and poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Accordingly, in the case where the size of the electronic component 730 is to be reduced, the width of the terminal pitch becomes an issue, which sometimes makes it difficult to provide a large number of wirings for achieving a wide memory bandwidth. For this reason, the monolithic stacked-layer structure using the OS transistors is suitable, as described above. A composite structure where memory cell arrays stacked using a TSV and monolithically stacked memory cell arrays are combined may be employed.

A heat sink (a radiator plate) may be provided to overlap with the electronic component 730. In the case where a heat sink is provided, integrated circuits provided on the interposer 731 preferably have the same height. For example, in the electronic component 730 described in this embodiment, the semiconductor devices 710 and the semiconductor device 735 preferably have the same height.

Electrodes 733 may be provided on a bottom part of the package substrate 732 to mount the electronic component 730 on another substrate. FIG. 38B shows an example in which the electrodes 733 are formed of solder balls. When the solder balls are provided in a matrix on the bottom part of the package substrate 732, BGA (Ball Grid Array) mounting can be achieved. Alternatively, the electrodes 733 may be formed of conductive pins. When the conductive pins are provided in a matrix on the bottom part of the package substrate 732, PGA (Pin Grid Array) mounting can be achieved.

The electronic component 730 can be mounted on another substrate by a variety of mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### [Large Computer]

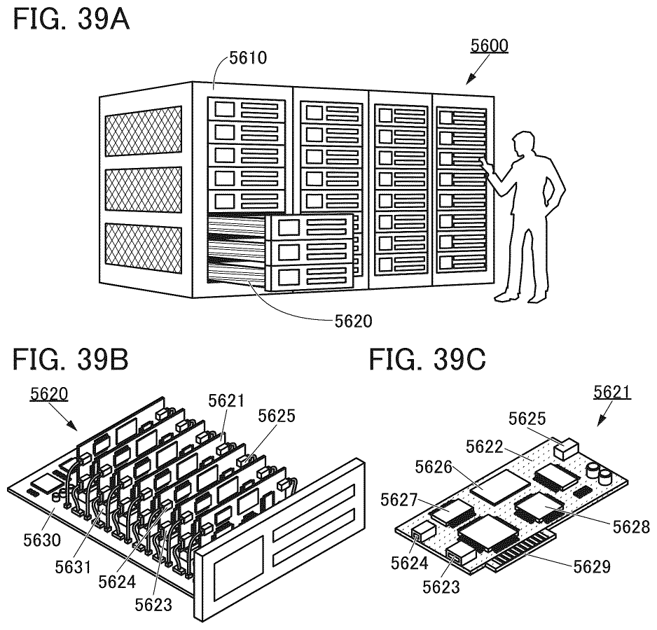

FIG. 39A shows a perspective view of a large computer 5600. In the large computer 5600, a plurality of rack mount computers 5620 are stored in a rack 5610. Note that the large computer 5600 may also be referred to as a supercomputer.

FIG. 39B shows a perspective view of an example of the computer 5620. The computer 5620 includes a motherboard 5630. The motherboard 5630 is provided with a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

FIG. 39C shows an example of the PC card 5621. The PC card 5621 is a processing board provided with a CPU, a GPU, a memory device, and the like, for example. The PC card 5621 includes a board 5622, and the connection terminal 5623, the connection terminal 5624, the connection terminal 5625, an electronic component 5626, an electronic component 5627, an electronic component 5628, a connection terminal 5629, and the like that are mounted on the board 5622. Note that FIG. 39C shows components other than the electronic component 5626, the electronic component 5627, and the electronic component 5628.

The connection terminal 5629 has a shape that can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. As another example, the connection terminal 5623, the connection terminal 5624, and the connection terminal 5625 can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard for each of the connection terminal 5623, the connection terminal 5624, and the connection terminal 5625 is HDMI (registered trademark).

The electronic component 5626 includes a terminal (not shown) for inputting and outputting signals, and when the terminal is inserted in a socket (not shown) of the board 5622, the electronic component 5626 and the board 5622 can be electrically connected to each other.

The electronic component 5627 and the electronic component 5628 each include a plurality of terminals, and when the terminals are reflow-soldered, for example, to wirings of the board 5622, the electronic component 5627 and the electronic component 5628 can be mounted. Examples of the electronic component 5627 include an FPGA, a GPU, and a CPU. The electronic component 730 can be used as the electronic component 5627, for example. An example of the electronic component 5628 is a memory device. The electronic component 700 can be used as the electronic component 5628, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used for space equipment.

The semiconductor device of one embodiment of the present invention includes an OS transistor. A change in electrical characteristics of the OS transistor due to exposure to radiation is small. That is, the OS transistor is highly resistant to radiation and thus can be suitably used in an environment where radiation can enter. For example, the OS transistor can be suitably used in the case of being used in outer space. Specifically, the OS transistor can be used as a transistor included in a semiconductor device provided in a space shuttle, an artificial satellite, or a space probe. Examples of radiation include X-rays and a neutron beam. Note that outer space refers to, for example, space at an altitude greater than or equal to 100 km, and outer space described in this specification may include one or more of the thermosphere, the mesosphere, and the stratosphere.

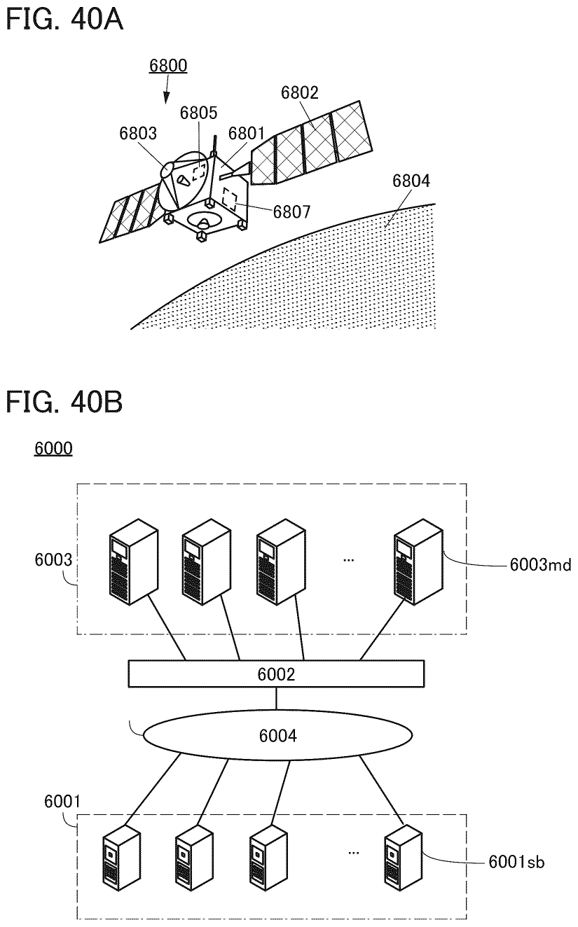

FIG. 40A shows an artificial satellite 6800 as an example of space equipment. The artificial satellite 6800 includes a body 6801, solar panels 6802, an antenna 6803, a secondary battery 6805, and a control device 6807. Note that FIG. 40A shows a planet 6804 in outer space, for example.

Although not shown in FIG. 40A, a battery management system (also referred to as a BMS) or a battery control circuit may be provided in the secondary battery 6805. An OS transistor is suitably used in the battery management system or the battery control circuit because low power consumption and high reliability are achieved even in outer space.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, electric power required for the operation of the artificial satellite 6800 might not be generated. In order to operate the artificial satellite 6800 even in the situation where the amount of generated electric power is small, the artificial satellite 6800 may be provided with the secondary battery 6805. Note that the solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed using one or more selected from a CPU, a GPU, and a memory device, for example. Note that the semiconductor device that is one embodiment of the present invention and includes an OS transistor is suitably used for the control device 6807. A change in electrical characteristics due to exposure to radiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can have a function of an earth observing satellite, for example.

Although the artificial satellite is shown as an example of space equipment in this embodiment, the present invention is not limited thereto. The semiconductor device of one embodiment of the present invention can be suitably used for space equipment such as a spacecraft, a space capsule, or a space probe, for example.

As described above, the OS transistor has excellent effects of achieving a wide memory bandwidth and being highly resistant to radiation as compared with the Si transistor.

### [Data Center]

The semiconductor device of one embodiment of the present invention can be suitably used for, for example, a storage system employed in a data center or the like. Long-term data management, such as a guarantee for data immutability, is required for the data center. The long-term data management needs increasing the scale of the data center, such as installing a storage and a server for storing an enormous amount of data, ensuring a stable power source for data retention, and ensuring cooling equipment required for data retention.

With the use of the semiconductor device of one embodiment of the present invention for a storage system employed in a data center, electric power required for data retention can be reduced and a semiconductor device that retains data can be downsized. Accordingly, downsizing of the storage system, downsizing of a power source for data retention, downscaling of cooling equipment, and the like can be achieved. Therefore, space saving of the data center can be achieved.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention can achieve a data center that stably operates even in a high-temperature environment. Thus, the reliability of the data center can be increased.

FIG. 40B shows a storage system applicable to a data center. A storage system 6000 shown in FIG. 40B includes a plurality of servers 6001sb as a host 6001. In addition, the storage system 6000 includes a plurality of memory devices 6003md as a storage. In the shown example, the host 6001 and the storage 6003 are connected through a storage area network 6004 and a storage control circuit.

The host 6001 corresponds to a computer that accesses data stored in the storage 6003. The hosts 6001 may be connected to each other through a network.

The data access speed, i.e., the time taken for storing and outputting data, of the storage 6003 is shortened by using a flash memory, but is considerably longer than the data access speed of a DRAM that can be used as a cache memory in a storage. In the storage system, in order to solve the problem of low access speed of the storage 6003, a cache memory is usually provided in a storage to shorten the time taken for storing and outputting data.

The cache memories are used in the storage control circuit 6002 and the storage 6003. Data transmitted between the host 6001 and the storage 6003 are stored in the cache memories in the storage control circuit 6002 and the storage 6003 and then output to the host 6001 or the storage 6003.

The use of an OS transistor as a transistor for storing data in the cache memory to retain a potential based on data can reduce the frequency of refreshing, so that power consumption can be reduced. Furthermore, downsizing is possible by stacking memory cell arrays.

Note that the use of the semiconductor device of one embodiment of the present invention for one or more selected from an electronic component, an electronic appliance, a large computer, space equipment, and a data center is expected to produce an effect of reducing power consumption. While the demand for energy is expected to increase with higher performance or higher integration of semiconductor devices, the emission amount of greenhouse effect gases typified by carbon dioxide (CO₂) can be reduced with the use of the semiconductor device of one embodiment of the present invention. Furthermore, the semiconductor device of one embodiment of the present invention has low power consumption and thus is effective as a global warming countermeasure.

At least part of this embodiment can be implemented in combination with the other embodiments described in this specification as appropriate.

### Example 1

In this example, evaluations of etching characteristics of a metal film and coating films that can be used for one embodiment of the present invention were conducted.

First, a metal film, a first coating film, and a second coating film were prepared.

The metal film which was prepared is described. An insulating film was formed over a silicon wafer, and a ruthenium film was formed thereover as the metal film by a DC sputtering method. A ruthenium metal was used as a target; an Ar gas was made to flow at 50 sccm; the film formation pressure was 0.4 Pa; 0.5 kW was applied to a film formation electrode; and a distance between the target and the substrate was 185 mm. The substrate temperature was room temperature. The thickness of the metal film was approximately 50 nm.

Next, an insulating film was formed over a silicon wafer, and an SOC film was formed thereover as the first coating film. First, a resin including an organic substance was applied by a spin coating method. After that, baking was performed at 250° C. for 60 seconds, so that the first coating film was obtained. The thickness of the first coating film was formed to have a thickness sufficient for evaluating an etching rate.

Next, an insulating film was formed over a silicon wafer, and an SOG film was formed thereover as the second coating film. First, a solution including polysiloxane and an organic solvent was applied by a spin coating method. After that, baking was performed at 220° C. for 60 seconds, so that the second coating film was obtained. The thickness of the second coating film was formed to have a thickness sufficient for evaluating an etching rate.

Next, dry etching treatment was performed on each of the obtained metal film, first coating film, and second coating film, and the amount of reduction in thickness due to the etching was measured to calculate an etching rate. As a dry etching apparatus, an inductively-coupled plasma etching apparatus was used. The dry etching conditions were as follows: the ICP high-frequency power was 3000 W; the Bias high-frequency power was 200 W; the pressure was 0.67 Pa; and the lower electrode temperature was 40° C. As etching gases, an oxygen gas and a chlorine gas were used. The total flow rate of the oxygen gas and the chlorine gas was 200 sccm. The sum of flow rates of the oxygen gas and the chlorine gas was set to 100[%], and the flow rate ratio of the oxygen gas was set for four conditions of 62.5, 75, 87.5, and 100[%].

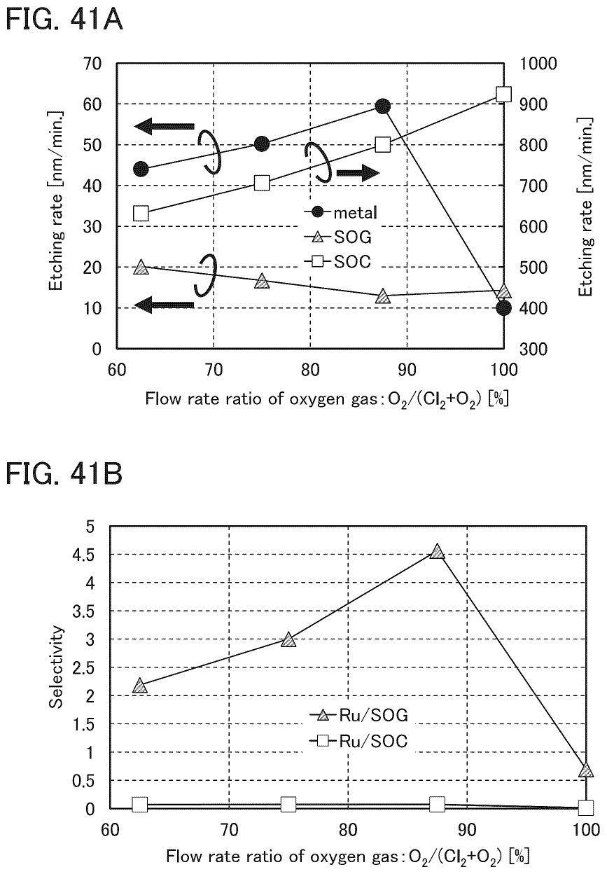

FIG. 41A shows the etching rates of the metal film (denoted by metal in the drawing), the first coating film (denoted by SOC in the drawing), and the second coating film (denoted by SOG in the drawing). The horizontal axis represents the flow rate ratio of the oxygen gas, the first vertical axis (shown on the left) represents the etching rates of the metal film and the second coating film, and the second vertical axis (shown on the right) represents the etching rate of the first coating film.

FIG. 41B shows the etching selectivity of the metal film to the second coating film (denoted by Ru/SOG in the drawing) and the etching selectivity of the metal film to the first coating film (denoted by Ru/SOC in the drawing). The horizontal axis represents the flow rate ratio of the oxygen gas, and the vertical axis represents the selectivity. The etching selectivity of the metal film to the second coating film was calculated as the etching rate of the metal film regarding the etching rate of the second coating film as 1. The etching selectivity of the metal film to the first coating film was calculated as the etching rate of the metal film regarding the etching rate of the first coating film as 1.

The maximum etching selectivity of the metal film to the second coating film was 4.6, revealing that the second coating film can be suitably used for etching of ruthenium or the like. Furthermore, it was found that although the selectivity tended to be higher as the flow rate ratio of the oxygen gas increased, the selectivity was lower than 1 under the condition where the chlorine gas was not included at all. Thus, it was suggested that an etching gas including an oxygen gas having a high flow rate ratio and including a chlorine gas was preferable.

### Example 2

In this example, evaluations of etching characteristics of a conductive film that can be used for one embodiment of the present invention were conducted.

First, a conductive film was prepared. An insulating film was formed over a silicon wafer, and an ITSO film was formed thereover as a metal film by a sputtering method. An indium tin oxide including silicon oxide at 5 wt % was used as a target; an Ar gas was made to flow at 50 sccm; the film formation pressure was 0.4 Pa; and the film formation power was 1000 W. The substrate temperature was room temperature. The thickness of the conductive film was formed to have a thickness sufficient for evaluating an etching rate.

Next, a metal film was prepared under the conditions described in Example 1. The thickness of the metal film was formed to have a thickness sufficient for evaluating an etching rate.

Next, dry etching treatment was performed on each of the conductive film and the metal film, and the amount of reduction in thickness due to the etching was measured to calculate an etching rate. As a dry etching apparatus, a capacitively coupled plasma etching apparatus was used. The dry etching conditions were as follows: the power of an upper electrode was 1000 W; and the power of a lower electrode was set for four conditions of 50 W, 200 W, 400 W, and 600 W. The pressure was 1.2 Pa, and the lower electrode temperature was 60° C. As etching gases, a methane gas and an argon gas were used, and the flow rate of the methane gas was 18 sccm and the flow rate of the argon gas was 42 sccm.

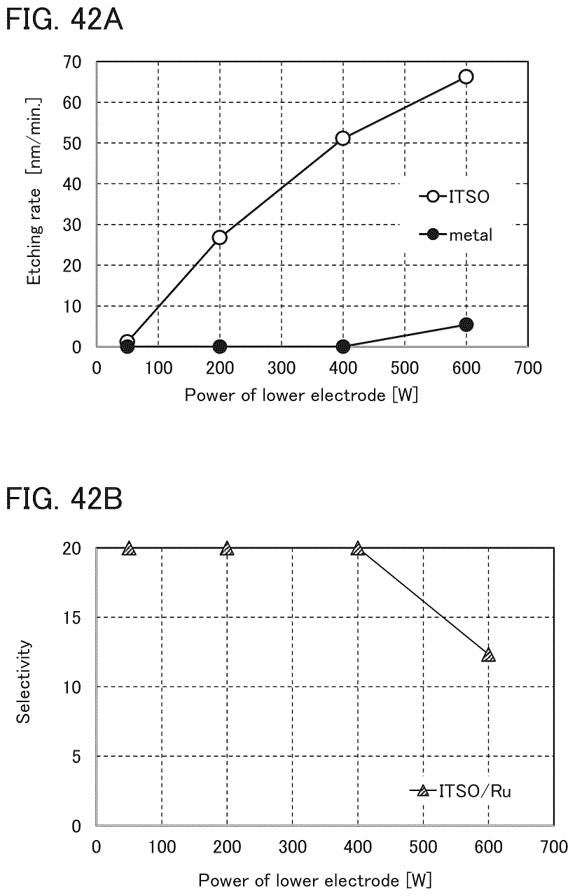

FIG. 42A shows the etching rates of the conductive film (denoted by ITSO in the drawing) and the metal film (denoted by metal in the drawing). The horizontal axis represents the power of the lower electrode, and the vertical axis represents the etching rates of the conductive film and the metal film.

FIG. 42B shows the etching selectivity of the conductive film to the metal film (denoted by ITSO/Ru in the drawing). The horizontal axis represents the power of the lower electrode, and the vertical axis represents the selectivity. The etching selectivity of the conductive film to the metal film was calculated as the etching rate of the conductive film regarding the etching rate of the metal film as 1.

It was revealed that the use of the etching conditions enabled etching of ITSO at a suitable rate. When the power of the lower electrode was lower than or equal to 400 W, the etching rate of ruthenium used for the metal film was able to be extremely low. It was found that the etching selectivity of the conductive film to the metal film can be increased under the etching conditions using a methane gas and an argon gas.

### Example 3

In this example, a stack of one embodiment of the present invention was fabricated and subjected to cross-sectional observation.

First, the conductive layer 112a was formed over an insulating layer. The conductive layer 112a had a stacked-layer structure of a tungsten layer and an ITSO layer over the tungsten layer.

Next, as the insulating film 110af, a 5-nm-thick silicon nitride film was formed over the conductive layer 112a. Subsequently, as the insulating film 110bf, a 20-nm-thick silicon oxide film was formed over the insulating film 110af. Then, as the insulating film 110cf, a 10-nm-thick silicon nitride film was formed over the insulating film 110bf.

Next, as the conductive film 51af, a 15-nm-thick ITSO film was formed over the insulating film 110cf by a sputtering method. Then, as the metal film 51bf, a 10-nm-thick ruthenium film was formed over the conductive film 51af by a DC sputtering method.

Next, as the coating film 278f, a 40-nm-thick SOG film was formed over the metal film 51bf. Subsequently, the coating film 278f was processed using a resist mask to form the coating film 278. The coating film 278 included, in a region overlapping with the conductive layer 112a, an opening portion that had a diameter of 60 nm and was a substantially circular in a top view.

Next, the metal film 51bf was processed by a dry etching method using the coating film 278 as a mask to form the metal layer 51b. The dry etching conditions were as follows: the ICP high-frequency power was 3000 W; the Bias high-frequency power was 200 W; the pressure was 0.67 Pa; and the lower electrode temperature was 40° C. As etching gases, an oxygen gas and a chlorine gas were used. The flow rate of the oxygen gas was 175 sccm and the flow rate of the chlorine gas was 25 sccm.

Next, in a state where the top surface of the metal layer 51b was covered with the coating film 278, the conductive film 51af was processed by a dry etching method using the coating film 278 as a mask to form the conductive layer 51a. As a dry etching apparatus, a capacitively coupled plasma etching apparatus was used. The dry etching conditions were as follows: the power of an upper electrode was 1000 W; and the power of a lower electrode was 200 W. The pressure was 1.2 Pa, and the lower electrode temperature was 60° C. As etching gases, a methane gas and an argon gas were used, and the flow rate of the methane gas was 18 sccm and the flow rate of the argon gas was 42 sccm.

Next, the insulating film 110cf, the insulating film 110bf, and the insulating film 110af were processed in this order by a dry etching method to form the insulating layer 110c, the insulating layer 110b, and the insulating layer 110a. As etching gases, C₄F₈, C₄F₆, oxygen, and argon were used.

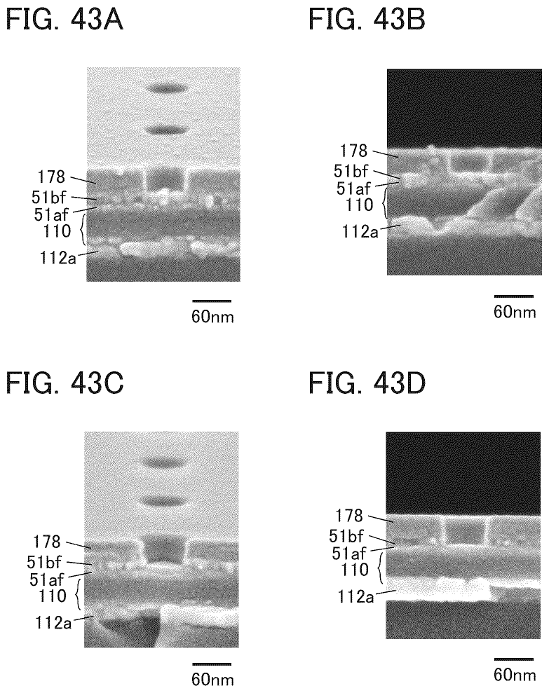

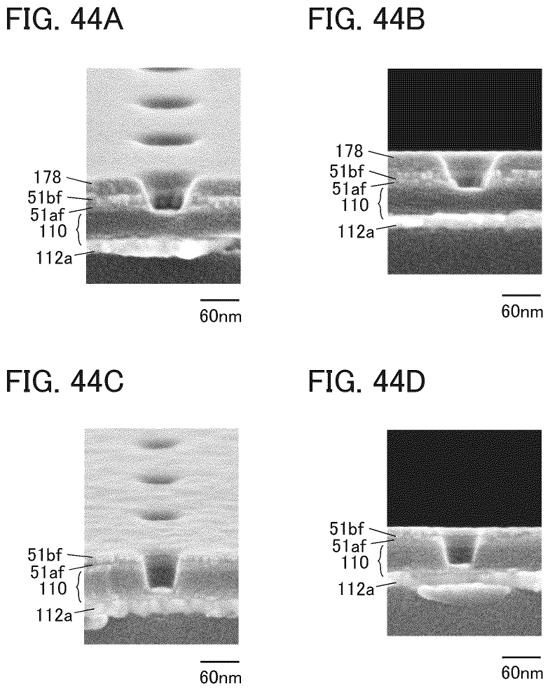

FIG. 43A and FIG. 43B show results of SEM observation after the steps up to the formation of the coating film 278 were conducted. FIG. 43C and FIG. 43D show results of SEM observation after the steps up to the formation of the metal layer 51b were conducted. FIG. 44A and FIG. 44B show results of SEM observation after the steps up to the formation of the conductive layer 51a were conducted. FIG. 44C and FIG. 44D show results of SEM observation after the steps up to the formation of the insulating layer 110a were conducted.

For the observation, samples were each cut to expose a cross section. FIG. 43A, FIG. 43C, FIG. 44A, and FIG. 44C show bird's eye images, and FIG. 43B, FIG. 43D, FIG. 44B, and FIG. 44D show cross-sectional images.

It was suggested that an opening portion reaching the top surface of the conductive layer 112a was favorably formed. Furthermore, the metal layer 51b was processed into a favorable shape without being lifted or having unevenness on its surface, for example.

Moreover, it was suggested that the coating film 278 was also removed at the time of the formation of the insulating layer 110a. This is probably because the coating film 278 was also etched under the etching conditions of the insulating film 110bf.

Reference Numerals

ANO: wiring, BL: wiring, BLB: wiring, C31: capacitor, C41: capacitor, D141: width, GL: wiring,
INV: inverter circuit, L100: channel length, L200: channel length, LAT: latch circuit, LIN: terminal,
MPG: conductive layer, MTCK: transistor, PL: wiring, RL: wiring, ROUT: terminal, RWL: wiring,
SA_OUT: wiring, SA_OUTB: wiring, SAN: wiring, SAP: wiring, SL: wiring, SMP: terminal,
T110a: thickness, T110b: thickness, T110c: thickness, Tr31: transistor, Tr33: transistor, Tr35:
transistor, Tr36: transistor, Tr41: transistor, Tr43: transistor, Tr45: transistor, Tr47: transistor,
VCOM: wiring, W100: channel width, W200: channel width, WL[1]: wiring, WL[i]: wiring,
WL[m]: wiring, WL: wiring, WWL: wiring, 10a: transistor, 10b: transistor, 10c: transistor, 10:
transistor, 11: insulating layer, 20a: opening, 20b: opening, 20c: opening, 20d: opening, 21:
semiconductor layer, 22: insulating layer, 23_1: conductive layer, 23_2: conductive layer, 23_3:
conductive layer, 23_4: conductive layer, 23: conductive layer, 30: memory cell, 31_1: conductive
layer, 31_2: conductive layer, 31: conductive layer, 32_1: conductive layer, 32_2: conductive layer,
32_3: conductive layer, 32a: conductive layer, 32b: conductive layer, 32: conductive layer, 33:
conductive layer, 34: conductive layer, 40b: memory cell, 41_1: insulating layer, 41_2: insulating
layer, 41a: insulating layer, 41b: insulating layer, 41c: insulating layer, 41: insulating layer, 42:
insulating layer, 43_1: insulating layer, 43_2: insulating layer, 44_1: insulating layer, 44_2:
insulating layer, 44: insulating layer, 46: insulating layer, 47: insulating layer, 48: insulating layer,
50A: display apparatus, 50B: display apparatus, 50: capacitor, 51a: conductive layer, 51af:
conductive film, 51ag: conductive layer, 51b: metal layer, 51bf: metal film, 51bg: metal layer, 52a:
conductive layer, 52b: metal layer, 53a: conductive layer, 53b: metal layer, 56: conductive layer,
57: conductive layer, 58: insulating layer, 60: memory unit, 61: conductive layer, 62: conductive
layer, 63: conductive layer, 65: insulating layer, 70: layer, 71: element layer, 73: element layer, 75:
element layer, 77: wiring layer, 80A: semiconductor device, 80B: semiconductor device, 80:
semiconductor device, 90: transistor, 91: substrate, 92: semiconductor region, 93: insulating layer,
94: conductive layer, 95a: low-resistance region, 95b: low-resistance region, 100A: transistor, 100:
transistor, 102: substrate, 104: conductive layer, 106: insulating layer, 107: adhesive layer, 108f:
metal oxide film, 108: semiconductor layer, 110a: insulating layer, 110af: insulating film, 110b:
insulating layer, 110bf: insulating film, 110c: insulating layer, 110cf: insulating film, 110f:
insulating film, 110: insulating layer, 111: pixel electrode, 112a: conductive layer, 112b:
conductive layer, 112bf: conductive film, 113a: first layer, 113b: second layer, 113c: third layer,
114: common layer, 115: common electrode, 118a: mask layer, 119: substrate, 121: insulating layer,
123: insulating layer, 125: insulating layer, 126a: conductive layer, 126b: conductive layer, 126c:
conductive layer, 127: insulating layer, 128: layer, 129a: conductive layer, 129b: conductive layer,
129c: conductive layer, 130B: light-emitting device, 130G: light-emitting device, 130R: light-
emitting device, 130: light-emitting device, 131: protective layer, 137: metal oxide layer, 139: film,
140: connection portion, 141: opening, 143: opening, 145: opening, 146: opening, 147: insulating
layer, 149: insulating layer, 151: substrate, 152: substrate, 157: resist mask, 159: resist mask, 162:
display portion, 164: circuit portion, 165: conductive layer, 172: FPC, 173: IC, 182a: conductive
layer, 182b: conductive layer, 182c: conductive layer, 195: insulating layer, 200A: transistor, 200:
transistor, 204: conductive layer, 208A: semiconductor layer, 208: semiconductor layer, 210: pixel,
212a: conductive layer, 212b: conductive layer, 230B: pixel, 230G: pixel, 230R: pixel, 230: pixel,
231: first driver circuit portion, 232: second driver circuit portion, 233: insulating layer, 234:
conductive layer, 235: insulating layer, 236: wiring, 238: wiring, 247: insulating layer, 249:
insulating layer, 277_2: coating film, 277f: coating film, 277: coating film, 278_2: coating film,
278f: coating film, 278: coating film, 279: resist mask, 300: transistor, 310: substrate, 312: element
isolation layer, 313: semiconductor region, 314a: low-resistance region, 314b: low-resistance
region, 315: insulating layer, 316: conductive layer, 317: insulating layer, 320: insulating layer,
322: insulating layer, 324: insulating layer, 326: insulating layer, 328: conductive layer, 330:
conductive layer, 350: insulating layer, 352: insulating layer, 354: insulating layer, 356: conductive
layer, 401: semiconductor layer, 402f: insulating film, 402: insulating layer, 420: layer, 422:
peripheral circuit, 430: element layer, 432: memory cell, 437: transistor, 438: capacitor, 440: driver
circuit, 442: row decoder, 443: row driver, 444: column decoder, 445: column driver, 446: sense
amplifier, 447: input circuit, 448: output circuit, 470: layer, 471: PSW, 472: PSW, 473: control
circuit, 474: voltage generation circuit, 480: memory device, 482_1: transistor, 482_2: transistor,
482: switch circuit, 483_1: transistor, 483_2: transistor, 483_3: transistor, 483: precharge circuit,
484_1: transistor, 484_2: transistor, 484_3: transistor, 484: precharge circuit, 485_1: transistor,
485_2: transistor, 485_3: transistor, 485_4: transistor, 485: amplifier circuit, 512: insulating layer,
514: conductive layer, 574: insulating layer, 581: insulating layer, 592: insulating layer, 594:
insulating layer, 596: conductive layer, 598: insulating layer, 599: insulating layer, 651A: pixel
circuit, 651: pixel circuit, 652A: transistor, 652B: transistor, 652C: transistor, 653: capacitor, 661:
light-emitting device, 700A: electronic device, 700B: electronic device, 700: electronic component,
702: printed circuit board, 704: circuit board, 710: semiconductor device, 711: mold, 712: land,
713: electrode pad, 714: wire, 715: driver circuit layer, 716: memory layer, 721: housing, 723:
wearing portion, 727: earphone portion, 730: electronic component, 731: interposer, 732: package
substrate, 733: electrode, 735: semiconductor device, 750: earphone, 751: display panel, 753:
optical member, 756: display region, 757: frame, 758: nose pad, 800A: electronic device, 800B:
electronic device, 820: display portion, 821: housing, 822: communication portion, 823: wearing
portion, 824: control portion, 825: image-capturing portion, 827: earphone portion, 832: lens,
5600: large computer, 5610: rack, 5620: computer, 5621: PC card, 5622: board, 5623: connection
terminal, 5624: connection terminal, 5625: connection terminal, 5626: electronic component,
5627: electronic component, 5628: electronic component, 5629: connection terminal, 5630:
motherboard, 5631: slot, 6000: storage system, 6001sb: server, 6001: host, 6002: storage control
circuit, 6003md: memory device, 6003: storage, 6500: electronic device, 6501: housing, 6502:
display portion, 6503: power button, 6504: button, 6505: speaker, 6506: microphone, 6507: camera,
6508: light source, 6509: control device, 6510: protection member, 6511: display panel, 6512:
optical member, 6513: touch sensor panel, 6515: FPC, 6516: IC, 6517: printed circuit board, 6518:
battery, 6800: artificial satellite, 6801: body, 6802: solar panel, 6803: antenna, 6804: planet, 6805:
secondary battery, 6807: control device, 7000: display portion, 7100: television device, 7101:
housing, 7103: stand, 7111: remote control, 7200: laptop personal computer, 7211: housing, 7212:
keyboard, 7213: pointing device, 7214: external connection port, 7216: control device, 7300:
digital signage, 7301: housing, 7303: speaker, 7311: information terminal, 7400: digital signage,
7401: pillar, 7411: information terminal, 9000: housing, 9001: display portion, 9002: camera,
9003: speaker, 9005: operation key, 9006: connection terminal, 9007: sensor, 9008: microphone,
9050: icon, 9051: information, 9052: information, 9053: information, 9054: information, 9055:
hinge, 9101: portable information terminal, 9102: portable information terminal, 9103: tablet
terminal, 9200: portable information terminal, 9201: portable information terminal

1. A method for manufacturing a stack comprising a first insulating layer comprising a first opening, a first conductive layer over the first insulating layer, and a second conductive layer over the first conductive layer, the method comprising:
forming a first insulating film;
forming a first conductive film over the first insulating film;
forming a second conductive film over the first conductive film;
forming a first coating film over the second conductive film;
forming a second coating film by removing a part of the first coating film;
forming the second conductive layer by etching the second conductive film using the second coating film as a mask;
forming the first conductive layer by etching the first conductive film using the second conductive layer as a mask; and
forming the first insulating layer comprising the first opening by etching the first insulating film using the second conductive layer as a mask,
wherein the first coating film is a film comprising silicon, oxygen, and carbon,
wherein the first conductive film is an oxide conductor or a nitride conductor, and
wherein the second conductive film is a metal film comprising one or more of ruthenium, tantalum, nickel, titanium, molybdenum, tungsten, hafnium, vanadium, niobium, aluminum, chromium, copper, silver, gold, platinum, zinc, manganese, iron, cobalt, magnesium, zirconium, beryllium, indium, iridium, strontium, and lanthanum.

2. The method for manufacturing a stack, according to claim 1,
wherein the second coating film is removed at the same time as the etching of the first insulating film.

3. The method for manufacturing a stack, according to claim 1,
wherein the second conductive film is a ruthenium film,
wherein the second conductive film is processed by dry etching using an oxygen gas and a chlorine gas, and
wherein a flow rate ratio of the oxygen gas in the dry etching is higher than or equal to 50% and lower than 100% when the sum of flow rates of the oxygen gas and the chlorine gas is set to 100%.

4. The method for manufacturing a stack, according to claim 3,
wherein a pressure in a chamber in the etching of the second conductive film is higher than or equal to 0.5 Pa and lower than or equal to 50 Pa.

5. The method for manufacturing a stack, according to claim 1,
wherein the first conductive film is an oxide film comprising indium.

6. A method for manufacturing a semiconductor device comprising a first conductive layer, a first insulating layer comprising a first opening overlapping with the first conductive layer, a second conductive layer over the first insulating layer, a third conductive layer over the second conductive layer, a first semiconductor layer, a second insulating layer, and a fourth conductive layer, the method comprising:
forming a first conductive film;
forming the first conductive layer by processing the first conductive film;
forming a first insulating film over the first conductive layer;
forming a second conductive film over the first insulating film;
forming a third conductive film over the second conductive film;
forming a first coating film over the third conductive film;
forming a second coating film by removing a part of the first coating film;
forming the third conductive layer by etching the third conductive film using the second coating film as a mask;
forming the second conductive layer by etching the second conductive film using the third conductive layer as a mask;
forming the first insulating layer comprising the first opening by etching the first insulating film using the third conductive layer as a mask;
forming the first semiconductor layer to cover a top surface of the first conductive layer, a side surface of the second conductive layer, a side surface of the third conductive layer, and a side surface of the first insulating layer in the first opening;
forming the second insulating layer over the first semiconductor layer; and
forming the fourth conductive layer over the second insulating layer,
wherein the first coating film is a film comprising silicon, oxygen, and carbon,
wherein the second conductive film is an oxide conductor or a nitride conductor,
wherein the third conductive film is a metal film comprising one or more of ruthenium, tantalum, nickel, titanium, molybdenum, tungsten, hafnium, vanadium, niobium, aluminum, chromium, copper, silver, gold, platinum, zinc, manganese, iron, cobalt, magnesium, zirconium, beryllium, indium, iridium, strontium, and lanthanum, and
wherein the first semiconductor layer is a metal oxide.

7. The method for manufacturing a semiconductor device, according to claim 6, wherein the second coating film is removed at the same time as the etching of the first insulating film.

8. The method for manufacturing a semiconductor device, according to claim 6,
wherein the second conductive film is a ruthenium film,
wherein the second conductive film is processed by dry etching using an oxygen gas and a chlorine gas, and
wherein a flow rate ratio of the oxygen gas in the dry etching is higher than or equal to 50% and lower than 100% when the sum of flow rates of the oxygen gas and the chlorine gas is set to 100%.

9. The method for manufacturing a semiconductor device, according to claim 6,
wherein a pressure in a chamber in the etching of the second conductive film is higher than or equal to 0.5 Pa and lower than or equal to 50 Pa.

10. The method for manufacturing a semiconductor device, according to claim 6,
wherein the first conductive film is an oxide film comprising indium.

11. The method for manufacturing a semiconductor device, according to claim 6,
wherein the metal oxide comprises one or more of indium and zinc.

12. The method for manufacturing a semiconductor device, according to claim 6,
wherein the metal oxide comprises an element M and one or more of indium and zinc, and
wherein the element M is one or more kinds selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.
